(19) United States
(12) Patent Application Publication
(10) Pub. No.: US 2025/0149446 A1
(43) Pub. Date: May 8, 2025

(54) SEMICONDUCTOR DEVICE

(71) Applicant: SEMICONDUCTOR ENERGY LABORATORY CO., LTD., Atsugi-shi (JP)

(72) Inventors: Shoki MIYATA, Atsugi (JP); Takanori MATSUZAKI, Atsugi (JP)

(21) Appl. No.: 18/928,265

(22) Filed: Oct. 28, 2024

(30) Foreign Application Priority Data
Nov. 2, 2023 (JP) 2023-188121

(51) Int. Cl. H01L 23/528; H01L 23/532; H01L 29/40; H10B 10/00

(52) U.S. Cl. CPC H01L 23/5283; H01L 23/5329; H10B 10/12; H10D 64/118

(57) ABSTRACT

A semiconductor device with large memory capacity, a semiconductor device which can be miniaturized or highly integrated, a highly reliable semiconductor device, a semiconductor device with low power consumption, or a semiconductor device with high operating speed is provided. A first insulating layer, a second conductive layer, a second insulating layer, and a third conductive layer are provided over a first conductive layer in this order and each include an opening portion reaching the first conductive layer. In the opening portion of the second conductive layer, a third insulating layer, a first charge-accumulation layer, a fourth insulating layer, an oxide semiconductor layer, a fifth insulating layer, a second charge-accumulation layer, a sixth insulating layer, and a fourth conductive layer are provided in this order from a sidewall of the opening portion. The first conductive layer and the third conductive layer function as a source electrode or a drain electrode of a transistor. The fourth conductive layer functions as a first control gate. The second conductive layer functions as a second control gate.

### BACKGROUND OF THE INVENTION

### 1. Field of the Invention

One embodiment of the present invention relates to a semiconductor device, a memory device, and an electronic device. One embodiment of the present invention also relates to a method for manufacturing a semiconductor device and a memory device.

Note that one embodiment of the present invention is not limited to the above technical field. Examples of the technical field of one embodiment of the present invention include a display device, a light-emitting apparatus, a power storage device, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, semiconductor devices have been developed to be used mainly for an LSI, a central processing unit (CPU), a memory, and the like. A CPU is an aggregation of semiconductor elements; the CPU includes a semiconductor integrated circuit (including at least a transistor and a memory) formed into a chip by processing a semiconductor wafer, and is provided with an electrode that is a connection terminal. A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a material of a semiconductor thin film that can be used in a transistor. As another material, an oxide semiconductor has been attracting attention.

A transistor using an oxide semiconductor is known to have an extremely low leakage current in an off state. For example, Patent Document 1 discloses a low-power CPU utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

Non-Patent Document 2 discloses CAAC-IGZO as a crystalline oxide semiconductor. Non-Patent Document 2 also discloses a growth mechanism and the like of CAAC-IGZO.

Patent Document 5 discloses a nonvolatile memory using a floating gate. Patent Document 6 discloses a nonvolatile memory including an oxide semiconductor layer. As disclosed in Patent Document 7, memory transistors can be arranged three-dimensionally in a nonvolatile semiconductor memory device.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537
[Patent Document 5] Japanese Published Patent Application No. 2009-295971
[Patent Document 6] Japanese Published Patent Application No. 2011-124563
[Patent Document 7] Japanese Published Patent Application No. 2007-266143

### Non-Patent Documents

[Non-Patent Document 1] M. Oota, et al., “3D-Stacked CAAC-In—Ga—Zn Oxide FETs with Gate Length of 72 nm”, IEDM Tech. Dig., 2019, pp. 50-53
[Non-Patent Document 2] Noboru Kimizuka and Shunpei Yamazaki, “PHYSICS AND TECHNOLOGY OF CRYSTALLINE OXIDE SEMICONDUCTOR CAAC-IGZO” FUNDAMENTALS (the United States), Wiley-SID Series in Display Technology, 2017, pp. 50-150

### SUMMARY OF THE INVENTION

An object of one embodiment of the present invention is to provide a transistor, a semiconductor device, or a memory device with large memory capacity. Another object of one embodiment of the present invention is to provide a transistor, a semiconductor device, or a memory device which can be miniaturized or highly integrated. Another object of one embodiment of the present invention is to provide a highly reliable transistor, semiconductor device, or memory device. Another object of one embodiment of the present invention is to provide a transistor, a semiconductor device, or a memory device with low power consumption. Another object of one embodiment of the present invention is to provide a transistor, a semiconductor device, or a memory device with high operating speed. Another object of one embodiment of the present invention is to provide a novel transistor, semiconductor device, or memory device. Another object of one embodiment of the present invention is to provide a method for manufacturing the above-described transistor, semiconductor device, or memory device.

Note that the description of these objects does not preclude the existence of other objects. One embodiment of the present invention does not necessarily achieve all of these objects. Other objects can be derived from the description of the specification, the drawings, and the claims.

One embodiment of the present invention is a semiconductor device including a first conductive layer, a first insulating layer over the first conductive layer, a second conductive layer over the first insulating layer, a second insulating layer over the second conductive layer, a third conductive layer over the second insulating layer, an oxide semiconductor layer, a fourth conductive layer, a third insulating layer, a fourth insulating layer, a fifth insulating layer, a sixth insulating layer, a first charge-accumulation layer, and a second charge-accumulation layer. The first insulating layer, the second conductive layer, the second insulating layer, and the third conductive layer each include an opening portion reaching the first conductive layer. The third insulating layer includes a region in contact with a sidewall of the opening portion of the first insulating layer, a region in contact with a sidewall of the opening portion of the second conductive layer, and a region in contact with a top surface of the first conductive layer. The first charge-accumulation layer includes a region covering the sidewall of the opening portion of the second conductive layer with the third insulating layer therebetween. The fourth insulating layer includes a region covering the sidewall of the opening portion of the second conductive layer with the third insulating layer and the first charge-accumulation layer therebetween. The fourth insulating layer includes a region between the oxide semiconductor layer and the first charge-accumulation layer. The oxide semiconductor layer includes a region in contact with the top surface of the first conductive layer, a region covering the sidewall of the opening portion of the second conductive layer with the third insulating layer, the first charge-accumulation layer, and the fourth insulating layer therebetween, and a region in contact with the third conductive layer. The fourth conductive layer includes a region positioned in the opening portion of the second conductive layer. The second charge-accumulation layer includes a region between the oxide semiconductor layer and the fourth conductive layer. The fifth insulating layer includes a region between the oxide semiconductor layer and the second charge-accumulation layer. The sixth insulating layer includes a region between the second charge-accumulation layer and the fourth conductive layer.

In the above mode, the fourth insulating layer and the fifth insulating layer preferably include one or more selected from silicon oxide, silicon oxynitride, silicon nitride oxide, silicon nitride, and aluminum oxide.

In the above mode, at least one of the first charge-accumulation layer and the second charge-accumulation layer preferably includes one or more metal elements selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, and lanthanum; an alloy containing any of these metal elements as its component; or an alloy containing a combination of these metal elements.

In the above mode, at least one of the first charge-accumulation layer and the second charge-accumulation layer preferably includes a metal nitride or a metal oxide.

In the above mode, at least one of the first charge-accumulation layer and the second charge-accumulation layer preferably includes one or more selected from silicon and germanium.

In the above mode, at least one of the first charge-accumulation layer and the second charge-accumulation layer preferably includes one or more selected from silicon nitride and silicon nitride oxide.

In the above mode, it is preferable that each of the first conductive layer and the third conductive layer function as a source electrode or a drain electrode of a transistor, the fourth conductive layer function as a first control gate of the transistor, and the second conductive layer function as a second control gate of the transistor.

With one embodiment of the present invention, a transistor, a semiconductor device, or a memory device with large memory capacity can be provided. With another embodiment of the present invention, a transistor, a semiconductor device, or a memory device which can be miniaturized or highly integrated can be provided. With another embodiment of the present invention, a highly reliable transistor, semiconductor device, or memory device can be provided. With another embodiment of the present invention, a transistor, a semiconductor device, or a memory device with low power consumption can be provided. With another embodiment of the present invention, a transistor, a semiconductor device, or a memory device with high operating speed can be provided. With another embodiment of the present invention, a novel transistor, semiconductor device, or memory device can be provided. With another embodiment of the present invention, a method for manufacturing the above-described transistor, semiconductor device, or memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a perspective view illustrating an example of a semiconductor device, FIG. 1B is a plan view illustrating the example of the semiconductor device, FIG. 1C is a cross-sectional view illustrating the example of the semiconductor device, and FIG. 1D is a circuit diagram of one embodiment of the present invention;

FIGS. 2A to 2E are cross-sectional views each illustrating an example of a semiconductor device;

FIGS. 3A and 3B are cross-sectional views each illustrating an example of a semiconductor device, and FIG. 3C is a perspective view illustrating an example of a semiconductor device;

FIG. 4A is a plan view illustrating an example of a semiconductor device, and FIGS. 4B and 4C are cross-sectional views each illustrating an example of the semiconductor device;

FIG. 5A is a cross-sectional view illustrating an example of a semiconductor device, FIG. 5B is a plan view illustrating an example of the semiconductor device, and FIGS. 5C and 5D are cross-sectional views each illustrating an example of the semiconductor device;

FIGS. 6A and 6B are cross-sectional views each illustrating an example of a semiconductor device;

FIGS. 7A and 7B are circuit diagrams each illustrating an example of a semiconductor device;

FIG. 8A is a circuit diagram showing an operation example of a semiconductor device, and FIG. 8B shows an example of the I_{d}-V_{gs} curves of the semiconductor device;

FIGS. 9A to 9C are timing charts each showing an operation example of a semiconductor device;

FIG. 10A is a circuit diagram showing an operation example of a semiconductor device, and FIG. 10B is a timing chart showing an operation example of the semiconductor device;

FIG. 11A is a circuit diagram showing an operation example of a semiconductor device, and FIG. 11B is a timing chart showing an operation example of the semiconductor device;

FIG. 12 is a circuit diagram showing an operation example of a semiconductor device;

FIGS. 13A to 13C are timing charts each showing an operation example of a semiconductor device;

FIGS. 14A and 14B are timing charts each showing an operation example of a semiconductor device;

FIG. 15 is a circuit diagram showing an operation example of a semiconductor device;

FIGS. 16A to 16C are timing charts each showing an operation example of a semiconductor device;

FIGS. 17A to 17C are timing charts each showing an operation example of a semiconductor device, and FIG. 17D shows an example of the I_{d}-V_{gs} curves of the semiconductor device;

FIGS. 18A to 18D are cross-sectional views illustrating an example of a method for manufacturing a semiconductor device;

FIGS. 19A to 19D are cross-sectional views illustrating an example of a method for manufacturing a semiconductor device;

FIGS. 20A to 20C are cross-sectional views illustrating an example of a method for manufacturing a semiconductor device;

FIG. 21 is a cross-sectional view illustrating an example of a semiconductor device;

FIGS. 22A to 22D are cross-sectional views illustrating an example of a method for forming an oxide semiconductor;

FIGS. 23A to 23D are cross-sectional views each illustrating an example of an oxide semiconductor;

FIG. 24 is a block diagram illustrating a structure example of a semiconductor device;

FIGS. 25A and 25B are perspective views each illustrating a structure example of a semiconductor device;

FIG. 26 is a block diagram illustrating a CPU;

FIGS. 27A and 27B are perspective views of a semiconductor device;

FIGS. 28A and 28B are perspective views of a semiconductor device;

FIGS. 29A and 29B each illustrate a hierarchy of various kinds of memory devices;

FIGS. 30A and 30B each illustrate an example of an electronic component; and

FIGS. 31A to 31C illustrate an example of a large computer, FIG. 31D illustrates an example of a device for space, and FIG. 31E illustrates an example of a storage system that can be used in a data center.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, a switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. In this specification and the like, a transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen in a film can be analyzed by secondary ion mass spectrometry (SIMS) or X-ray photoelectron spectroscopy (XPS), for example. Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

In this specification and the like, the term “electrically connected” includes the case where components are connected to each other through an object having any electric function. There is no particular limitation on an “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vth, and the off state of a p-channel transistor means that V_{gs} is higher than Vth.

Note that “normally-on characteristics” in this specification and the like mean a state where a channel exists and a current flows through a transistor even when no voltage is applied to a gate. Furthermore, “normally-off characteristics” mean a state where a current does not flow through a transistor when no potential or a ground potential is applied to a gate.

In this specification and the like, a top surface shape of a component means the outline of the component in a plan view. A plan view means a view to observe the component from a normal direction of a surface where the component is formed or from a normal direction of a surface of a support (e.g., a substrate) where the component is formed.

In this specification and the like, the expression “having substantially the same top surface shapes” means that the outlines of stacked layers at least partly overlap with each other. For example, the case of patterning or partly patterning an upper layer and a lower layer with the use of the same mask pattern is included. The expression “having substantially the same top surface shapes” also sometimes includes the case where the outlines do not completely overlap with each other; for instance, the edge of the upper layer may be positioned on the inner side or the outer side of the edge of the lower layer. In the case where the top surface shapes are the same or substantially the same, it can be said that the end portions are aligned or substantially aligned with each other or the side end portions are aligned or substantially aligned with each other.

Note that in this specification and the like, a tapered shape refers to a shape in which at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, step disconnection refers to a phenomenon in which a layer, a film, or an electrode is split because of the shape of its formation surface (e.g., a step).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, a semiconductor device of one embodiment of the present invention is described.

The semiconductor device of one embodiment of the present invention includes a first conductive layer, a second conductive layer, and an oxide semiconductor layer.

A first insulating layer is positioned over the first conductive layer, and the second conductive layer is positioned over the first insulating layer. The first insulating layer includes a first opening portion reaching the first conductive layer. The oxide semiconductor layer covers a top surface of the first conductive layer and a side surface of the first insulating layer in the first opening portion. Note that the opening portion is also referred to as an opening.

The second conductive layer includes a second opening portion overlapping with the first opening portion. The oxide semiconductor layer covers a side surface of the second conductive layer in the second opening portion.

The semiconductor device of one embodiment of the present invention includes a third conductive layer, a fourth conductive layer, a first charge-accumulation layer, and a second charge-accumulation layer.

The third conductive layer overlaps with the oxide semiconductor layer with the first charge-accumulation layer therebetween in the first opening portion.

The fourth conductive layer is positioned over the first insulating layer and under the second conductive layer. The fourth conductive layer includes a third opening portion overlapping with the first opening portion. The oxide semiconductor layer overlaps with the fourth conductive layer with the second charge-accumulation layer therebetween in the third opening portion.

The first conductive layer functions as one of a source electrode and a drain electrode of a transistor. The second conductive layer functions as the other of the source electrode and the drain electrode of the transistor. The third conductive layer functions as a first gate electrode of the transistor, and the fourth conductive layer functions as a second gate electrode of the transistor.

The charge-accumulation layer can accumulate electric charge. The charge-accumulation layer can release the accumulated electric charge. The charge-accumulation layer can retain the accumulated electric charge.

When electric charge is accumulated in the charge-accumulation layer, information can be stored in the transistor included in the semiconductor device of one embodiment of the present invention. The transistor included in the semiconductor device of one embodiment of the present invention can function as a memory device. The transistor included in the semiconductor device of one embodiment of the present invention includes a plurality of charge-accumulation layers, and thus can be used as a multilevel memory. Thus, the use of the transistor of one embodiment of the present invention can achieve a semiconductor device with large memory capacity. The transistor of one embodiment of the present invention includes a first charge-accumulation layer where writing of information is controlled by the first gate electrode and a second charge-accumulation layer where writing of information is controlled by the second gate electrode, which results in an increase in the amount of information that can be held in one transistor.

The semiconductor device of one embodiment of the present invention includes a transistor functioning as a memory element. The semiconductor device of one embodiment of the present invention can hold data written to the semiconductor device for a long time even after power supply to the memory element is stopped. The semiconductor device of one embodiment of the present invention can be referred to as a nonvolatile semiconductor device. The transistor included in the semiconductor device of one embodiment of the present invention can rewrite written data. The transistor included in the semiconductor device of one embodiment of the present invention is sometimes referred to as an electrically erasable programmable read only memory (EEPROM).

Note that in this specification and the like, a simple expression “in a cross-sectional view” is replaced with a specific expression “in a cross-sectional view from the same direction” in some cases. For example, in the case where the relation between a plurality of components is described, a relation in a cross-sectional view from the same direction is described. In this case, the relation between the plurality of components can be described using one cross-sectional view.

In the transistor of one embodiment of the present invention, the source electrode and the drain electrode are positioned at different levels (e.g., heights in a direction perpendicular to a substrate plane or an insulating plane where the transistor is provided), so that a current flows in the semiconductor layer in the height direction. In other words, the channel length direction includes a height (vertical) component, so that the transistor of one embodiment of the present invention can also be referred to as a vertical field effect transistor (VFET), a vertical transistor, a vertical-channel transistor, or the like.

In the transistor of one embodiment of the present invention, the source electrode, the semiconductor layer, and the drain electrode can be provided to overlap with each other. Thus, the area occupied by the transistor can be significantly smaller than the area occupied by what is called a planar transistor in which a planar semiconductor layer is provided.

In this specification and the like, the expression “an end portion is aligned with another end portion” means that at least outlines of stacked layers partly overlap with each other in a plan view. For example, the case of processing or partly processing an upper layer and a lower layer with the use of the same mask pattern is included. The expression “an end portion is aligned with another end portion” also includes the case where the outlines do not completely overlap with each other; for instance, the outline of the upper layer may be positioned inside or outside the outline of the lower layer.

In general, it is sometimes difficult to clearly differentiate “completely aligned” from “substantially aligned”. Thus, in this specification and the like, the expression “aligned” includes both “completely aligned” and “substantially aligned”, in some cases.

### <Structure Example 1 of Semiconductor Device>

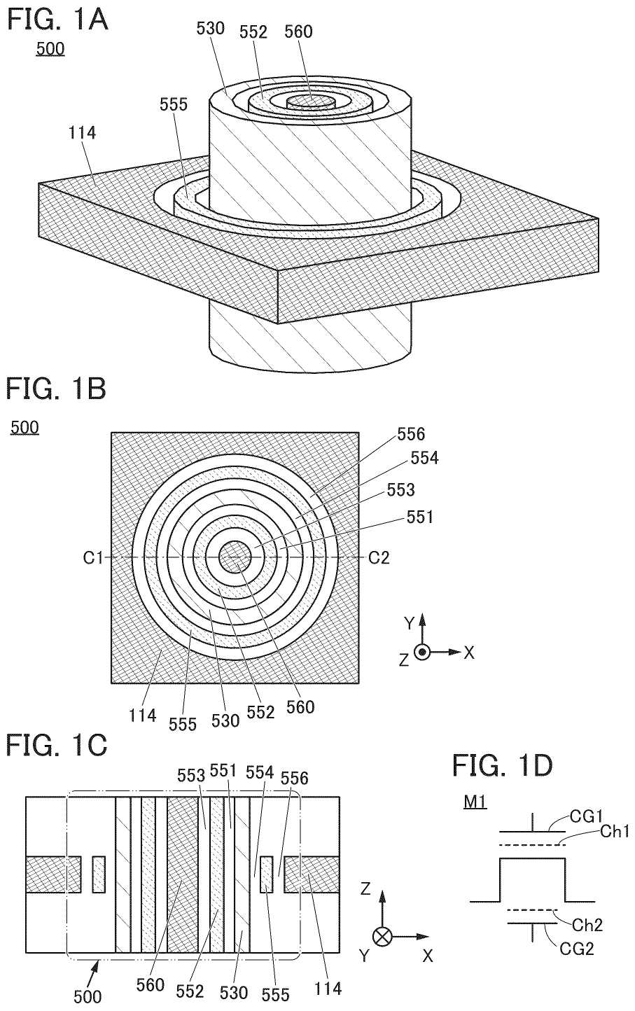

FIG. 1A is a perspective view of a semiconductor device including a transistor 500. FIG. 1B is a plan view of the transistor 500 illustrated in FIG. 1A, and FIG. 1C is a cross-sectional view taken along a dashed-dotted line C1-C2 in FIG. 1B. Note that for simplification of the drawing, some components are not illustrated in the perspective view of FIG. 1A.

The transistor 500 functions as a memory element, especially can function as a nonvolatile memory element. When memory cells each including the transistor 500 are arranged in a matrix, a memory device that can store a large amount of data can be formed. The memory cell including the transistor 500 can function as, for example, a NOR memory cell or a NAND memory cell. Note that the transistor 500 is referred to as a memory transistor in some cases. The transistor 500 can be expressed as a nonvolatile memory. A semiconductor device including the transistor 500 is referred to as a nonvolatile semiconductor device, a nonvolatile memory device, or the like in some cases.

The transistor 500 includes an oxide semiconductor layer 530, a charge-accumulation layer 552, a conductive layer 560, a charge-accumulation layer 555, and a conductive layer 114. The conductive layer 560 has a columnar shape. The charge-accumulation layer 552 is provided so as to surround the conductive layer 560; the oxide semiconductor layer 530 is provided so as to surround the conductive layer 560 with the charge-accumulation layer 552 therebetween; the charge-accumulation layer 555 is provided so as to surround the conductive layer 560 with the charge-accumulation layer 552 and the oxide semiconductor layer 530 therebetween; and the conductive layer 114 is provided so as to surround the conductive layer 560 with the charge-accumulation layer 552, the oxide semiconductor layer 530, and the charge-accumulation layer 555 therebetween. The charge-accumulation layer 552, the oxide semiconductor layer 530, the charge-accumulation layer 555, and the conductive layer 114 each have a cylindrical shape.

In FIGS. 1A to 1C, the conductive layer 560 can be expressed as having a cylindrical shape, and each of the charge-accumulation layer 552, the oxide semiconductor layer 530, the charge-accumulation layer 555, and the conductive layer 114 can be expressed as having a hollow cylindrical shape. Here, a hollow cylinder refers to a structure in which a first cylinder is cut out with a second cylinder, the first cylinder and the second cylinder have the same center, and the second cylinder has a smaller diameter than the first cylinder. The conductive layer 560 can also be expressed as being positioned in a hollow portion of the charge-accumulation layer 552, the oxide semiconductor layer 530, the charge-accumulation layer 555, and the conductive layer 114 each with a hollow cylindrical shape.

The conductive layer 560 and the conductive layer 114 include a region where they overlap with each other with the oxide semiconductor layer 530 therebetween.

The charge-accumulation layer 552 includes a region positioned between the oxide semiconductor layer 530 and the conductive layer 560. An insulating layer 551 includes a region positioned between the oxide semiconductor layer 530 and the charge-accumulation layer 552. An insulating layer 553 includes a region positioned between the charge-accumulation layer 552 and the conductive layer 560.

In the transistor 500, the oxide semiconductor layer 530 functions as a semiconductor layer, the conductive layer 560 functions as a first gate electrode, and the conductive layer 114 functions as a second gate electrode.

The conductive layer 560 and the conductive layer 114 are each referred to as a control gate or a control gate electrode in some cases. Here, the conductive layer 560 is referred to as a first control gate, and the conductive layer 114 is referred to as a second control gate. In the case where the charge-accumulation layer 552 has high conductivity, the charge-accumulation layer 552 is referred to as a floating gate or a floating gate electrode in some cases. Similarly, in the case where the charge-accumulation layer 555 has high conductivity, the charge-accumulation layer 555 is referred to as a floating gate or a floating gate electrode in some cases.

Insulating layers are provided between the charge-accumulation layer and the semiconductor layer and between the charge-accumulation layer and the control gate. In FIGS. 1B and 1C, the insulating layer 551 and an insulating layer 554 are shown as the insulating layers between the charge-accumulation layer and the semiconductor layer, and the insulating layer 553 and an insulating layer 556 are shown as the insulating layers between the charge-accumulation layer and the control gate. Note that in FIGS. 1B and 1C, the boundary between these insulating layers and the boundary between these insulating layers and insulating layers (e.g., interlayer insulating layers) in other regions are not clearly illustrated.

The insulating layer 551, the charge-accumulation layer 552, and the insulating layer 553 each include a region positioned between the oxide semiconductor layer 530 and the conductive layer 560. The insulating layer 551, the charge-accumulation layer 552, and the insulating layer 553 are provided in this order from the oxide semiconductor layer 530.

The insulating layer 554, the charge-accumulation layer 555, and the insulating layer 556 each include a region positioned between the oxide semiconductor layer 530 and the conductive layer 114. The insulating layer 554, the charge-accumulation layer 555, and the insulating layer 556 are provided in this order from the oxide semiconductor layer 530.

FIG. 1D illustrates an example of a transistor that can employ the structure of the transistor 500.

A transistor M1 illustrated in FIG. 1D includes a first control gate (denoted by CG1 in the diagram) and a second control gate (denoted by CG2 in the diagram). The transistor M1 includes a first charge-accumulation layer (denoted by Ch1 in the diagram) in which charge accumulation and release are controlled by the first control gate and a second charge-accumulation layer (denoted by Ch2 in the diagram) in which charge accumulation and release are controlled by the second control gate. The first control gate, the second control gate, the first charge-accumulation layer, and the second charge-accumulation layer can correspond to the conductive layer 560, the conductive layer 114, the charge-accumulation layer 552, and the charge-accumulation layer 555, respectively, which are included in the transistor 500. In some cases, the first control gate, the second control gate, the first charge-accumulation layer, and the second charge-accumulation layer may correspond to the conductive layer 114, the conductive layer 560, the charge-accumulation layer 555, and the charge-accumulation layer 552, respectively.

Information can be written to the transistor 500 by injecting or releasing carriers into or from at least one of the charge-accumulation layer 552 and the charge-accumulation layer 555. The injection or release of carriers into or from the charge-accumulation layer can change the threshold voltage of the transistor 500, thereby changing the value of a current flowing between the source and the drain in reading. The injection or release of carriers into or from the charge-accumulation layer 552 can be performed by utilizing a tunnel current flowing through the insulating layer 551 positioned between the oxide semiconductor layer 530 and the charge-accumulation layer 552. The injection or release of carriers into or from the charge-accumulation layer 555 can be performed by utilizing a tunnel current flowing through the insulating layer 554 positioned between the oxide semiconductor layer 530 and the charge-accumulation layer 555. Each of the insulating layers 551 and 554 is referred to as a tunnel insulating layer in some cases.

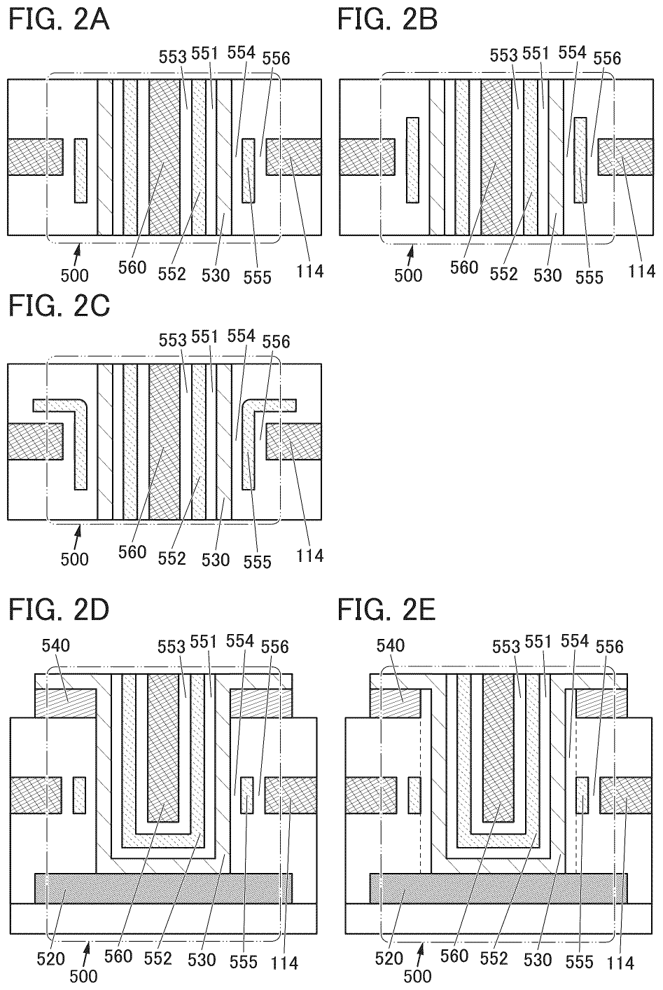

Although FIG. 1C illustrates an example in which the charge-accumulation layer 555 and the conductive layer 114 are positioned at the same level, the charge-accumulation layer 555 may include one or both of a region at a higher level than the conductive layer 114 (a region having a larger Z coordinate) and a region at a lower level than the conductive layer 114 (a region having a smaller Z coordinate). FIG. 2A illustrates an example in which the charge-accumulation layer 555 includes a region at a lower level than the conductive layer 114, and FIG. 2B illustrates an example in which the charge-accumulation layer 555 includes regions at a higher level and a lower level than the conductive layer 114.

As illustrated in FIG. 2C, the charge-accumulation layer 555 sometimes includes a region positioned over the conductive layer 114 in addition to a region sandwiched between the conductive layer 114 and the oxide semiconductor layer 530.

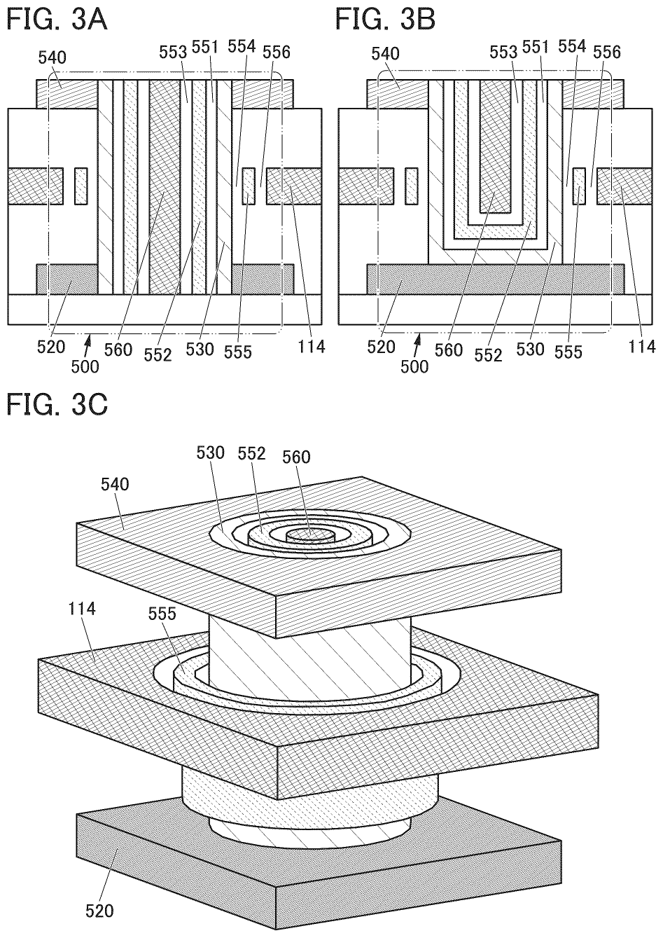

The transistor 500 preferably includes a conductive layer 520 and a conductive layer 540 as illustrated in FIGS. 3A and 3B. The conductive layer 520 functions as one of a source electrode and a drain electrode and the conductive layer 540 functions as the other of the source electrode and the drain electrode.

The oxide semiconductor layer 530 is preferably in contact with the conductive layer 520 and the conductive layer 540. In the structure illustrated in FIG. 3A, the oxide semiconductor layer 530 is in contact with a side surface of the conductive layer 520 and a side surface of the conductive layer 540. In FIG. 3B, the oxide semiconductor layer 530 includes a region in contact with a top surface of the conductive layer 520. FIG. 3C is a perspective view corresponding to the cross section in FIG. 3B.

Note that as illustrated in FIG. 2D, the oxide semiconductor layer 530 can be in contact with a top surface as well as the side surface of the conductive layer 540. Such a structure can increase the contact area and reduce the contact resistance.

In the structure example illustrated in FIG. 2E, the insulating layer 554 covers a side surface of the conductive layer 560. The oxide semiconductor layer 530 covers the side surface and the top surface of the conductive layer 540 but is in contact only with the top surface and not with the side surface because the insulating layer 554 is provided between the oxide semiconductor layer 530 and the conductive layer 540.

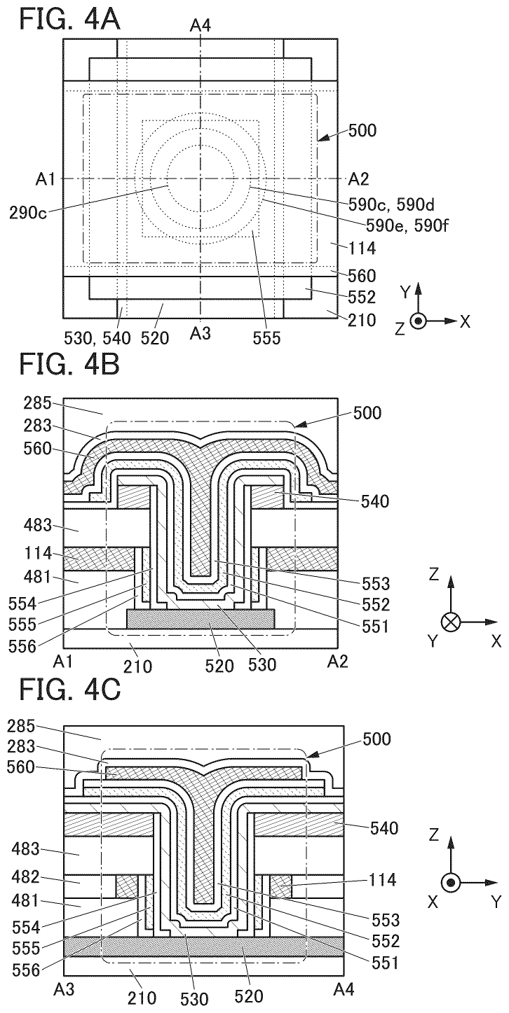

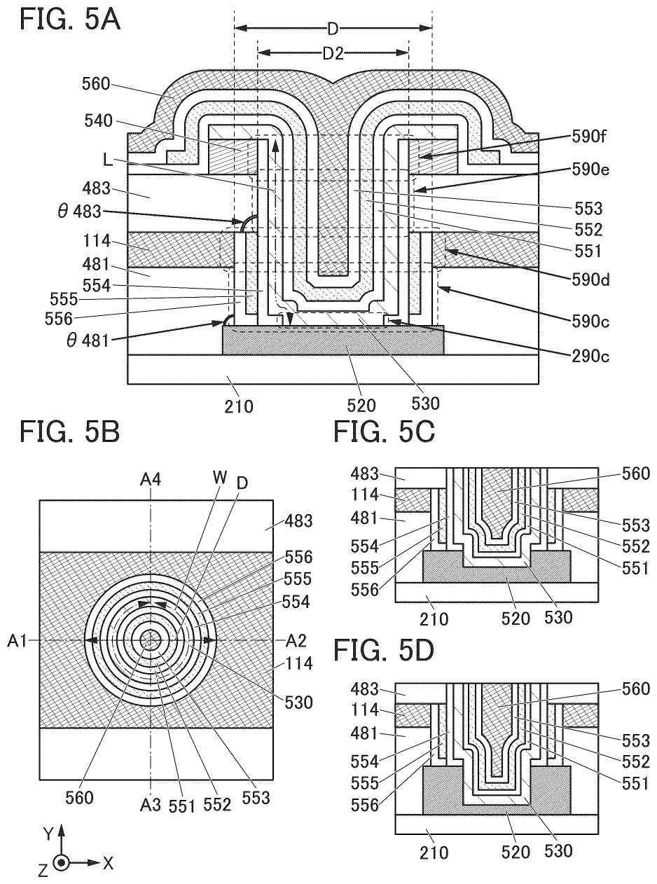

A structure of a semiconductor device of one embodiment of the present invention is described with reference to FIGS. 4A to 4C. FIG. 4A is a plan view of the semiconductor device including the transistor 500. FIG. 4B is a cross-sectional view taken along a dashed-dotted line A1-A2 in FIG. 4A. FIG. 4C is a cross-sectional view taken along a dashed-dotted line A3-A4 in FIG. 4A. FIG. 5A is an enlarged view of FIG. 4B. Note that for simplification of the drawing, some components are not illustrated in the plan view of FIG. 4A. Some components may be omitted also in the following plan views.

The semiconductor device illustrated in FIGS. 4A to 4C includes an insulating layer 210 over a substrate (not illustrated), the transistor 500 over the insulating layer 210, an insulating layer 481 over the insulating layer 210, an insulating layer 482 over the insulating layer 481, an insulating layer 483 over the insulating layer 482, and an insulating layer 283 and an insulating layer 285 over the transistor 500. The insulating layers 210, 481, 482, 483, 283, and 285 function as interlayer films.

In FIGS. 4A to 4C, the transistor 500 includes the conductive layer 520, the conductive layer 540, the oxide semiconductor layer 530, the insulating layer 551, the charge-accumulation layer 552, the insulating layer 553, the conductive layer 560, the insulating layer 554, the charge-accumulation layer 555, the insulating layer 556, and the conductive layer 114. The conductive layer 520 and the conductive layer 540 are positioned at different levels. The insulating layer 481, the insulating layer 482, and the insulating layer 483 are positioned between the conductive layer 520 and the conductive layer 540.

The insulating layer 556 includes a region overlapping with the top surface of the conductive layer 520. In the region, the insulating layer 556 is sandwiched between the conductive layer 520 and the charge-accumulation layer 555. This can prevent the conductive layer 520 and the charge-accumulation layer 555 from being in direct contact with each other. When the conductive layer 520 is in direct contact with the charge-accumulation layer 555, electric charge retained in the charge-accumulation layer 555 flows to the conductive layer 520.

The conductive layer 114 and the insulating layer 482 are provided over the insulating layer 481. The insulating layer 483 is provided over the conductive layer 114 and the insulating layer 482.

In the semiconductor device illustrated in FIGS. 4A to 4C and FIG. 5A, the insulating layer 481 is positioned over the conductive layer 520, the conductive layer 114 is positioned over the insulating layer 481, the insulating layer 483 is positioned over the conductive layer 114, and the conductive layer 540 is positioned over the insulating layer 483. Opening portions (an opening portion 590c, an opening portion 590d, an opening portion 590e, and an opening portion 590f) reaching the conductive layer 520 are provided in the insulating layer 481, the conductive layer 114, the insulating layer 483, and the conductive layer 540.

The insulating layer 481 includes the opening portion 590c reaching the top surface of the conductive layer 520. The conductive layer 114 includes the opening portion 590d. In the plan view, the opening portion 590c and the opening portion 590d overlap with each other. A side surface of the opening portion 590c and a side surface of the opening portion 590d are preferably connected smoothly. This allows the insulating layer, the conductive layer, the semiconductor layer, and the like to be formed on the side surfaces of the opening portions 590c and 590d with high coverage.

The conductive layer 560 includes at least a region positioned in the opening portion 590e. In the opening portion 590e, the conductive layer 560 overlaps with the conductive layer 114 with the oxide semiconductor layer 530 therebetween.

The insulating layer 556 covers the side surface of the opening portion 590c of the insulating layer 481 and the side surface of the opening portion 590d of the conductive layer 114. The insulating layer 556 is preferably in contact with the side surface of the opening portion 590c of the insulating layer 481 and the side surface of the opening portion 590d of the conductive layer 114. The charge-accumulation layer 555 covers the side surface of the opening portion 590c of the insulating layer 481 and the side surface of the opening portion 590d of the conductive layer 114 with the insulating layer 556 therebetween.

As illustrated in FIGS. 4B and 4C and FIG. 5A, the conductive layer 114, the insulating layer 482, the insulating layer 556, and the charge-accumulation layer 555 are preferably provided so as to have top surfaces substantially level with each other.

The insulating layer 483 includes the opening portion 590e. The opening portion 590e overlaps with the opening portion 590c in the plan view. The opening portion 590e is preferably surrounded by the opening portion 590c in the plan view.

The conductive layer 540 includes the opening portion 590f. The opening portion 590f overlaps with the opening portion 590c in the plan view. The opening portion 590f is preferably surrounded by the opening portion 590c in the plan view.

A side surface of the opening portion 590e and a side surface of the opening portion 590f are preferably connected smoothly. This allows the insulating layer, the conductive layer, the semiconductor layer, and the like to be formed on the side surfaces of the opening portions 590e and 590f with high coverage.

The insulating layer 554 covers the side surface of the opening portion 590e of the insulating layer 483 and the side surface of the opening portion 590f of the conductive layer 540. The insulating layer 554 is preferably in contact with the side surface of the opening portion 590e of the insulating layer 483 and the side surface of the opening portion 590f of the conductive layer 540. The insulating layer 554 covers the side surface of the opening portion 590c of the insulating layer 481 and the side surface of the opening portion 590d of the conductive layer 114 with the charge-accumulation layer 555 and the insulating layer 556 therebetween.

The oxide semiconductor layer 530 includes a region in contact with the top surface of the conductive layer 520 in the opening portion 590c. The oxide semiconductor layer 530 includes a region in contact with the top surface of the conductive layer 540. The oxide semiconductor layer 530 covers the insulating layer 554 in the opening portion 590c, the opening portion 590d, the opening portion 590e, and the opening portion 590f.

The insulating layer 551, the charge-accumulation layer 552, and the insulating layer 553 are provided in this order over the oxide semiconductor layer 530. The conductive layer 560 is provided over the insulating layer 553.

The conductive layer 560 includes a region facing the conductive layer 114 with the oxide semiconductor layer 530 therebetween in the opening portion 590e.

In FIGS. 4A to 4C, the insulating layer 554 includes a region overlapping with the top surface of the conductive layer 520 and includes an opening portion 290c overlapping with the conductive layer 520. When the opening portion 290c is provided in the insulating layer 554, the oxide semiconductor layer 530 can be in contact with the conductive layer 520 with the opening portion 290c therebetween.

In the semiconductor device of one embodiment of the present invention, a metal oxide functioning as a semiconductor (also referred to as an oxide semiconductor) can be used for the oxide semiconductor layer 530.

A region of the oxide semiconductor layer 530 that is in contact with the conductive layer 520 and the conductive layer 540 preferably functions as a low-resistance region.

The oxide semiconductor layer 530 is provided inside the opening portion 590c of the insulating layer 481, inside the opening portion 590d of the conductive layer 114, and inside the opening portion 590e of the insulating layer 483. The transistor 500 has a structure in which a current flows in the vertical direction since one of a source electrode and a drain electrode (here, the conductive layer 520) is positioned below and the other of the source electrode and the drain electrode (here, the conductive layer 540) is positioned above.

Information is written to the transistor 500 by changing the amount of electric charge accumulated in the charge-accumulation layer. Carriers such as electrons and holes can be accumulated in the charge-accumulation layer. A conductor can be used for the charge-accumulation layer, for example. In the case where a conductor is used for the charge-accumulation layer, the conductor is preferably surrounded by an insulator. Alternatively, an insulator having a function of trapping carriers can be used for the charge-accumulation layer, for example. For example, when a positive high potential is applied to a gate with reference to a source or a drain, electrons are injected from the oxide semiconductor layer 530 through the insulating layer between the oxide semiconductor layer and the charge-accumulation layer and accumulated in the charge-accumulation layer. For another example, when a negative high potential is applied to the gate with reference to the source or the drain, electrons are released from the charge-accumulation layer to the oxide semiconductor layer 530 through the insulating layer. The charge-accumulation layer can retain the accumulated electric charge.

When the oxide semiconductor layer 530 is in contact with not only the side surface but also the top surface of the conductive layer 540, the area where the oxide semiconductor layer 530 and the conductive layer 540 are in contact with each other can be increased as compared with the case where the oxide semiconductor layer 530 is not in contact with the top surface of the conductive layer 540 but in contact with the side surface of the conductive layer 540, for example. Thus, the contact resistance between the oxide semiconductor layer 530 and the conductive layer 540 can be reduced.

In the transistor 500, the charge-accumulation layer 552 covers both the side surface and the top surface of the conductive layer 540, so that the area where the charge-accumulation layer 552 covers the conductive layer 540 can be larger than that in the case where the charge-accumulation layer 552 covers only one of the side surface and the top surface of the conductive layer 540. In the case where carrier injection from the oxide semiconductor layer 530 to the charge-accumulation layer 552 is induced by the electric field between the gate and the drain at the time of writing data to the transistor 500, writing efficiency can be increased by increasing the area where the charge-accumulation layer 552 covers the conductive layer 540. The structure of the transistor of one embodiment of the present invention can increase the writing efficiency as compared with that of a planar transistor.

In a planar transistor in which an island-shaped semiconductor layer is formed, an end portion of the island-shaped semiconductor layer is included at the boundary between a channel formation region and a drain formation region. In the case where heat or the like is generated due to a current flowing through the transistor, heat generation might significantly affect the end portion of the island-shaped semiconductor layer in the channel width direction. Such heat generation might cause a decrease in withstand voltage, and the influence is more significant in some cases in a transistor that has a large channel width and thus has a large amount of current. Meanwhile, the transistor 500, in which the semiconductor layer can be provided along the sidewall of the opening portion of the insulating layer, can have a structure in which the semiconductor layer does not have an end portion at the boundary between the channel formation region and the drain formation region. As a result, the source-drain resistance of the transistor can be increased. This can also increase the withstand voltage between the gate and the drain or between the gate and the source. Thus, deterioration of the transistor can be inhibited to improve the reliability of the memory element even in the case where a high electric field is applied between the drain and the source, between the gate and the source, between the gate and the drain, and the like in writing and erasing.

In the semiconductor device illustrated in FIGS. 4A to 4C, an end portion of the charge-accumulation layer 552 is positioned outward from an end portion of the conductive layer 560 in the cross section illustrated in FIG. 4C. That is, the end portion of the charge-accumulation layer 552 is positioned outward from the end portion of the conductive layer 560 in the direction along the Y axis, and a top surface of the charge-accumulation layer 552 includes a region not covered with the conductive layer 560. With the structure illustrated in FIG. 4C, the insulating layer 551, the charge-accumulation layer 552, and the insulating layer 553 are sandwiched between the conductive layer 560 and the conductive layer 540, so that a leakage current between the conductive layer 560 and the conductive layer 540 can be inhibited.

Meanwhile, in the cross section in FIG. 4B, the end portion of the charge-accumulation layer 552 is positioned inward from the end portion of the conductive layer 560. This is because the conductive layer 560 extends in the direction along the X-axis.

Also in the direction along the Y-axis, the end portion of the charge-accumulation layer 552 may be positioned inward from the end portion of the conductive layer 560. Such a structure can increase the area where the charge-accumulation layer 552 and the conductive layer 560 overlap with each other and increase the capacitance value between the charge-accumulation layer 552 and the conductive layer 560. An increase in the capacitance value reduces the voltage required for writing, which sometimes increases the efficiency of writing to the memory element.

The area occupied by the transistor 500, specifically, the area of the transistor seen from above, for example, is roughly determined by the width of the opening portion 590c of the insulating layer 481, the width of the opening portion 590e of the insulating layer 483, and the like. Since the channel formation region, the source region, and the drain region of the transistor 500 can be arranged at different levels, the area occupied by the transistor 500 can be smaller than that of a transistor in which a semiconductor layer, a channel formation region, a source region, and a drain region are placed on a plane. Thus, the semiconductor device can be highly integrated. The use of the semiconductor device of one embodiment of the present invention can increase the memory capacity per unit area.

In the transistor 500, the conductive layer 520 functioning as one of the source electrode and the drain electrode and the conductive layer 540 functioning as the other are provided at different levels. The conductive layer 520 can be shared by a plurality of transistors 500, and the conductive layer 540 can also be shared by a plurality of transistors 500. The conductive layer shared by a plurality of transistors can be extended to be used as a wiring.

Since the conductive layer 520 and the conductive layer 540 are provided at different levels in the semiconductor device of one embodiment of the present invention, even in the case where the conductive layer 520 and the conductive layer 540 are extended to be used as wirings, the wiring using the conductive layer 520 and the wiring using the conductive layer 540 can be arranged to intersect with each other without being short-circuited. Accordingly, the area of the memory cell can be reduced.

FIG. 5B illustrates a cross section along the XY plane including the insulating layer 481. The oxide semiconductor layer 530 surrounds the entire periphery of the conductive layer 560 with the insulating layer 551, the charge-accumulation layer 552, and the insulating layer 553 therebetween. When a gate electric field is applied from the conductive layer 560, the channel formation region of the transistor 500 can be formed in the whole oxide semiconductor layer 530 surrounding the periphery of the conductive layer 560. Note that FIG. 5B can be regarded as a cross-sectional view along the XY plane including the channel formation region of the oxide semiconductor layer 530.

The conductive layer 114 surrounds the periphery of the oxide semiconductor layer 530 with the insulating layer 554, the charge-accumulation layer 555, and the insulating layer 556 therebetween. When a gate electric field is applied from the conductive layer 114, the channel formation region of the transistor 500 can be formed in the whole oxide semiconductor layer 530 surrounded by the conductive layer 114.

FIG. 5A is an enlarged view of FIG. 4B. The channel length of the transistor 500 is the distance between the source region and the drain region. That is, the channel length of the transistor 500 is determined by the sum of the thickness of the insulating layer 481 over the conductive layer 520 and the thicknesses of the insulating layer 483 and the conductive layer 114. In FIG. 5A, a channel length L of the transistor 500 is indicated by a dashed double-headed arrow. The channel length L is the distance between an end portion of a region where the oxide semiconductor layer 530 and the conductive layer 520 are in contact with each other and an end portion of a region where the oxide semiconductor layer 530 and the conductive layer 540 are in contact with each other in a cross-sectional view. That is, the channel length L roughly corresponds to the sum of the length of a side surface of the opening portion 590c of the insulating layer 481, the length of a side surface of the opening portion 590d of the conductive layer 114, the length of a side surface of the opening portion 590e of the insulating layer 483, and the length of a side surface of the opening portion 590f of the conductive layer 540 in the cross-sectional view.

The width of the opening portion 590c is referred to as a width D. The width of the opening portion 590e is referred to as a width D2. The width D and the width D2 sometimes vary in the depth direction. For example, the width D and the width D2 can each be the width of an upper end of the opening portion of the insulating layer. Alternatively, the width D and the width D2 can each be the width of a lower end of the opening portion of the insulating layer. Alternatively, the width D and the width D2 can each be the width at half of the depth of the opening portion of the insulating layer.

The sidewalls of the opening portion 590c, the opening portion 590e, and the like preferably have an angle perpendicular or substantially perpendicular to a top surface of the formation surface of the layer including the opening portion (in the case where the top surface of the formation surface has unevenness, a top surface of a layer below the formation surface with little unevenness or a top surface of the substrate surface). Such a shape of the opening portion can reduce the area occupied by the transistor 500. Thus, the semiconductor device can be miniaturized.

The angle between the top surface of the conductive layer 520 (or a top surface of the insulating layer 210 or the top surface of the substrate) and the sidewall of the opening portion 590c in the insulating layer 481 is referred to as an angle θ481. The angle between the top surface of the conductive layer 520 (or the top surface of the insulating layer 210, the top surface of the substrate, or a top surface of the conductive layer 114) and the sidewall of the opening portion 590e in the insulating layer 483 is referred to as an angle θ483. Each of θ481 and θ483 is preferably 90° or close to 90°. For example, each of θ481 and θ483 is preferably greater than or equal to 75° and less than or equal to 90°.

Each of θ481 and θ483 may be less than 75°, less than 70°, less than 65°, or less than 60°. When the sidewall of the opening portion has a tapered shape, coverage with a film formed on the sidewall of the opening portion can be improved.

The minimum channel length of a planar transistor is limited by the light exposure accuracy of photolithography, and further miniaturization is difficult. In the semiconductor device of one embodiment of the present invention, the channel length of the transistor corresponds to the thicknesses of the insulating layers 481, 483, and the like. Thus, the channel length can be less than the minimum value that is limited by the light exposure accuracy of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 500 can have a higher on-state current and the memory element can have higher response speed.

Since the channel length of the transistor included in the semiconductor device of one embodiment of the present invention is determined by the thicknesses of the insulating layer 481 over the conductive layer 520, the insulating layer 483, and the like, even when the channel length is set greater than or equal to 60 nm, for example, the area occupied by the transistor, specifically, the area of the transistor seen from the above is roughly determined by, for example, the width of the opening portion provided in the insulating layer 481, the insulating layer 483, and the like. As described later, the width D2 of the opening portion 590e is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. For example, even in the case where the channel length is 150 nm, the width of the opening portion 590e can be shorter than 150 nm. That is, a transistor having a width of the opening portion shorter than the channel length can be obtained, in which case the area occupied by the transistor can be reduced and the semiconductor device can be highly integrated. A longer channel length increases the withstand voltage between the source and the drain at the time of writing to the memory element, thereby improving the reliability.

When the channel length of the transistor is, for example, less than or equal to 1 μm, less than or equal to 500 nm, or less than or equal to 300 nm, the productivity, yield, and the like can be improved in formation of the insulating layers 481 and 483 and formation of the opening portions in the insulating layers 481 and 483, for example.

Thus, the channel length of the transistor included in the semiconductor device of one embodiment of the present invention is preferably greater than or equal to 0.1 nm, greater than or equal to 1 nm, or greater than or equal to 5 nm, and less than or equal to 1 μm, less than or equal to 500 nm, or less than or equal to 300 nm.

A high voltage is sometimes applied between the drain and the source of the transistor 500 in data writing and erasing. Thus, the transistor 500 preferably has a channel length long enough to withstand a high voltage between the drain and the source. The channel length of the transistor 500 may be greater than or equal to 10 nm, greater than or equal to 20 nm, or greater than or equal to 30 nm, for example. As described above, the area occupied by the transistor 500 is roughly determined by the width of the opening portion 590c or the like and is hardly influenced by an increase in the channel length of the transistor. In other words, the transistor 500 has a structure that achieves both high withstand voltage and integration.

As illustrated in FIG. 5B, the oxide semiconductor layer 530 and the conductive layer 560 are provided concentrically. Therefore, the side surface of the conductive layer 560 provided at the center faces a side surface of the oxide semiconductor layer 530. That is, in the plan view, all the perimeter of the oxide semiconductor layer 530 serves as the channel formation region. In this case, for example, the channel width of the transistor 500 is determined by the length of the perimeter of the oxide semiconductor layer 530. In other words, the channel width of the transistor 500 is determined by the width of the opening portion 590e, 590f, or the like (the diameter in the case where the opening portion is circular in the plan view). In FIG. 5B, a channel width W of the transistor 500 is indicated by a dashed-dotted double-headed arrow. By increasing the width D2 of the opening portion 590e, the channel width per unit area can be increased and the on-state current can be increased.

In the case where the opening portion is formed by a photolithography method, the minimum value of the width D2 of the opening portion 590e is limited by the light exposure accuracy of photolithography. The width D2 of the opening portion 590e is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion is circular in the plan view, the width D2 of the opening portion corresponds to the diameter of the opening portion, and the channel width W can be calculated to be “D2×π”. In FIG. 5B and the like, the width D of the opening portion 590c is a value obtained by adding twice the thickness of the charge-accumulation layer 555 and twice the thickness of the insulating layer 556 to the width D2.

When the channel length L of the transistor 500 is smaller than the channel width W of the transistor 500, the current drive capability of the transistor can be increased, and accordingly, the writing speed of the memory element can be increased, for example.

When the channel length L of the transistor 500 is larger than the channel width W of the transistor 500, the withstand voltage between the source and the drain of the transistor can be increased, and accordingly, the rewrite endurance of the memory element can be increased, for example.

When the opening portions 590c, 590f, and 590e are each formed to be circular in the plan view, the oxide semiconductor layer 530 and the conductive layer 560 are formed concentrically. This allows an electric field from the conductive layer 560 to be substantially uniformly applied to the oxide semiconductor layer 530. When the opening portion 590f is formed to be circular, the oxide semiconductor layer 530 and opening portion of the conductive layer 114 are formed concentrically. This allows an electric field from the conductive layer 114 to be substantially uniformly applied to the oxide semiconductor layer 530.

Although this embodiment shows an example in which the opening portions 590c, 590f, 590e, and the like are each circular in the plan view, one embodiment of the present invention is not limited thereto. For example, the opening portion may have, in the plan view, an almost circular shape such as an ellipse, a polygonal shape such as a square, or a polygonal shape with rounded corners such as a square with rounded corners. The shape with no corners, such as a circular shape or an almost circular shape, or the polygonal shape with rounded corners can inhibit concentration of electric fields from the conductive layers 560 and 114 on the corner portion of the oxide semiconductor layer 530.

Note that as illustrated in FIG. 5C, the conductive layer 520 may have a depressed portion. In FIG. 5C, the conductive layer 520 has a depressed portion overlapping with the opening portion 590c. The opening portion 590c and the depressed portion of the conductive layer 520 form a continuous opening portion. The oxide semiconductor layer 530 is provided along a bottom portion and a side surface of the depressed portion of the conductive layer 520. Thus, the electric field of a drain can be received from the bottom direction and the side direction, and accordingly, the writing efficiency can be improved.

FIG. 5D illustrates an example in which the conductive layer 520 has a deeper depressed portion. In FIG. 5D, at least parts of the oxide semiconductor layer 530, the insulating layer 551, the charge-accumulation layer 552, the insulating layer 553, and the conductive layer 560 are formed in the depressed portion. With such a structure, the gate electric field of the conductive layer 560 can be easily applied to the oxide semiconductor layer 530 in the vicinity of the conductive layer 520.

In FIG. 5D, the conductive layer 520 and the conductive layer 560 have a region where they overlap with each other with the oxide semiconductor layer 530, the insulating layer 551, the charge-accumulation layer 552, and the insulating layer 553 therebetween. As a result, a gate electric field is easily applied to the channel formation region of the oxide semiconductor layer 530, for example, so that the writing voltage of the memory element can be reduced in some cases. Thus, the power consumption of the semiconductor device can be reduced in some cases.

When the thickness of the insulating layer 551 is reduced, the voltage of the first control gate at the time of writing to the transistor 500 can be reduced. Similarly, when the thickness of the insulating layer 554 is reduced, the voltage of the second control gate at the time of writing to the transistor 500 can be reduced. A reduction in voltage can reduce the power consumption of the memory device. In addition, the time required for writing can be shortened. Consequently, the operation speed of the memory device can be increased.

Meanwhile, in the case where the insulating layer 551 has a too small thickness, carriers accumulated in the charge-accumulation layer 552 might be reduced by a leakage current. Similarly, in the case where the insulating layer 554 has a too small thickness, carriers accumulated in the charge-accumulation layer 555 might be reduced by a leakage current. A reduction in carriers due to a leakage current degrades the retention characteristics of the memory device.

Thus, the thickness of each of the insulating layers 551 and 554 can be greater than or equal to 1 nm and less than or equal to 20 nm, for example. For the insulating layers 551 and 554, silicon oxide, silicon oxynitride, silicon nitride oxide, silicon nitride, aluminum oxide, or the like is preferably used.

The insulating layer 553 preferably has a larger thickness than the insulating layer 551, for example. This can reduce a tunnel current flowing through the insulating layer 553 and inhibit electric charge in the charge-accumulation layer 552 from running to the first control gate side. Similarly, the insulating layer 556 preferably has a larger thickness than the insulating layer 554, for example. The thicknesses of the insulating layers 553 and 556 can each be, for example, greater than or equal to 8 nm and less than or equal to 30 nm. For the insulating layers 553 and 556, silicon oxide, silicon oxynitride, aluminum oxide, hafnium oxide, or the like is preferably used, for example.

Materials that can be used for the charge-accumulation layers 552 and 555 will be described later.

### <Modification Example 1 of Semiconductor Device>

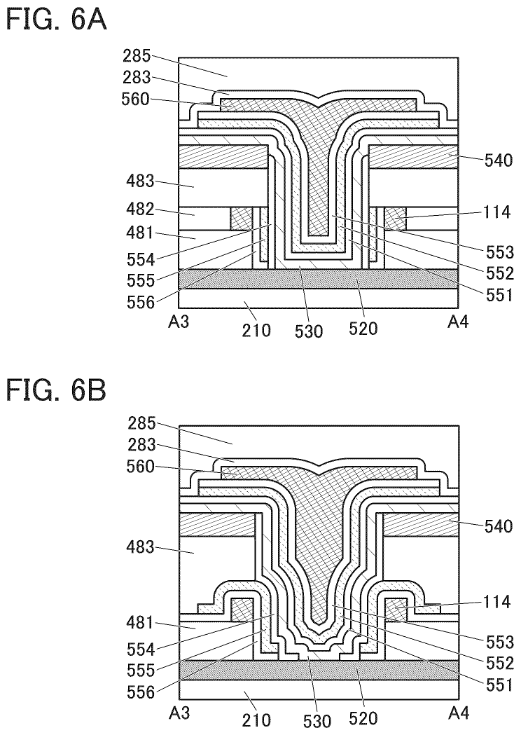

FIG. 6A illustrates a modification example of FIG. 4C. In the structure example illustrated in FIG. 6A, the insulating layer 554 is mainly provided along the sidewalls of the opening portions 590c, 590d, 590e, and 590f. The insulating layer 554 illustrated in FIG. 6A can be formed by anisotropic etching, for example. The insulating layer 554 illustrated in FIG. 6A can be referred to as a sidewall or a sidewall insulating layer.

As illustrated in FIG. 6A, the top end of the insulating layer 554 can be at a lower level than the top surface of the conductive layer 540. Such a structure enables the oxide semiconductor layer 530 to be in contact with not only the top surface but also the side surface of the conductive layer 540.

Note that in the structures illustrated in FIGS. 4B and 4C, FIG. 6A, and the like, the top end of the charge-accumulation layer 555 is substantially level with the top end of the conductive layer 114. This offers a structure in which the charge-accumulation layer 555 is not provided in a region other than the region between the conductive layer 114 and the oxide semiconductor layer 530.

### <Modification Example 2 of Semiconductor Device>

By contrast, as illustrated in FIG. 6B, the top end of the charge-accumulation layer 555 is not necessarily substantially level with the top end of the conductive layer 114, and the charge-accumulation layer 555 may be provided also over the conductive layer 114. In the example illustrated in FIG. 6B, the insulating layer 482 is not provided.

In FIG. 4C, the conductive layer 114, the charge-accumulation layer 555, the insulating layer 556, and the insulating layer 482 are provided so as to have top surfaces substantially level with each other; meanwhile, in FIG. 6B, the charge-accumulation layer 555 and the insulating layer 556 include a region covering the top surface of the conductive layer 114. In FIG. 6B, there is a step between the sidewall of the charge-accumulation layer 555 and the sidewall of the insulating layer 483.

The structure illustrated in FIG. 6B does not need the following steps: the step of forming the insulating layer 482; the step of processing the conductive layer 114, the charge-accumulation layer 555, the insulating layer 556, and the insulating layer 482 so as to have top surfaces substantially aligned with each other; and the step of reducing the step between the sidewall of the charge-accumulation layer 555 and the sidewall of the insulating layer 483 as much as possible. As a result, the manufacturing process can be simplified and the manufacturing cost can be reduced. By contrast, in the structure illustrated in FIG. 4C and the like, the charge-accumulation layer 555 is provided only in the region between the conductive layer 114 and the oxide semiconductor layer 530, and a uniform electric field is easily applied from the conductive layer 114 to the charge-accumulation layer 555, so that the reliability of the memory element can be increased.

### <Structure Example of Memory Cell Array>

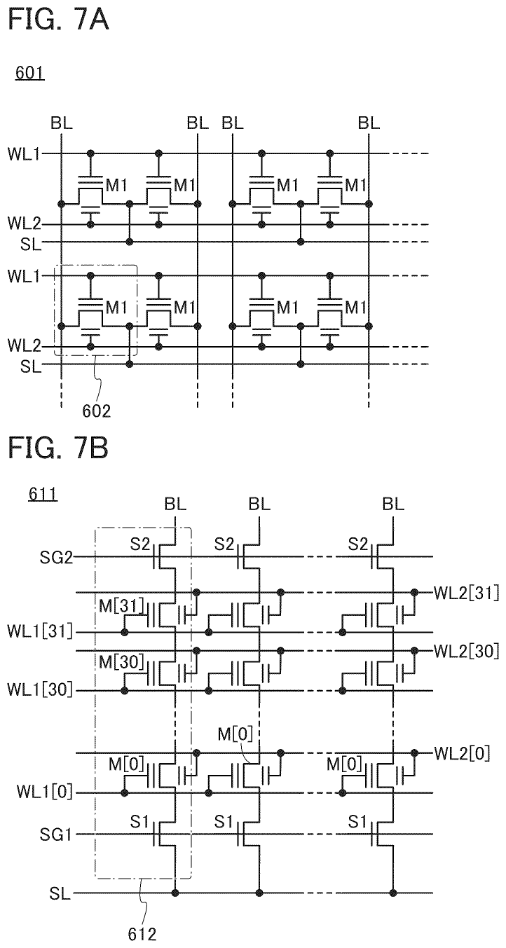

An application example of a memory cell including the transistor 500 is described with reference to FIGS. 7A and 7B.

FIG. 7A illustrates an example of a circuit diagram of a memory cell array 601 including a plurality of NOR-type memory cells 602. Each of the memory cells 602 includes the transistor M1. The transistor 500 described above can be used as the transistor M1.

In the memory cell 602, one of a source and a drain of the transistor M1 is connected to a wiring BL, and the other is connected to a wiring SL. A first control gate of the transistor M1 is connected to a wiring WL1, and a second control gate of the transistor M1 is connected to a wiring WL2. The wirings WL1 and WL2 function as word lines, and the wiring BL functions as a bit line.

The memory cell array 601 includes a plurality of wirings BL, a plurality of wirings SL, a plurality of wirings WL1, and a plurality of wirings WL2. One of the wirings BL is connected to the transistors M1 included in a plurality of memory cells 602 arranged in the same column. One of the wirings SL is connected to the transistors M1 included in a plurality of memory cells 602 arranged in the same row. One of the wirings WL1 is connected to the transistors M1 included in a plurality of memory cells 602 arranged in the same row. One of the wirings WL2 is connected to the transistors M1 included in a plurality of memory cells 602 arranged in the same row.

In each of the transistors M1 included in the plurality of memory cells 602 arranged in the same row, the same signal can be supplied to the control gate and one of the source and the drain. In the case where the transistor M1 is an n-channel transistor, for example, when a negative potential is supplied to one of the source and the drain with reference to the control gate, data can be erased at a time in the plurality of memory cells 602 arranged in the same row.

FIG. 7B illustrates an example of a circuit diagram of a memory cell array 611 including a plurality of NAND-type memory cells 612. Each of the memory cells 612 includes a transistor M[0] to a transistor M[31], a transistor S1, and a transistor S2 which are connected in series. The transistor 500 described above can be used as each of the transistor M[0] to the transistor M[31].

In each of the transistor M[0] to the transistor M[31], the transistor S1, and the transistor S2, hereinafter, one of a source and a drain is referred to as a first terminal, and the other of the source and the drain is referred to as a second terminal. A first terminal of a transistor M[k] is connected to a second terminal of a transistor M[k−1], and a second terminal of the transistor M[k] is connected to a first terminal of the transistor M[k+1]. Here, k is an integer greater than or equal to 2 and less than or equal to 30.

A first terminal of the transistor S1 is connected to the wiring SL, and a second terminal of the transistor S1 is connected to a first terminal of the transistor M[0]. A first terminal of the transistor S2 is connected to a second terminal of the transistor M[31], and a second terminal of the transistor S2 is connected to the wiring BL.

The memory cell array 611 includes a plurality of wirings BL, each of which is connected to one memory cell 612. The memory cell array 611 includes a wiring SG1, a wiring SG2, a wiring WL1[0] to a wiring WL1[31], and a wiring WL2[0] to a wiring WL2[31].

Gates of the transistors S1 in a plurality of memory cells 612 are connected to the wiring SG1. Gates of the transistors S2 in the plurality of memory cells 612 are connected to the wiring SG2. First gates of the transistor M[0] to the transistor M[31] in the plurality of memory cells 612 are connected to the wiring WL1[0] to the wiring WL1[31], respectively. Second gates of the transistor M[0] to the transistor M[31] in the plurality of memory cells 612 are connected to the wiring WL2[0] to the wiring WL2[31], respectively.

The wiring SG1 and the wiring SG2 function as wirings for selecting the memory cells 612 when operations such as writing, reading, and erasing are performed.

Although FIGS. 6A and 6B each illustrate a structure in which one memory cell 612 is connected to one wiring, one embodiment of the present invention is not limited thereto.

### <Operation Example 1-1 of Semiconductor Device>

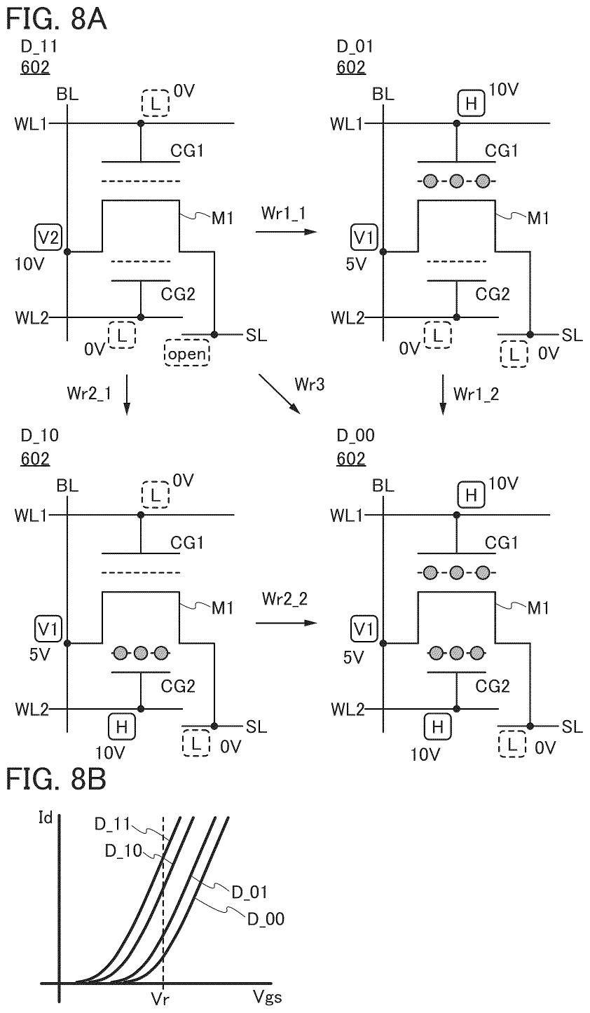

An operation example of the semiconductor device of one embodiment of the present invention is described with reference to FIG. 8A to FIG. 17D.

FIG. 8A illustrates four states of the memory cell 602. Specifically, four pieces of data, data D_11, data D_01, data D_10, and data D_00, are held in the respective four states. FIG. 8B shows an example of the I_{d}-V_{gs} curves of the transistor M1 in the states where the four pieces of data are held. The drain current I_{d} is a drain current of the transistor M1, and the voltage V_{gs} is a voltage between the gate and the source of the transistor M1. The threshold value of the transistor is changed by the held data. Thus, when the gate-source voltage V_{gs} has a predetermined value (Vᵣ in FIG. 8B), the drain current I_{d} changes in accordance with the held state. By reading the drain current I_{d}, the held data can be determined.

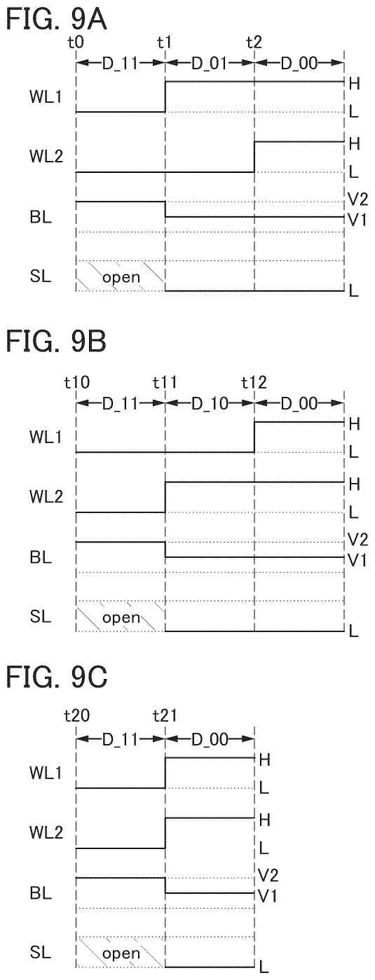

FIGS. 9A to 9C are timing charts corresponding to the operations of the memory cell 602.

First, an operation example of the semiconductor device is described with reference to FIGS. 8A and 9A.

In the memory cell 602 illustrated in FIG. 8A and the like, the wiring WL1 is connected to the first control gate (denoted by CG1 in the drawing), and the wiring WL2 is connected to the second control gate (denoted by CG2 in the drawing). The wiring BL is connected to one of the source and the drain, and the wiring SL is connected to the other of the source and the drain.

### [Data D_11]

In FIG. 9A, at Time t0 where the data D_11 is held, a low potential L, the low potential L, and a potential V2 are supplied to the wiring WL1, the wiring WL2, and the wiring BL, respectively. The wiring SL is in a floating state. The state at Time t0 corresponds to a state where the data D_11 is held in FIG. 8A (the memory cell 602 shown on the upper left). At this time, electric charge is not accumulated in a charge-accumulation layer (hereinafter referred to as a first charge-accumulation layer) positioned between the first control gate and the semiconductor layer. Similarly, electric charge is not accumulated in a charge-accumulation layer (hereinafter referred to as a second charge-accumulation layer) positioned between the second control gate and the semiconductor layer.

### [Operation Wr1_1: Data D_01]

Next, at Time t1 shown in FIG. 9A, the potential supplied to the wiring WL1 is changed from the low potential L to a high potential H, the potential supplied to the wiring BL is changed from the potential V2 to a potential V1, and the low potential L is supplied to the wiring SL, so that the state where the data D_11 is held can be changed into the state where the data D_01 is held (the memory cell 602 shown on the upper right in FIG. 8A) (Operation Wr1_1). The data D_01 means a state where electric charge is accumulated in the first charge-accumulation layer. Note that the electric charge accumulated in the charge-accumulation layer is an electron, for example, in the following description.

### [Operation Wr1_2: Data D_00]

Next, at Time t2 shown in FIG. 9A, the potential supplied to the wiring WL2 is changed from the low potential L to the high potential H, so that the state where the data D_01 is held can be changed into the state where the data D_00 is held (the memory cell 602 shown on the lower right in FIG. 8A) (Operation Wr1_2). The data D_00 means a state where electric charge is accumulated in the first charge-accumulation layer and the second charge-accumulation layer.

### <Operation Example 1-2 of Semiconductor Device>

Although FIG. 9A illustrates an example in which electric charge is accumulated in the first charge-accumulation layer and the second charge-accumulation layer in this order, electric charge may be accumulated in the second charge-accumulation layer and the first charge-accumulation layer in this order by the operation shown in FIG. 9B.

### [Data D_11]

At Time t10 shown in FIG. 9B, the data D_11 is held like at Time t0 shown in FIG. 9A.

### [Operation Wr2_1: Data D_10]

At Time t11 shown in FIG. 9B, the potential supplied to the wiring WL2 is changed from the low potential L to the high potential H, the potential supplied to the wiring BL is changed from the potential V2 to the potential V1, and the low potential L is supplied to the wiring SL, so that the state where the data D_11 is held can be changed into the state where the data D_10 is held (the memory cell 602 shown on the lower left in FIG. 8A) (Operation Wr2_1). The data D_10 means a state where electric charge is accumulated in the second charge-accumulation layer.

### [Operation Wr2_2: Data D_00]

Next, at Time t12 shown in FIG. 9B, the potential supplied to the wiring WL1 is changed from the low potential L to the high potential H, so that the state where the data D_10 is held can be changed into the state where the data D_00 is held (Operation Wr2_2).

### <Operation Example 1-3 of Semiconductor Device>

Although FIGS. 9A and 9B illustrate examples in which electric charge is supplied to the first charge-accumulation layer and the second charge-accumulation layer at different timings, electric charge may be accumulated in the first charge-accumulation layer and the second charge-accumulation layer by the same operation shown in FIG. 9C.

### [Data D_11]

At Time t20 shown in FIG. 9C, the data D_11 is held like at Time t0 shown in FIG. 9A.

### [Operation Wr3: Data D_00]

At Time t21 shown in FIG. 9C, the potentials supplied to the wiring WL1 and the wiring WL2 are changed from the low potential L to the high potential H, the potential supplied to the wiring BL is changed from the potential V2 to the potential V1, and the low potential L is supplied to the wiring SL, so that the state where the data D_11 is held can be changed into the state where the data D_00 is held (Operation Wr3).

Note that in FIG. 8A, FIGS. 9A to 9C, and the like, the voltages of the low potential L, the high potential H, the potential V1, and the potential V2 are 0 V, 10 V, 5 V, and 10 V, respectively, but are not limited thereto.

Note that when electric charge is accumulated in the charge-accumulation layer in the transistor M1, the I_{d}-V_{gs} curve shifts to a positive voltage. In other words, a voltage needed for writing increases when electric charge is accumulated in the charge-accumulation layer.

Note that in the case where the transistor 500 described above is used as the transistor M1, the conductive layer 560 can be used as the control gate CG1, and the conductive layer 114 can be used as the control gate CG2, for example. Here, the area where the conductive layer 560 overlaps with the oxide semiconductor layer 530 is larger than the area where the conductive layer 114 overlaps with the oxide semiconductor layer 530. Accordingly, writing using the control gate CG1 is performed with higher efficiency.

It is thus preferable that after writing is performed using the control gate CG2, writing using the control gate CG1 capable of higher efficiency be performed while a voltage needed for writing is increased by shifting of the I_{d}-V_{gs} curve. That is, in some cases, the operation Wr2-1 and the operation Wr2-2 are preferably performed in this order rather than the above-described operation Wr1-1 and operation Wr1-2 are performed in this order in terms of efficiency.

### <Operation Example 2-1 of Semiconductor Device>

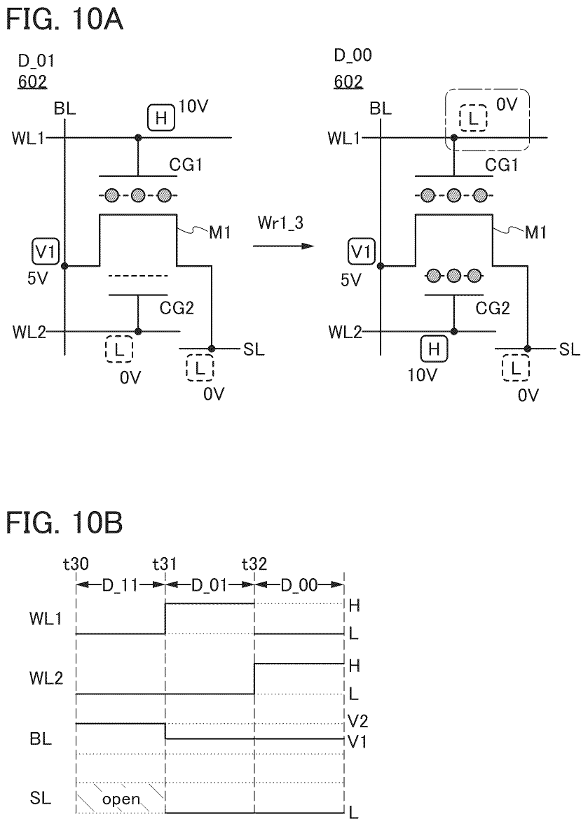

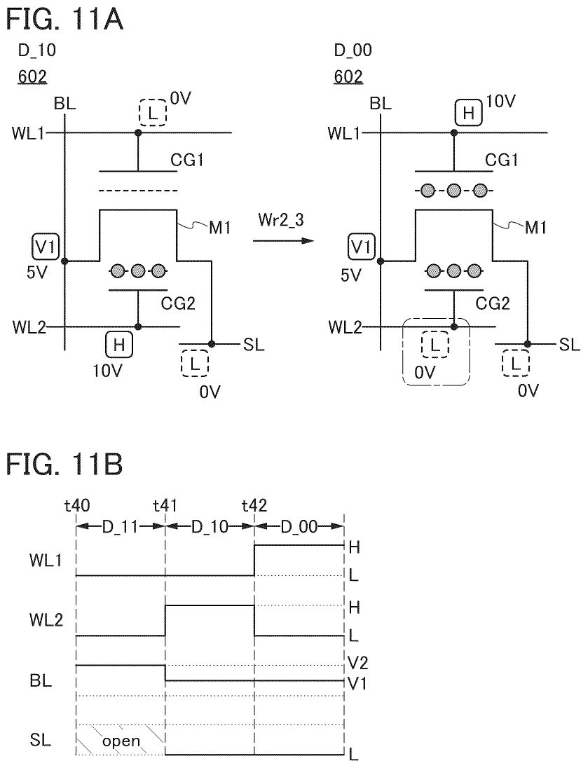

After electric charge is accumulated in the charge-accumulation layer, as shown in FIGS. 10A and 10B and FIGS. 11A and 11B, the voltage applied to the control gate is reduced while the held electric charge is prevented from being lost, whereby the power consumption of the semiconductor device can be reduced. In addition, the lifetime of the memory cell 602 can be increased in some cases.

FIG. 10A is a circuit diagram corresponding to the operation of the memory cell 602, and FIG. 10B is a timing chart corresponding to the operation illustrated in FIG. 10A.

### [Data D_11]

At Time t30 shown in FIG. 10B, the data D_11 is held like at Time t0 shown in FIG. 10A.

### [Data D_01]

Next, at Time t31 shown in FIG. 10B, the state where the data D_11 is held is changed into the state where the data D_01 is held. For the description of Time t30 to Time t31, the description of Time t0 to Time t1 in FIG. 9A can be referred to.

### [Data D_00]

Next, at Time t32 shown in FIG. 10B, the potential supplied to the wiring WL2 is changed from the low potential L to the high potential H, so that the state where the data D_01 is held can be changed into the state where the data D_00 is held. When the potential supplied to the wiring WL1 is changed from the high potential H to the low potential L at this time, the power consumption of the semiconductor device can be reduced. Here, the potential difference between the wiring WL1 and the wiring BL (the voltage difference between the low potential L and the potential V1) can have a value that prevents electric charge accumulated in the first charge-accumulation layer from being released (erased), i.e., a value that prevents the held data from being rewritten.

### <Operation Example 2-2 of Semiconductor Device>

FIG. 11A is a circuit diagram corresponding to the operation of the memory cell 602, and FIG. 11B is a timing chart corresponding to the operation shown in FIG. 11A.

### [Data D_11]

At Time t40 shown in FIG. 11B, the data D_11 is held like at Time t10 shown in FIG. 9B

### [Data D_10]

Next, at Time t41 shown in FIG. 11B, the state where the data D_11 is held is changed into the state where the data D_10 is held. For the description of Time t40 to Time t41, the description of Time t10 to Time t11 in FIG. 9B can be referred to.

### [Data D_00]

Next, at Time t42 shown in FIG. 11B, the potential supplied to the wiring WL1 is changed from the low potential L to the high potential H, so that the state where the data D_10 is held can be changed into the state where the data D_00 is held. When the potential supplied to the wiring WL2 is changed from the high potential H to the low potential L at this time, the power consumption of the semiconductor device can be reduced. Here, the potential difference between the wiring WL2 and the wiring BL (the voltage difference between the low potential L and the potential V1) can have a value that prevents electric charge accumulated in the second charge-accumulation layer from being released (erased), i.e., a value that prevents the held data from being rewritten.

### <Operation Example 3-1 of Semiconductor Device>

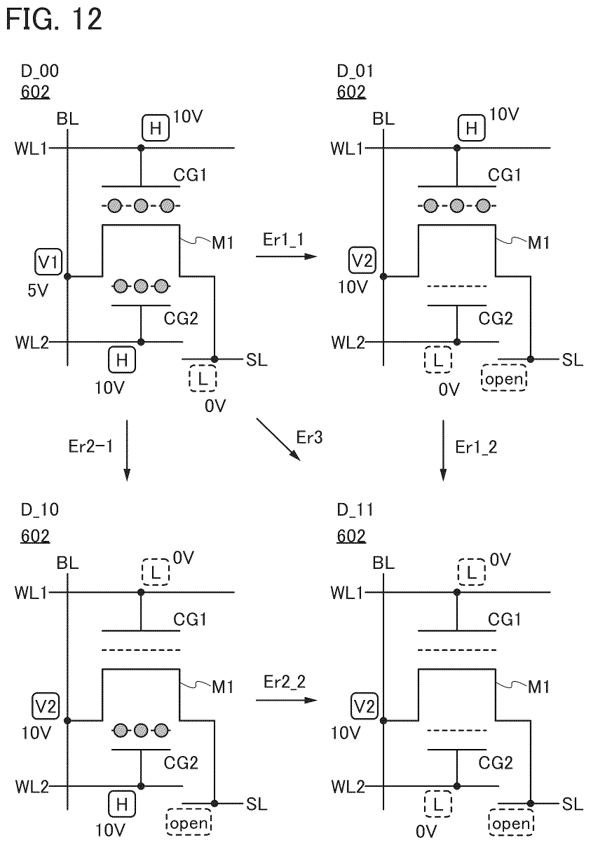

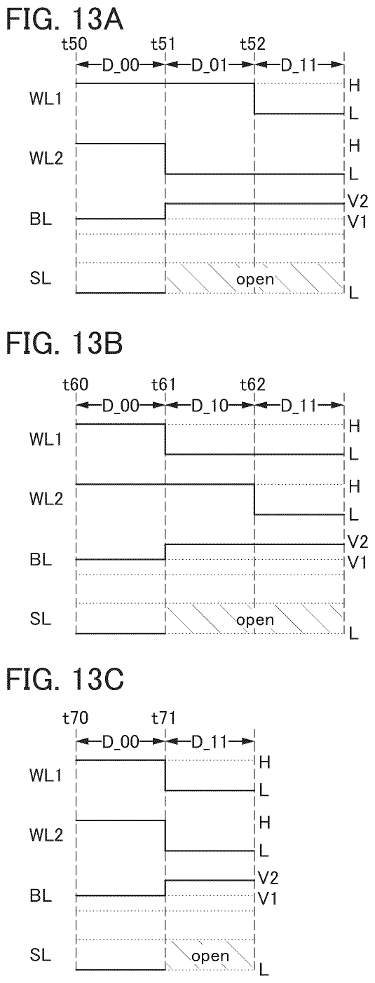

FIG. 12 illustrates four states of the memory cell 602 (in which four pieces of data, the data D_11, the data D_01, the data D_10, and the data D_00 are held). FIGS. 13A to 13C are timing charts corresponding to the operations of the memory cell 602. The operations shown in FIG. 12 and FIGS. 13A to 13C, in which electrons accumulated in the charge-accumulation layer are released, are referred to as erasing operations in some cases.

Although electron release is described here, holes may be accumulated in addition to or instead of electron release.

First, an operation example of the semiconductor device is described with reference to FIG. 12 and FIG. 13A.

### [Data D_00]

At Time t50 shown in FIG. 13A, the data D_00 is held. The data can be held by the operations shown in FIG. 8A to FIG. 11B.

### [Operation Er1_1: Data D_01]

Next, at Time t51 shown in FIG. 13A, the potential supplied to the wiring WL2 is changed from the high potential H to the low potential L, the potential supplied to the wiring BL is changed from the potential V1 to the potential V2, and the wiring SL is brought into a floating state, so that electric charge of the second charge-accumulation layer can be released, and the state where the data D_00 is held can be changed into the state where the data D_01 is held (the memory cell 602 shown on the upper right in FIG. 12) (Operation Er1_1).

### [Operation Er1_2: Data D_11]

Next, at Time t52 shown in FIG. 13A, the potential supplied to the wiring WL1 is changed from the high potential H to the low potential L, so that electric charge of the first charge-accumulation layer can be released, and the state where the data D_01 is held can be changed into the state where the data D_11 is held (the memory cell 602 shown on the lower right in FIG. 12) (Operation Er1_2).

### <Operation Example 3-2 of Semiconductor Device>

Although FIG. 13A illustrates an example in which electric charge is released from the second charge-accumulation layer and the first charge-accumulation layer in this order, electric charge may be released from the first charge-accumulation layer and the second charge-accumulation layer in this order by the operation shown in FIG. 13B.

### [Data D_00]

At Time t60 shown in FIG. 13B, the data D_00 is held like at Time t50 shown in FIG. 13A.

### [Operation Er2_1: Data D_10]

At Time t61 shown in FIG. 13B, the potential supplied to the wiring WL1 is changed from the high potential H to the low potential L, the potential supplied to the wiring BL is changed from the potential V1 to the potential V2, and the wiring SL is brought into a floating state, so that electric charge of the first charge-accumulation layer can be released, and the state where the data D_00 is held can be changed into the state where the data D_10 is held (the memory cell 602 shown on the lower left in FIG. 12) (Operation Er2_1).

### [Operation Er2_2: Data D_11]

Next, at Time t62 shown in FIG. 13B, the potential supplied to the wiring WL2 is changed from the high potential H to the low potential L, so that electric charge held in the second charge-accumulation layer can be released, and the state where the data D_10 is held can be changed into the state where the data D_11 is held (Operation Er2_2).

### <Operation Example 3-3 of Semiconductor Device>

Although FIGS. 13A and 13B illustrate examples in which electric charge is released from the first charge-accumulation layer and the second charge-accumulation layer at different timings, electric charge may be released from the first charge-accumulation layer and the second charge-accumulation layer by the same operation shown in FIG. 13C.

### [Data D_00]

At Time t70 shown in FIG. 13C, the data D_00 is held like at Time t50 shown in FIG. 13A.

### [Operation Er3: Data D_00]

At Time t71 shown in FIG. 13C, the potentials supplied to the wiring WL1 and the wiring WL2 are changed from the high potential H to the low potential L, the potential supplied to the wiring BL is changed from the potential V1 to the potential V2, and the wiring SL is brought into a floating state, so that the state where the data D_00 is held can be changed into the state where the data D_11 is held (Operation Er3).

### <Operation Example 4-1 of Semiconductor Device>

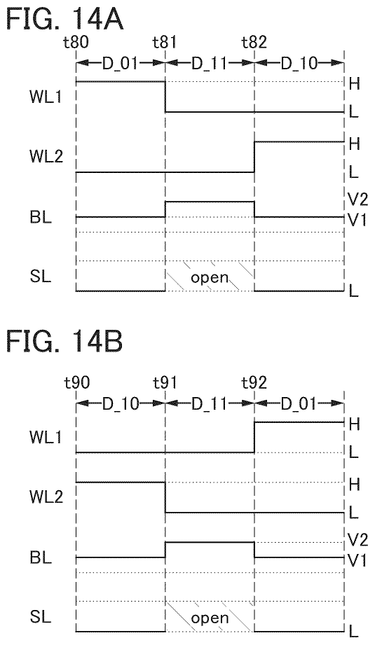

In the examples described above, data is rewritten from the state where the data D_00 is held; timing charts shown in FIGS. 14A and 14B show examples in which data is rewritten from the state where the data D_01 is held and the state where the data D_10 is held, respectively.

The timing chart in FIG. 14A is described.

### [Data D_01]

At Time t80, the data D_01 is held. The data can be held by the operations shown in FIG. 8A to FIG. 9C.

### [Data D_11]

Next, at Time t81, the potential supplied to the wiring WL1 is changed from the high potential H to the low potential L, the potential supplied to the wiring BL is changed from the potential V1 to the potential V2, and the wiring SL is brought into a floating state, so that the state where the data D_01 is held can be changed into the state where the data D_11 is held.

### [Data D_10]

Next, at Time t82, the state where the data D_11 is held is changed into the state where the data D_10 is held. For the description of Time t81 to Time t82, the description of Time t10 to Time t11 in FIG. 9B can be referred to.

### <Operation Example 4-2 of Semiconductor Device>

Next, the timing chart in FIG. 14B is described.

### [Data D_10]

At Time t90, the data D_10 is held. The data can be held by the operations shown in FIG. 8A to FIG. 9C.

### [Data D_11]

Next, at Time t91, the potential supplied to the wiring WL2 is changed from the high potential H to the low potential L, the potential supplied to the wiring BL is changed from the potential V1 to the potential V2, and the wiring SL is brought into a floating state, so that the state where the data D_10 is held can be changed into the state where the data D_11 is held.

### [Data D_01]

Next, at Time t92, the state where the data D_11 is held is changed into the state where the data D_01 is held. For the description of Time t91 to Time t92, the description of Time t0 to Time t1 in FIG. 9A can be referred to.

### <Operation Example 5-1 of Semiconductor Device>

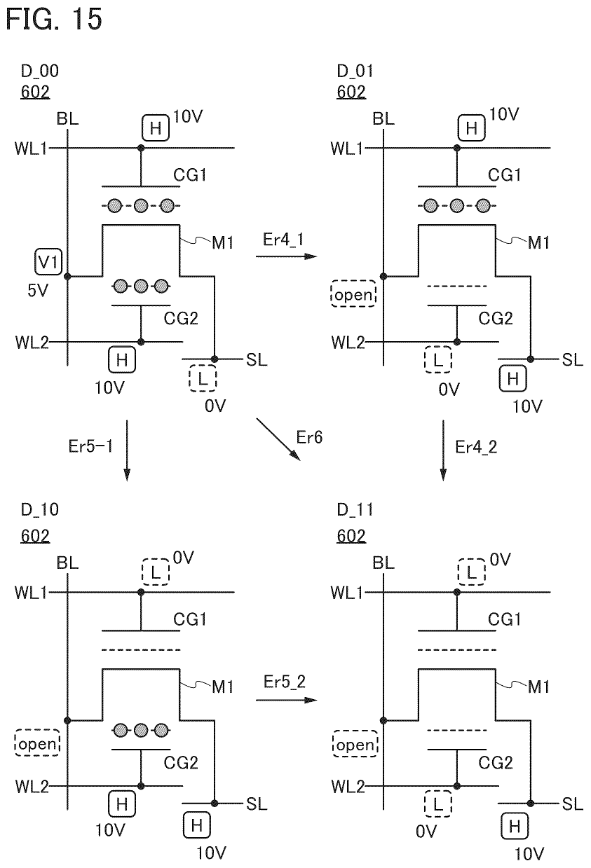

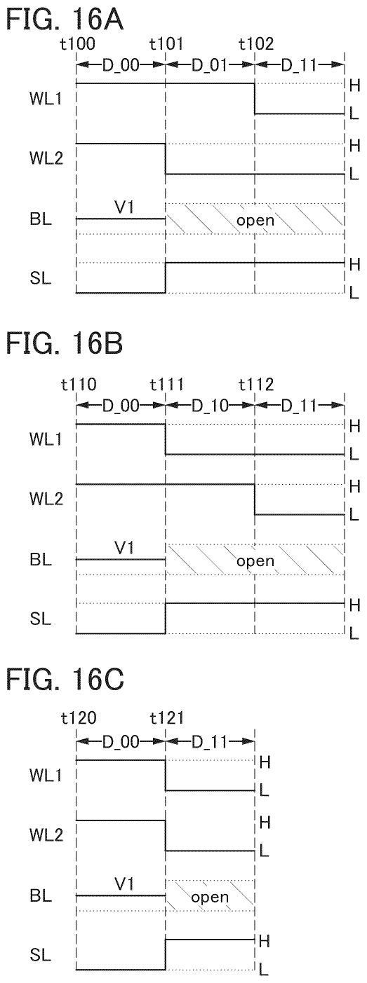

The operation examples shown in FIG. 15 and FIGS. 16A to 16C are different from those in FIG. 12 and FIGS. 13A to 13C mainly in that data to be held is changed using a change in the potential of the wiring SL. With the use of the wiring SL, data in the memory cells 602 positioned in the same row can be changed at a time. This operation is referred to as a collective erasing operation in some cases.

First, an operation example of the semiconductor device is described with reference to FIG. 15 and FIG. 16A.

### [Data D_00]

At Time t100 shown in FIG. 16A, the data D_00 is held (the memory cell 602 shown on the upper left in FIG. 15). The data can be held by the operations shown in FIG. 8A to FIG. 11B.

[Operation Er4_1: data D_01]

Next, at Time t101 in FIG. 16A, the potential supplied to the wiring WL2 is changed from the high potential H to the low potential L, the potential supplied to the wiring SL is changed from the low potential L to the high potential H, and the wiring BL is brought into a floating state, so that electric charge of the second charge-accumulation layer can be released, and the state where the data D_00 is held can be changed into the state where the data D_01 is held (the memory cell 602 shown on the upper right in FIG. 15) (Operation Er4_1). This operation can change the data of all the memory cells 602 connected to the same wiring WL2 and the same wiring SL.

[Operation Er4_2: data D_11]

Next, at Time t102 in FIG. 16A, the potential supplied to the wiring WL1 is changed from the high potential H to the low potential L, so that electric charge of the first charge-accumulation layer can be released, and the state where the data D_01 is held can be changed into the state where the data D_11 is held (the memory cell 602 shown on the lower right in FIG. 15) (Operation Er4_2). This operation can change the data of all the memory cells 602 connected to the same wiring WL1 and the same wiring SL.

### <Operation Example 5-2 of Semiconductor Device>

Although FIG. 16A illustrates an example in which electric charge is released from the second charge-accumulation layer and the first charge-accumulation layer in this order, electric charge may be released from the first charge-accumulation layer and the second charge-accumulation layer in this order by the operation shown in FIG. 16B.

### [Data D_00]

At Time t110 shown in FIG. 16B, the data D_00 is held like at Time t100 shown in FIG. 16A.

[Operation Er5_1: data D_10]

At Time t111 in FIG. 16B, the potential supplied to the wiring WL1 is changed from the high potential H to the low potential L, the potential supplied to the wiring SL is changed from the low potential L to the high potential H, and the wiring BL is brought into a floating state, so that electric charge of the first charge-accumulation layer can be released, and the state where the data D_00 is held can be changed into the state where the data D_10 is held (the memory cell 602 shown on the lower left in FIG. 15) (Operation Er5_1). This operation can change the data of all the memory cells 602 connected to the same wiring WL1 and the same wiring SL.

[Operation Er5_2: data D_11]

Next, at Time t112 shown in FIG. 16B, the potential supplied to the wiring WL2 is changed from the high potential H to the low potential L, so that electric charge held in the second charge-accumulation layer can be released, and the state where the data D_10 is held can be changed into the state where the data D_11 is held (Operation Er5_2). This operation can change the data of all the memory cells 602 connected to the same wiring WL2 and the same wiring SL.

### <Operation Example 5-3 of Semiconductor Device>

Although FIGS. 16A and 16B illustrate examples in which electric charge is released from the first charge-accumulation layer and the second charge-accumulation layer at different timings, electric charge may be released from the first charge-accumulation layer and the second charge-accumulation layer by the same operation shown in FIG. 16C.

### [Data D_00]

At Time t120 shown in FIG. 16C, the data D_00 is held like at Time t100 shown in FIG. 16A.

[Operation Er6: data D_11]

At Time t121 shown in FIG. 16C, the potentials supplied to the wiring WL1 and the wiring WL2 are changed from the high potential H to the low potential L, the potential supplied to the wiring SL is changed from the low potential L to the high potential H, and the wiring BL is brought into a floating state, so that the state where the data D_00 is held can be changed into the state where the data D_11 is held (Operation Er6). This operation can change the data of all the memory cells 602 connected to the same wiring WL1, the same wiring WL2, and the same wiring SL.

### <Operation Example 6-1 of Semiconductor Device>

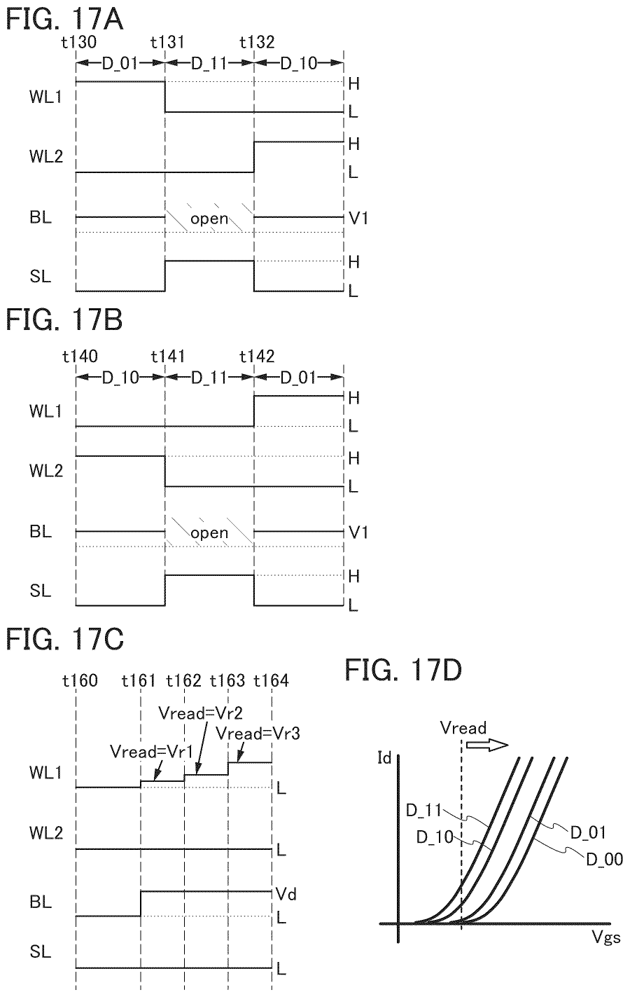

As for the operation of changing the held data with use of a change in the potential of the wiring SL, in the examples described above, data is rewritten from the state where the data D_00 is held; timing charts shown in FIGS. 17A and 17B show examples in which data is rewritten from the state where the data D_01 is held and the state where the data D_10 is held, respectively.

The timing chart in FIG. 17A is described.

### [Data D_01]

At Time t130, the data D_01 is held. The data can be held by the operations shown in FIG. 8A to FIG. 9C.

### [Data D_11]

Next, at Time t131, the potential supplied to the wiring WL1 is changed from the high potential H to the low potential L, the potential supplied to the wiring SL is changed from the low potential L to the high potential H, and the wiring BL is brought into a floating state, so that the state where the data D_01 is held can be changed into the state where the data D_11 is held.

### [Data D_10]

Next, at Time t132, the potential supplied to the wiring WL2 is changed from the low potential L to the high potential H, the potential supplied to the wiring SL is changed from the high potential H to the low potential L, and the potential supplied to the wiring BL becomes the potential V1, so that the state where the data D_11 is held can be changed into the state where the data D_10 is held.

### <Operation Example 6-2 of Semiconductor Device>

Next, the timing chart in FIG. 17B is described.

### [Data D_10]

At Time t140, the data D_10 is held. The data can be held by the operations shown in FIG. 8A to FIG. 9C.

### [Data D_11]

Next, at Time t141, the potential supplied to the wiring WL2 is changed from the high potential H to the low potential L, the potential supplied to the wiring SL is changed from the low potential L to the high potential H, and the wiring BL is brought into a floating state, so that the state where the data D_10 is held can be changed into the state where the data D_11 is held.

### [Data D_01]

Next, at Time t142, the potential supplied to the wiring WL1 is changed from the low potential L to the high potential H, the potential supplied to the wiring SL is changed from the high potential H to the low potential L, and the potential supplied to the wiring BL becomes the potential V1, so that the state where the data D_11 is held can be changed into the state where the data D_01 is held.

### <Operation Example of Semiconductor Device: Reading>

An operation example of reading data held in the memory cell 602 is described with reference to a timing chart shown in FIG. 17C.

First, at Time t161, the low potential L is supplied to the wiring WL1, the wiring WL2, the wiring BL, and the wiring SL.

Next, the potential of the wiring WL1 is changed to read the held data. The threshold value of the transistor M1 included in the memory cell 602 changes in accordance with the held data. FIG. 17D shows an example of the I_{d}-V_{gs} curves of the transistor M1 (which are the same as those shown in FIG. 8B). A current flowing through the transistor changes with a change in a reading potential (denoted by a reading potential V_{read} in the drawing). The current of the transistor is read while the reading potential V_{read} changes, whereby data held in the transistor M1 can be determined.

In the example described below, reading is performed while the potential supplied to the wiring WL1 as the reading potential V_{read} is changed to Vr1, Vr2, and Vr3 in this order

First, at Time t162, a potential Va is supplied to the wiring BL as a predetermined potential. When the potential of the wiring WL1 is changed to the potential Vr1, current flows between the wiring BL and the wiring SL in the case where the data D_11 is held in the memory cell 602.

Next, when the potential of the wiring WL1 is changed to the potential Vr2 at Time t163, current flows between the wiring BL and the wiring SL in the case where the data D_10 is held in the memory cell 602.

Next, when the potential of the wiring WL1 is changed to the potential Vr3 at Time t164, current flows between the wiring BL and the wiring SL in the case where the data D_01 is held in the memory cell 602. Note that no current flows between the wiring BL and the wiring SL in the case where the data D_00 is held in the memory cell 602. By measuring current flowing between the wiring BL and the wiring SL in this manner, held data can be read.

### <Materials of Components of Semiconductor Device>

Materials that can be used for the semiconductor device of this embodiment are described below. Note that the layers included in the semiconductor device of this embodiment may have a single-layer structure or a stacked-layer structure.

### [Conductive Layer]

For the conductive layers (e.g., the conductive layers 520, 540, and 560) included in the semiconductor device, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. A nitride or an oxide of any of the above metal elements may be also used. As an alloy containing any of the above metal elements, a nitride of the alloy or an oxide of the alloy may be used. For example, it is preferable to use tantalum nitride, titanium nitride, ruthenium nitride, a nitride containing molybdenum, a nitride containing tungsten, titanium, and aluminum, a nitride containing tantalum and aluminum, ruthenium oxide, an oxide containing strontium and ruthenium, an oxide containing lanthanum and nickel, or the like. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (a registered trademark)), and indium zinc oxide containing tungsten oxide. In this specification and the like, a conductive film deposited using the conductive material containing oxygen may be referred to as an oxide conductive film.

A conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen can be provided on the channel formation region side. When the conductive material containing oxygen is provided on the channel formation region side, oxygen released from the conductive material is easily supplied to the channel formation region.

As the conductive material containing a metal element and nitrogen, for example, tantalum nitride, titanium nitride, ruthenium nitride, a nitride containing molybdenum, a nitride containing tungsten, titanium, and aluminum, a nitride containing tantalum and aluminum, or the like can be used. As the conductive material containing a metal element and oxygen, for example, ruthenium oxide, an oxide containing strontium and ruthenium, and an oxide containing lanthanum and nickel can be used.

One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may also be used.

Titanium, tantalum, ruthenium, or a material containing one or more selected from the metal elements is preferable because it is a conductive material that is not easily oxidized, a conductive material having a function of inhibiting diffusion of oxygen, or a material that maintains the conductivity even after absorbing oxygen.

Each of the conductive layers 520 and 540 is in contact with the oxide semiconductor layer, and thus is preferably formed using a conductive material that is not easily oxidized, a conductive material that maintains the low electrical resistance even after being oxidized, an oxide conductive material, or a conductive material that has a function of inhibiting diffusion of oxygen. Examples of the conductive material include a conductive material containing nitrogen and a conductive material containing oxygen. Thus, a decrease in conductivity of the conductive layer can be inhibited.

As the conductive material containing oxygen, ITO, ITSO, IZO (registered trademark), or the like is preferably used, for example.

In the case where the conductive layer 520 has a stacked-layer structure, a conductive material containing nitrogen and a conductive material containing oxygen may be used for the upper layer in contact with the oxide semiconductor layer.

In the case where the conductive layer 540 has a stacked-layer structure, for example, the lower layer can be formed using a material having higher conductivity than that for the upper layer, and the upper layer can be formed using a conductive material containing nitrogen, a conductive material containing oxygen, a conductive material that is less likely to be oxidized, a conductive material having a function of inhibiting diffusion of oxygen, a material that maintains the conductivity even after absorbing oxygen, or the like.

Specifically, for example, ruthenium, tungsten, titanium nitride, or tantalum nitride is preferably used for the lower layer of the conductive layer 540, and ITO or ITSO is preferably used for the upper layer. In that case, ITO or ITSO is in contact with the oxide semiconductor layer. Such a structure can maintain conductivity even when the conductive layer is in contact with the oxide semiconductor layer. When the lower layer is formed using a material having higher conductivity than that for the upper layer, the conductivity of the conductive layer can be increased.

In the case where the conductive layer has a two-layer structure, the upper layer may be formed using a material having higher conductivity than that for the lower layer, and the lower layer can be formed using a conductive material containing nitrogen, a conductive material containing oxygen, a conductive material that is less likely to be oxidized, a conductive material having a function of inhibiting diffusion of oxygen, a material that maintains the conductivity even after absorbing oxygen, or the like. In such a case, for example, when the oxide semiconductor layer is in contact with the top surface of the conductive layer, the contact resistance between the conductive layer and the oxide semiconductor layer can be reduced.

### [Insulating Layer]

An inorganic insulating film is preferably used for each of the insulating layers (the insulating layers 210, 481, 482, 483, 283, 285, 551, 553, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a nitride such as aluminum nitride, silicon nitride oxide, or silicon nitride can be used.

Specifically, it is preferable to use a barrier insulating layer against oxygen and impurities such as water or hydrogen.

Note that in this specification and the like, a barrier insulating layer refers to an insulating layer having a barrier property. In addition, the barrier property refers to a property that does not easily allow diffusion of a target substance, a property that does not easily allow passage of a target substance, a property with low permeability of a target substance, a function of inhibiting diffusion of a target substance, or a function of inhibiting transmission of a target substance. Note that hydrogen described as a target substance refers to at least one of a hydrogen atom, a hydrogen molecule, and a substance bonded to hydrogen, such as a water molecule or OH″, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

As the insulating layer having a function of inhibiting the passage of oxygen and impurities such as water or hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be given, for example. In addition, an oxide containing aluminum and hafnium (hafnium aluminate) can be given, for example. Furthermore, nitrides such as aluminum nitride, silicon nitride oxide, and silicon nitride can be given, for example.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, the amount of oxygen vacancies in the oxide semiconductor layer can be reduced. Examples of an insulating layer in which a region containing excess oxygen is easily formed include silicon oxide, silicon oxynitride, and porous silicon oxide.

With miniaturization and high integration of a transistor, for example, a problem such as generation of a leakage current may arise because of a thin gate insulating layer. When a material with a high dielectric constant (a high-k material) is used for the gate insulating layer, the voltage at the time of operation of the transistor can be reduced while the physical thickness is maintained. Furthermore, the equivalent oxide thickness (EOT) of the gate insulating layer can be reduced. When a material with a high dielectric constant is used for a dielectric layer of a capacitor, the element can have a larger capacitance value. By contrast, when a material with a low dielectric constant is used for the insulating layer functioning as an interlayer film, parasitic capacitance generated between wirings can be reduced. Thus, a material can be selected depending on the function of an insulating layer. Note that a material with a low dielectric constant is a material with high dielectric strength.

Examples of a material with a high dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include resins such as polyester, polyolefin, polyamide (e.g., nylon and aramid), polyimide, polycarbonate, and acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

For example, an inorganic insulating material such as silicon oxide, silicon oxynitride, and silicon nitride oxide can be used for both a layer in which a material with a high dielectric constant is suitably used, such as a gate insulating layer, and a layer in which a material with a low dielectric constant is suitably used, such as an interlayer film. These materials have relatively low dielectric constants as compared with a high-k material such as hafnium oxide, for example, and thus are each expressed as a material with a low dielectric constant in this specification and the like in some cases.

A material that can show ferroelectricity may be used for an insulating layer included in the semiconductor device. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Although the metal oxide and the metal nitride are shown above as examples of the material that can have ferroelectricity, one embodiment of the present invention is not limited thereto. For example, a metal oxynitride in which nitrogen is added to any of the above-described metal oxides, a metal nitride oxide in which oxygen is added to any of the above-described metal nitrides, or the like may be used.

As the material that can show ferroelectricity, a mixture or compound containing a plurality of materials selected from the above-listed materials can be used, for example. Alternatively, the insulating layer can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

A metal oxide containing one or both of hafnium and zirconium can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can show ferroelectricity processed into a layer shape is referred to as a ferroelectric layer in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure, in which case ferroelectricity is exhibited. A crystal included in the insulating layer may have one or more of crystal structures selected from cubic, tetragonal, orthorhombic, monoclinic, and hexagonal crystal structures. Alternatively, the insulating layer may have an amorphous structure. In that case, the insulating layer may have a composite structure including an amorphous structure and a crystal structure.

The concentration of impurities such as water or hydrogen in the insulating layer of one embodiment of the present invention is preferably reduced. This can inhibit entry of impurities such as water or hydrogen into the channel formation region of the oxide semiconductor layer.

Each of the insulating layers 481, 482, and 483 preferably includes the barrier insulating layer against hydrogen. The insulating layers 481, 482, and 483 are provided to surround the oxide semiconductor layer. When the insulating layers 481, 482, and 483 provided outside the oxide semiconductor layer have a barrier property against hydrogen, diffusion of hydrogen into the oxide semiconductor layer can be inhibited. For example, the insulating layers 481, 482, and 483 preferably include a silicon nitride film.

Note that silicon nitride also has a barrier property against oxygen. Thus, using silicon nitride for the insulating layers 481, 482, and 483 can inhibit extraction of oxygen from the oxide semiconductor layer, and accordingly can inhibit formation of an excess amount of oxygen vacancies in the oxide semiconductor layer.

Furthermore, when silicon nitride is used for the insulating layers 481, 482, and 483, excess oxygen can be prevented from being supplied to the oxide semiconductor layer. Thus, the channel formation region of the oxide semiconductor layer can be prevented from containing excess oxygen, whereby the reliability of the transistor can be improved.

Each of the insulating layers 481, 482, and 483 preferably includes any of an oxide insulating film, an oxynitride film, and an insulating layer including a region containing excess oxygen, which are described above.

The concentration of impurities such as water or hydrogen in the insulating layers 481, 482, and 483 is preferably reduced. This can inhibit entry of impurities such as water or hydrogen into the channel formation region of the oxide semiconductor layer.

Each of the insulating layers 481, 482, and 483 can have a stacked-layer structure.

For example, the insulating layer can have a three-layer structure in which a second insulating layer is sandwiched vertically by a first insulating layer and a third insulating layer. Note that a structure that does not include any of the first insulating layer and the third insulating layer can also be employed.

The second insulating layer preferably includes a region having a higher oxygen content than at least one of the first insulating layer and the third insulating layer. When the second insulating layer has a high oxygen content, an i-type region can be easily formed in the oxide semiconductor layer in the vicinity of the second insulating layer.

It is further preferable that a film from which oxygen is released by heating be used for the second insulating layer. When the insulating layer releases oxygen by being heated during the manufacturing process of the transistor, the oxygen can be supplied to the oxide semiconductor layer. The oxygen supply to the oxide semiconductor layer, particularly to the channel formation region of the oxide semiconductor layer, reduces the amount of oxygen vacancies and V_{O}H in the oxide semiconductor layer, so that the transistor can have favorable electrical characteristics and high reliability.

In the insulating layers 481 and 483, a region in contact with the source region and the drain region of the oxide semiconductor layer 530 preferably has a small oxygen content. The small oxygen content reduces the amount of oxygen supplied to the oxide semiconductor layer, so that the resistance of the oxide semiconductor layer is likely to be reduced. Thus, in the first insulating layer and the third insulating layer by which the second insulating layer is sandwiched vertically, in particular, the insulating layer on the side in contact with the conductive layer 520 and the insulating layer on the side in contact with the conductive layer 540 preferably has a smaller oxygen content than the second insulating layer.

A material with a low dielectric constant is preferably used for the second insulating layer. In that case, parasitic capacitance generated between wirings can be reduced. For example, silicon oxide or silicon oxynitride can be used.

For each of the first and third insulating layers, a barrier insulating layer against oxygen is preferably used. This can inhibit the conductive layers 520 and 114 from being oxidized and having high resistance.

When an insulating layer having a function of capturing or fixing hydrogen is used as the first and third insulating layers, diffusion of hydrogen into the oxide semiconductor layer can be inhibited, and hydrogen contained in the oxide semiconductor layer can be captured or fixed. For example, magnesium oxide, aluminum oxide, hafnium oxide, an oxide containing hafnium and silicon, or the like can be used. Alternatively, for example, a stacked-layer film of aluminum oxide and silicon nitride over the aluminum oxide may be used.

### [Insulating Layers 551, 553, 554, and 556 and Charge-Accumulation Layers 552 and 555]

Any of the above-described materials can be used for the insulating layers 551, 553, 554, and 556 as appropriate.

In writing to the transistor 500, electric charge is not preferably captured in a region other than the charge-accumulation layer, specifically, in the films of the insulating layers 551, 553, 554, and 556, at the interface between the insulating layer 551 and the semiconductor layer, at the interface between the insulating layer 554 and the semiconductor layer, and the like. This is because capturing of electric charge in such a region might prevent captured electric charge from being released at a desired voltage to increase power consumption required for operation of the memory element, prevent information from being retained because of easy release of captured electric charge due to leakage current or the like, or decrease the reliability of the transistor 500 due to capturing of electric charge, for example.

From the above viewpoint, it is preferable that each of the insulating layers 551, 553, 554, and 556 be a film with few leakage currents or defects that cause charge capture, for example. It is further preferable that the insulating layer 551 having a small thickness have few defects.

For the insulating layers 551 and 554, silicon oxide, silicon oxynitride, silicon nitride oxide, silicon nitride, aluminum oxide, or the like is preferably used.

The thickness of each of the insulating layers 551 and 554 can be greater than or equal to 1 nm and less than or equal to 20 nm, for example.

In the case where a material having high conductivity is used for the charge-accumulation layer 552, the thickness of the insulating layer 551 can be greater than or equal to 5 nm and less than or equal to 20 nm, preferably greater than or equal to 6 nm and less than or equal to 15 nm, for example. In the case where a material having a high insulating property is used for the charge-accumulation layer 552, the thickness of the insulating layer 551 can be greater than or equal to 1 nm and less than or equal to 6 nm, preferably greater than or equal to 1.5 nm and less than or equal to 4.5 nm, for example.

In the case where a material having high conductivity is used for the charge-accumulation layer 555, the thickness of the insulating layer 554 can be greater than or equal to 5 nm and less than or equal to 20 nm, preferably greater than or equal to 6 nm and less than or equal to 15 nm, for example. In the case where a material having a high insulating property is used for the charge-accumulation layer 555, the thickness of the insulating layer 554 can be greater than or equal to 1 nm and less than or equal to 6 nm, preferably greater than or equal to 1.5 nm and less than or equal to 4.5 nm, for example.

The insulating layer 553 preferably has a larger thickness than the insulating layer 551, for example. The insulating layer 556 preferably has a larger thickness than the insulating layer 554, for example.

The thicknesses of the insulating layers 553 and 556 can each be, for example, greater than or equal to 8 nm and less than or equal to 30 nm.

For the insulating layers 553 and 556, any of the above-described materials for the insulating layer can be used. A plurality of materials may be stacked to be used. For the insulating layer 553, silicon oxide, silicon oxynitride, aluminum oxide, hafnium oxide, or the like is preferably used, for example.

A material having high conductivity can be used for the charge-accumulation layers 552 and 555. For example, any of the above-described materials for the conductive layer can be used as appropriate. Specifically, for example, it is possible to use one or more metal elements selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, and lanthanum; an alloy containing any of the above metal elements; or an alloy containing a combination of the above metal elements. A nitride or an oxide of any of the above metal elements can also be used. As an alloy containing any of the above metal elements, a nitride of the alloy or an oxide of the alloy may be used.

A semiconductor material such as silicon or germanium can be used for the charge-accumulation layer 552 and the charge-accumulation layer 555. In the case where a semiconductor material is used, a layer whose resistance is reduced by impurity injection may be used, for example.

A material with a high insulating property can be used for the charge-accumulation layer 552 and the charge-accumulation layer 555. For example, the above-described material for the insulating layer can be used for an insulating layer including a charge trap can be used. Specifically, silicon nitride or silicon nitride oxide can be used, for example. A layer in which conductive nanodots are dispersed in the insulating layer can also be used.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. In addition, the thickness distribution of the film provided over the insulating layer can be uniform. Furthermore, inhibiting formation of a crystal grain boundary in the insulating layer can reduce a leakage current due to the defect states in the crystal grain boundary. Thus, the insulating layer can function as an insulating film with a low leakage current. Thus, the insulating layer used as the insulating layer 551, the insulating layer 553, or the like preferably has an amorphous structure, for example.

When the gate insulating layer of the transistor has a function of capturing and fixing hydrogen, V_{O}H in the channel formation region can be reduced, so that the channel formation region can be an i-type or substantially i-type region.

When the gate insulating layer of the transistor includes a barrier insulating layer against hydrogen, diffusion of hydrogen into the oxide semiconductor layer can be inhibited.

When the gate insulating layer of the transistor includes an insulating layer having a thermally stable structure, such as silicon oxide or silicon oxynitride, the transistor characteristics can be stabilized.

When a barrier insulating layer against oxygen is used as the gate insulating layer of the transistor, diffusion of oxygen contained in the oxide semiconductor layer into the surrounding layer can be inhibited, and accordingly formation of oxygen vacancies in the oxide semiconductor layer can be inhibited.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include the above semiconductor substrates provided with an insulator region, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

### <Oxide Semiconductor Layer>

In the transistor 500, a metal oxide functioning as a semiconductor is preferably used for the oxide semiconductor layer 530 including a channel formation region. That is, the transistor 500 is preferably an OS transistor.

Note that for the semiconductor device of this embodiment, a transistor including another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used as a semiconductor material of a transistor include single crystal silicon, polycrystalline silicon, microcrystalline silicon, and amorphous silicon. An example of polycrystalline silicon is low-temperature polysilicon (LTPS).

Alternatively, a semiconductor layer of a transistor may include a layered material functioning as a semiconductor. The layered material generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

An oxide semiconductor layer that can be used as the oxide semiconductor layer 530 is described below.

As the oxide semiconductor layer 530, an oxide semiconductor layer 30 described below can be used.

The oxide semiconductor layer of one embodiment of the present invention preferably contains a metal oxide having crystallinity. Examples of the structure of a metal oxide having crystallinity include a c-axis aligned crystalline (CAAC) structure, a polycrystalline structure, and a nanocrystalline (nc) structure. By using a metal oxide having crystallinity for the oxide semiconductor layer, the density of defect states in the oxide semiconductor layer can be reduced. This can improve the reliability of a transistor including the oxide semiconductor layer of one embodiment of the present invention, thereby improving the reliability of a semiconductor device including the transistor.

It is particularly preferable that the oxide semiconductor layer of one embodiment of the present invention include a metal oxide having a CAAC structure. The CAAC structure is a crystal structure in which a plurality of microcrystals (typically, a plurality of microcrystals each having a hexagonal crystal structure) have c-axis alignment and are connected on the a-b plane without alignment. In cross-sectional observation of an oxide semiconductor layer having a CAAC structure with use of a high-resolution transmission electron microscope (TEM) image, metal atoms are observed to be arranged in a layered manner in a crystal part. Thus, the oxide semiconductor layer having a CAAC structure can also be referred to as a structure including the layered crystal parts. The metal atoms arranged in a layered manner can be observed as bright spots in the cross-sectional TEM image of the oxide semiconductor layer.

The CAAC structure is formed such that the c-axis is perpendicular or substantially perpendicular to a formation surface, for example. In the CAAC structure, metal atoms are arranged in a layered manner in a direction parallel or substantially parallel to the formation surface. In a region having the CAAC structure, an angle formed by the c-axis and the formation surface is preferably within 90°±20° (greater than or equal to 70° and less than or equal to 110°), further preferably within 90°±15° (greater than or equal to 75° and less than or equal to 105°), still further preferably within 90°±10° (greater than or equal to 80° and less than or equal to 100°), yet further preferably within 90°±5° (greater than or equal to 85° and less than or equal to 95°).

The polycrystalline structure includes a crystal grain boundary (grain boundary). When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. In the CAAC structure, grain boundaries in the a-b plane are not observed clearly; thus, a highly reliable semiconductor device can be achieved. Furthermore, because the CAAC structure has a small number of crystal grain boundaries, an energy barrier for carrier conduction in a channel of a transistor is low, and an on-state current is expected to be increased.

The crystallinity of the oxide semiconductor layer can be analyzed with X-ray diffraction (XRD), TEM, or electron diffraction (ED), for example. Alternatively, these methods may be combined as appropriate to be employed for analysis.

When the oxide semiconductor layer having the CAAC structure is subjected to electron diffraction, spots indicating c-axis alignment (bright spots) are observed in the electron diffraction pattern. The c-axes of the CAAC structure are preferably aligned in a direction parallel to the normal vector of the formation surface of the oxide semiconductor layer or the normal vector of a surface of the oxide semiconductor layer.

A fast Fourier transform (FFT) pattern obtained by FFT processing on a TEM image reflects reciprocal lattice space information similar to that of an electron diffraction pattern.

When the cross-sectional TEM image of the oxide semiconductor layer having the CAAC structure is obtained and each region in the cross-sectional TEM image is subjected to FFT processing to form the FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably greater than or equal to 70° and less than or equal to 110° (within 90°+) 20°, further preferably greater than or equal to 75° and less than or equal to 105° (within 90°+) 15°, still further preferably greater than or equal to 80° and less than or equal to 100° (within 90°+) 10°, and yet further preferably greater than or equal to 85° and less than or equal to 95° (within 90°+) 5° can be regarded as having the CAAC structure.

When the oxide semiconductor layer having the CAAC structure is observed from the direction perpendicular to the formation surface using the TEM image, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the formation surface, pentagonal, hexagonal, and heptagonal Voronoi regions are mainly observed, typically a hexagonal Voronoi region is observed. For example, the hexagonal Voronoi region accounts for higher than or equal to 30% and lower than 100% of the Voronoi regions observed in the Voronoi diagram.

A method for forming a Voronoi diagram is described. First, in TEM image analysis, FFT processing is performed, only information within a certain range is left by filtering, and then reverse fast Fourier transform is performed to obtain an FFT filtering image. Lattice points are extracted from the obtained FFT filtering image, and perpendicular bisectors of line segments each connecting adjacent lattice points are formed. A point at which three perpendicular bisectors intersect with each other is referred to as a Voronoi point, and a polygonal region surrounded by line segments connecting the Voronoi points is referred to as a Voronoi region. In the above manner, a Voronoi diagram can be formed.

Note that as the TEM observation range for forming a Voronoi diagram, a rectangular region that is 50 nm wide and 50 nm long is observed, for example. Note that the observation range is not limited to this.

When distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected to be tangled with each other. That is, no clear boundary portion is observed in the CAAC structure.

Note that as the hexagonal lattice orientation, the orientation of a hexagon formed by six lattice points closest to each other can be calculated.

Note that there is no particular limitation on the crystallinity of a semiconductor material included in the oxide semiconductor layer. The oxide semiconductor layer sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor layer having crystallinity can inhibit deterioration of the transistor characteristics in some cases.

The metal oxide of one embodiment of the present invention preferably contains at least indium (In) or zinc (Zn), particularly preferably contains indium as its main component. Here, the metal oxide contains indium as its main component, and can further contain an element M. The metal oxide preferably contains two or three selected from indium, the element M, and zinc, and particularly preferably contains indium and zinc as its main components. Here, the metal oxide contains indium and zinc as its main components, and can further contain the element M. The element M is a metal element or a metalloid element that has a high bonding energy with oxygen, such as a metal element or a metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, still further preferably one or more selected from gallium and tin. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may refer to a metalloid element.

In the cross section of the oxide semiconductor layer observed using the TEM image, metal atoms arranged in a layered manner in a direction parallel or substantially parallel to the formation surface are observed. In a TEM image, a metal atom is observed as a bright spot. For example, in a metal oxide containing indium, indium atoms arranged in a layered manner are observed. As another example, in a metal oxide containing indium and zinc, indium atoms and zinc atoms arranged in a layered manner are observed.

Examples of the metal oxide of one embodiment of the present invention include indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), and indium gallium aluminum zinc oxide (In—Ga—Al—Zn oxide, also referred to as IGAZO or IAGZO). Alternatively, indium tin oxide containing silicon (also referred to as ITSO), gallium tin oxide (Ga—Sn oxide), aluminum tin oxide (Al—Sn oxide), or the like can be given. As the metal oxide of one embodiment of the present invention, indium oxide can be used. Alternatively, as the metal oxide of one embodiment of the present invention, gallium oxide, zinc oxide, or the like can be used.

By increasing the proportion of the number of indium atoms in the total number of atoms of all the metal elements included in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

In the description of this embodiment, In—Ga—Zn oxide is sometimes taken as an example of the metal oxide.

The oxide semiconductor layer of one embodiment of the present invention can be formed by forming metal oxides using two kinds of film formation methods. For example, the oxide semiconductor layer of one embodiment of the present invention can be formed by forming a metal oxide using a first film formation method and a second film formation method. Note that the oxide semiconductor layer formed by two kinds of film formation methods may be referred to as a hybrid OS.

The oxide semiconductor layer of one embodiment of the present invention has crystallinity. The oxide semiconductor layer of one embodiment of the present invention preferably has a CAAC structure.

In the formation of the oxide semiconductor layer of one embodiment of the present invention, a metal oxide having crystallinity is formed by the first film formation method. The metal oxide formed at this time particularly preferably has the CAAC structure. A metal oxide formed by, for example, a sputtering method, is likely to have crystallinity.

In the case where a metal oxide is formed by the first film formation method, a mixed layer is sometimes formed at the interface between the metal oxide and a layer (formation surface) over which the metal oxide is formed. For example, in the case where a sputtering method is used as the first film formation method, the mixed layer is sometimes formed by particles ejected from a target or the like (also referred to as sputtered particles) or energy applied to the substrate side by sputtered particles or the like, for example. There is a concern that the mixed layer may hinder crystallization of the metal oxide film.

For example, in the case where an insulating layer containing silicon, e.g., silicon oxide, is used as the formation surface and a metal oxide is formed over the silicon oxide by the first film formation method, silicon might enter the metal oxide. There is a concern that the entry of impurities such as silicon into the metal oxide may hinder crystallization of the metal oxide.

In view of the above, in one embodiment of the present invention, a metal oxide is formed by the second film formation method before a metal oxide is formed by the first film formation method. In other words, a metal oxide is formed by the second film formation method as a first layer, and then a metal oxide is formed by the first film formation method as a second layer over the first layer. In that case, the second film formation method preferably causes less damage to a formation surface than the first film formation method. When a film formation method that causes less damage to a formation surface is used as the second film formation method, formation of a mixed layer at an interface between the oxide semiconductor layer and a layer serving as the formation surface of the oxide semiconductor layer can be inhibited. Moreover, entry of impurities such as silicon into the second layer can be inhibited, which can increase the crystallinity. For example, an atomic layer deposition (ALD) method and a chemical vapor deposition (CVD) method are suitable as the second film formation method because they can reduce damages to a formation surface as compared with a sputtering method.

As the first layer, for example, a metal oxide having a microcrystalline structure or an amorphous structure that has lower crystallinity than the CAAC structure is sometimes formed. Formation of the second layer having high crystallinity over the first layer having low crystallinity or the formation of the first and second layers followed by heat treatment can increase the crystallinity of the first layer using the second layer as a nucleus. Accordingly, the crystallinity can be increased in the whole oxide semiconductor layer including the vicinity of the interface with the formation surface in some cases.

In a preferred mode of the oxide semiconductor layer of one embodiment of the present invention, a metal oxide is formed over the formation surface by the second film formation method, and then a metal oxide is formed thereover by the first film formation method.

Examples of the first film formation method include a sputtering method and a pulsed laser deposition (PLD) method.

Examples of the second film formation method include an ALD method, a plasma enhanced CVD (PECVD) method, a thermal CVD (TCVD) method, a photo CVD method, a metal organic CVD (MOCVD) method, and a molecular beam epitaxy (MBE) method. The MBE method is a film formation method in which a thin film having a crystal structure reflecting a crystal system of a substrate is grown, and is one of film formation methods that cause less damage to a formation surface. A wet method can be used as the second film formation method. The wet method is one of film formation methods that cause less damage to a formation surface. An example of the wet method is a spray coating method.

For example, the oxide semiconductor layer of one embodiment of the present invention can be formed in the following manner: a metal oxide is formed as the first layer by the second film formation method, and then a metal oxide is formed as the second layer by the first film formation method. Specifically, an ALD method can be used as the second film formation method, and a sputtering method can be used as the first film formation method. The metal oxide formed by the first film formation method preferably has the CAAC structure.

Furthermore, a third layer can be formed over the second layer. Because the second layer has high crystallinity, the third layer can grow with a crystal of the second layer as a nucleus or a seed. Thus, the third layer can be crystallized even when a film formation method that easily gives crystallinity is not employed as the film formation method of the third layer. Here, for example, when the third layer is formed by a film formation method that gives higher coverage than that of the second layer, the whole oxide semiconductor layer can have both high crystallinity and high coverage. For another example, when the third layer is formed by a formation method that causes less damage than damage to the second layer, damage to the second layer can be reduced and high crystallinity can be obtained in the whole oxide semiconductor layer.

When influence of the formation surface on the second layer is reduced by provision of the first layer, the crystallinity of the second layer is increased to an extremely high level. Thus, the third layer whose crystal is grown with the second layer as a nucleus or a seed is also expected to have extremely high crystallinity.

Note that the third layer is the uppermost layer of the oxide semiconductor layer. In the case where the oxide semiconductor layer is used as a semiconductor layer of a transistor described later, the third layer is, for example, a layer in contact with a gate insulating layer. Increasing the crystallinity of the layer in contact with the gate insulating layer can increase the carrier mobility in an on state of the transistor.

For example, the oxide semiconductor layer of one embodiment of the present invention can be formed in the following manner: a metal oxide is formed as the first layer by the second film formation method, a metal oxide is formed as the second layer by the first film formation method, and then a metal oxide is formed as the third layer by the second film formation method. Specifically, an ALD method can be used as the second film formation method, and a sputtering method can be used as the first film formation method. The metal oxide formed by the first film formation method preferably has the CAAC structure. An ALD method is a film formation method that gives higher coverage than a sputtering method, and when an ALD method is used as the film formation method of the first layer and the third layer, the coverage with the oxide semiconductor layer can be improved. Thus, the oxide semiconductor layer can suitably cover a step, an opening portion, or the like with a high aspect ratio.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. Furthermore, an RF superimposed DC sputtering method can be given. For film formation using an insulating target, an RF sputtering method is preferably used. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used for forming a film of a compound such as an oxide, a nitride, or a carbide by a reactive sputtering method. In an RF superimposed DC sputtering method, the ion energy and the potential on the target side can be controlled during film formation. Thus, damage due to film formation can be reduced as compared with that in the case of an RF sputtering method. Moreover, a high-quality film can be obtained.

Examples of the ALD method include a thermal ALD method, in which a precursor and a reactant react with each other only by a thermal energy, and a plasma-enhanced ALD (PEALD) method, in which a reactant excited by plasma is used.

The ALD method enables atomic layers to be deposited one by one, and has advantages such as formation of an extremely thin film, formation of a film on a component with a high aspect ratio, formation of a film on a surface with a large step, formation of a film with few defects such as pinholes, formation of a film with excellent coverage, and low-temperature film formation. A PEALD method utilizing plasma is preferable because film formation at lower temperatures is possible in some cases. Note that a precursor used in the ALD method sometimes contains an element such as carbon or chlorine. Thus, a film formed by the ALD method may contain an element such as carbon or chlorine in a larger quantity than a film formed by another film formation method. Note that the elements can be quantified by X-ray photoelectron spectroscopy (XPS) or SIMS. The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike in a film formation method in which particles ejected from a target or the like are deposited, a film is formed by reaction at a surface of an object to be processed in an ALD method. Thus, the ALD method can give good step coverage, almost regardless of the shape of an object to be processed. In particular, the ALD method allows excellent step coverage and excellent thickness uniformity and can be suitably used to cover a surface of an opening portion with a high aspect ratio, for example.

A high-quality film can be obtained at a relatively low temperature through a plasma CVD method. A thermal CVD method does not use plasma and thus causes less plasma damage to an object to be processed. A thermal CVD method yields a film with few defects because of no plasma damage during film formation.

By a CVD method, a film with a desired composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

### [Formation Method of Oxide Semiconductor Layer]

For example, the oxide semiconductor layer 30 can be formed in the following manner: an oxide semiconductor layer 30a is formed over a layer 229 that is a formation surface of the oxide semiconductor by an ALD method, an oxide semiconductor layer 30b is formed over the oxide semiconductor layer 30a by a sputtering method, and an oxide semiconductor layer 30c is formed over the oxide semiconductor layer 30b by an ALD method. Furthermore, heat treatment is preferably performed after formation of the oxide semiconductor layer 30. The heat treatment can increase the crystallinity of the oxide semiconductor layer 30. Here, the heat treatment is not limited to the thermal treatment. For example, the heat treatment may be performed with heat applied in the manufacturing process. The layer 229 is an insulating film, and examples of the insulating film include silicon oxide, silicon oxynitride, silicon nitride, silicon nitride oxide, aluminum oxide, and hafnium oxide. As the layer 229, a film that is described later as an insulator included in the semiconductor device can be used.

Alternatively, the layer 229 may be a conductive film. For example, the oxide semiconductor layer 30 can also be formed over a conductive film functioning as an electrode of the semiconductor device.

The layer 229 does not need to have crystallinity. In other words, the layer 229 may have an amorphous structure. In the case where the layer 229 has crystallinity, the layer 229 may have a crystal structure with low lattice matching with the metal oxide included in the oxide semiconductor layer 30.

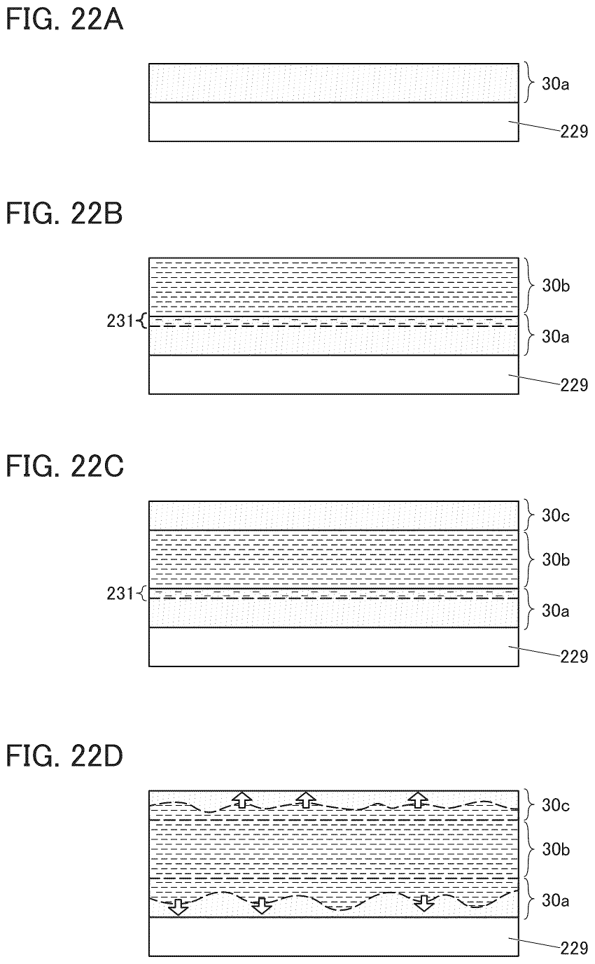

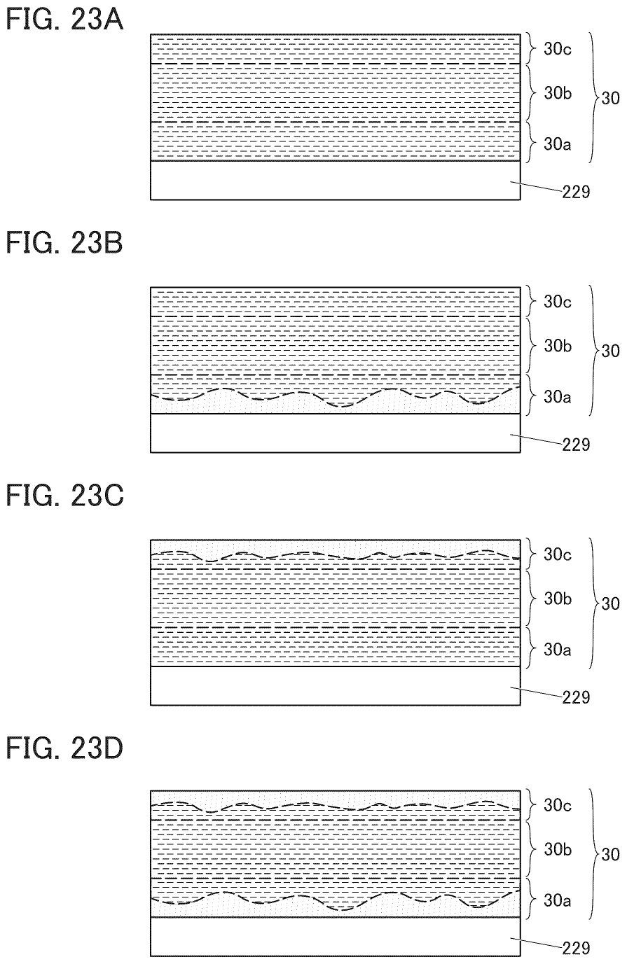

An example of the method for forming the oxide semiconductor layer 30 is described with reference to FIGS. 22A to 23D.

First, the oxide semiconductor layer 30a is formed over the layer 229 (FIG. 22A). Next, the oxide semiconductor layer 30b is formed over the oxide semiconductor layer 30a (FIG. 22B).

The oxide semiconductor layer 30b is preferably formed by a sputtering method. The oxide semiconductor layer 30b preferably has a composition suitable for forming the CAAC structure.

The oxide semiconductor layer 30a is preferably formed by a formation method that causes less damage to a formation surface than a formation method of the oxide semiconductor layer 30b. Here, the oxide semiconductor layer 30a is formed by an ALD method.

In the case where a metal oxide film is formed by a sputtering method, damage to a formation surface might cause alloying of a component contained in the metal oxide film with a component contained in a layer serving as the formation surface. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected. Therefore, it is preferable to inhibit alloying of the component contained in the metal oxide film and the component contained in the layer on which the metal oxide film is formed.

In the method for forming the oxide semiconductor layer of one embodiment of the present invention, the oxide semiconductor layer 30a is formed over the layer 229, and then the oxide semiconductor layer 30b is formed by a sputtering method. In this case, the oxide semiconductor layer 30a is preferably formed by a formation method that causes less damage to the formation surface. When the oxide semiconductor layer 30a is formed between the oxide semiconductor layer 30b and the layer 229 by a formation method that causes less damage to the formation surface, the alloying of the component contained in the oxide semiconductor layer 30 with the component contained in the layer 229 can be inhibited, so that the crystallinity of the oxide semiconductor layer 30 can be further increased.

With the above structure, the thickness of the alloyed region can be reduced or reduced to have a thickness that is small enough not to be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 22A and 22B illustrate an example in which the alloyed region is not formed between the layer 229 and the oxide semiconductor layer 30a.

Note that the thickness of the alloyed region can sometimes be calculated by performing SIMS or composition line analysis by energy dispersive X-ray spectroscopy (EDX) on the region and its vicinity.

For example, EDX line analysis is performed on the region and its vicinity with the direction perpendicular to the formation surface of the oxide semiconductor layer 30a regarded as the depth direction. Next, in profiles of quantitative values of elements in the depth direction obtained by the analysis, the depth at which the quantitative value of a metal that is the main component of the oxide semiconductor layer 30a and is not the main component of a layer (here, the layer 229) serving as a formation surface (the metal is In when the oxide semiconductor layer 30a contains In) becomes half is defined as a depth (position) of the interface between the region and the oxide semiconductor layer 30a. Furthermore, the depth at which the quantitative value of an element (e.g., Si) that is the main component of the layer serving as the formation surface and that is not the main component of the oxide semiconductor layer 30a becomes half is defined as a depth (position) of the interface between the region and the layer serving as the formation surface. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis of the oxide semiconductor layer 30 formed over the layer 229 that is formed using a silicon oxide layer is performed, the depth at which the silicon concentration is 50% of the maximum value of the silicon concentration of the layer 229 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness t_s2 is a value within the above range, the thickness of the alloyed region is reduced, whereby the thickness t_s2 can be a value within the above range.

Note that when the thickness of the alloyed region is reduced, the CAAC structure can be formed in the vicinity of a surface on which the oxide semiconductor layer 30 is formed. Here, the vicinity of the surface refers to, for example, a region ranging from the surface on which the oxide semiconductor layer 30 is formed to greater than 0 nm and less than or equal to 3 nm, preferably greater than 0 nm and less than or equal to 2 nm, further preferably greater than or equal to 1 nm and less than or equal to 2 nm in a direction substantially perpendicular to the surface.

Note that the CAAC structure in the vicinity of the surface on which the oxide semiconductor layer is formed can be confirmed in TEM observation in some cases. For example, in high-resolution TEM cross-sectional observation of the oxide semiconductor layer 30, bright spots arranged in a layered manner in a direction parallel to the surface are observed in the vicinity of the surface.

Alternatively, the CAAC structure in the vicinity of the surface on which the oxide semiconductor layer is formed can be evaluated from a map showing crystal orientation in some cases. The map showing crystal orientation can be obtained by, for example, obtaining a cross-sectional TEM image, performing FFT processing on each region in the cross-sectional TEM image to create an FFT pattern, and calculating the direction of the crystal axis of each region. The FFT pattern reflects reciprocal lattice space information like an electron diffraction pattern. For example, a region in which an angle formed by the crystal axis direction calculated and the surface on which the oxide semiconductor layer is formed is preferably greater than or equal to 70° and less than or equal to 110° (within 90°±20°), further preferably greater than or equal to 75° and less than or equal to 105° (within 90°±15°), still further preferably greater than or equal to 80° and less than or equal to 100° (within 90°±10°), and yet still further preferably greater than or equal to 85° and less than or equal to 95° (within 90°±5°) can be regarded as having the CAAC structure.

Note that when the oxide semiconductor layer 30a is formed by an ALD method, an oxide semiconductor layer having a microcrystalline structure or an amorphous structure that has lower crystallinity than the CAAC structure may be formed. That is, in the formation step illustrated in FIG. 22A, the oxide semiconductor layer 30a sometimes includes a region having lower crystallinity than the oxide semiconductor layer 30b.

Here, a method for forming an In-M-Zn oxide as the oxide semiconductor layer 30a by an ALD method is described. Note that the details of the formation of the metal oxide by an ALD method will be described later.

First, a source gas that contains a precursor containing indium is introduced into a chamber so that the precursor is adsorbed on the surface of the layer 229. Here, the substrate heating temperature is preferably a temperature corresponding to the decomposition temperature of the precursor.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than indium are released while indium is adsorbed on the substrate, whereby a layer in which indium and oxygen are bonded to each other is formed. Ozone, oxygen, water, or the like can be used as the oxidizer. After that, introduction of the oxidizer is stopped and the chamber is purged so that an excess reactant, a reaction product, and the like are removed from the chamber.

Subsequently, a source gas that contains a precursor containing the element M is introduced into the chamber, so that the precursor is adsorbed on the layer in which indium and oxygen are bonded to each other. Here, the substrate heating temperature is preferably a temperature corresponding to the decomposition temperature of the precursor.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than the element M are released while the element M is adsorbed on the substrate, whereby a layer in which the element M and oxygen are bonded to each other is formed. After that, introduction of the oxidizer is stopped and the chamber is purged so that an excess reactant, a reaction product, and the like are removed from the chamber.

Next, a source gas that contains a precursor containing zinc is introduced into the chamber and adsorbed on the layer in which the element M and oxygen are bonded to each other. Here, the substrate heating temperature is preferably a temperature corresponding to the decomposition temperature of the precursor.

Here, in the case of a thermal ALD method in which triethylindium is used as the precursor containing indium, triethylgallium is used as a precursor containing gallium, and diethylzinc is used as the precursor containing zinc, the substrate heating temperature is higher than or equal to 100° C. and lower than or equal to 350° C., preferably higher than or equal to 150° C. and lower than or equal to 300° C., for example.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than zinc are released while zinc is adsorbed on the substrate, whereby a layer in which zinc and oxygen are bonded to each other is formed. After that, introduction of the oxidizer is stopped and the chamber is purged so that an excess reactant, a reaction product, and the like are removed from the chamber.

Next, the layer in which indium and oxygen are bonded to each other is formed again over the layer in which zinc and oxygen are bonded to each other. By repeating the above steps, an In-M-Zn oxide can be formed as the oxide semiconductor layer 30a over the layer 229 by an ALD method.

When an ALD method is used, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be formed. In the case where a film is formed while the source gas is changed, as compared with the case where a film is formed using a plurality of deposition chambers, the time taken for the film formation can be shortened because the time taken for transfer and pressure adjustment is omitted. Hence, the productivity of the semiconductor device can be improved in some cases.

After the oxide semiconductor layer 30a is formed by an ALD method, an In-M-Zn oxide is formed over the oxide semiconductor layer 30a by a sputtering method as the oxide semiconductor layer 30b.

When the oxide semiconductor layer 30b is formed by a sputtering method, a mixed layer 231 is formed on the surface of the oxide semiconductor layer 30a or in the vicinity of the surface. A fine crystal region is sometimes formed in the mixed layer 231 by, for example, sputtered particles or energy or the like applied to the substrate side by sputtered particles or the like at the time of forming the oxide semiconductor layer 30b. In the subsequent heat treatment step, the mixed layer 231 or the fine crystal region formed in the mixed layer 231 serves as a nucleus, and at least part of the oxide semiconductor layer 30a is crystallized in some cases.

As a target used in a sputtering method, an In-M-Zn oxide can be used. In the case where a metal oxide is formed by a sputtering method, oxygen or a mixed gas of oxygen and a noble gas can be used as a sputtering gas. In addition, an increase in the proportion of oxygen in the sputtering gas can increase the amount of excess oxygen contained in the oxide film to be formed.

A higher proportion of the flow rate of an oxygen gas to the flow rate of the whole film formation gas (also referred to as oxygen flow rate ratio) used at the time of forming the metal oxide enables the formed metal oxide to have higher crystallinity in some cases.

When the metal oxide is formed by a sputtering method and the oxygen proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess oxide semiconductor layer in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, oxygen-deficient metal oxide is formed. A transistor including the oxygen-deficient metal oxide in a channel formation region can have relatively high field-effect mobility.

In the case where the metal oxide is formed by a sputtering method, the composition of the formed metal oxide may be different from the composition of the sputtering target. In particular, the zinc content of the formed metal oxide may be reduced to approximately 50% of that of the sputtering target.

In the formation of the oxide semiconductor layer 30b by a sputtering method, substrate heating is preferably performed. In forming a metal oxide, the substrate temperature (stage temperature) at the time of forming the metal oxide is increased, whereby a metal oxide with high crystallinity can be formed in some cases. In the formation of the oxide semiconductor layer 30b by a sputtering method, the substrate heating temperature is preferably higher than or equal to 100° C. and lower than or equal to 400° C., further preferably higher than or equal to 200° C. and lower than or equal to 300° C., for example.

As described above, as illustrated in FIG. 22B, the oxide semiconductor layer 30a and the oxide semiconductor layer 30b over the oxide semiconductor layer 30a can be formed over the layer 229.

Next, the oxide semiconductor layer 30c is formed over the oxide semiconductor layer 30b (FIG. 22C). Here, the oxide semiconductor layer 30c is formed by an ALD method. For the formation of the oxide semiconductor layer 30c by an ALD method, the method for forming the oxide semiconductor layer 30a can be referred to.

When the oxide semiconductor layer 30c having lower crystallinity than the CAAC structure is formed over the oxide semiconductor layer 30b having the CAAC structure by an ALD method, the oxide semiconductor layer 30c may epitaxially grow with the oxide semiconductor layer 30b as a nucleus. Thus, at the time of forming the oxide semiconductor layer 30c, the oxide semiconductor layer 30c may include a region having a CAAC structure. The region having the CAAC structure is preferably formed throughout the oxide semiconductor layer 30c.

Next, heat treatment may be performed.

The heat treatment temperature may be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature may be set to 400° C.±25° C. (higher than or equal to 375° C. and lower than or equal to 425° C.). The treatment time may be shorter than or equal to 10 hours, longer than or equal to 1 minute and shorter than or equal to 5 hours, or longer than or equal to 1 minute and shorter than or equal to 2 hours. In the case of using an RTA apparatus, the processing time may be longer than or equal to 1 second and shorter than or equal to 5 minutes, for example. By the heat treatment, the oxide semiconductor layer 30c (in other words, crystal molecules formed by an ALD method) is expected to fill the atomic-level space between crystal parts of the CAAC structure of the oxide semiconductor layer 30b.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure in the oxide semiconductor layer 30c is increased in some cases. In the case where the region is formed only below the oxide semiconductor layer 30c after deposition by an ALD method, the region may be extended upward by the heat treatment step (FIG. 22D). That is, by the heat treatment, the region having a CAAC structure is sometimes formed in the whole layer of the oxide semiconductor layer 30c.

Through the heat treatment step, the oxide semiconductor layer 30b is further repaired by the oxide semiconductor layer 30c (in other words, crystal molecules formed by an ALD method) that fills the atomic-level space between crystal parts of the CAAC structure of the oxide semiconductor layer 30b in some cases.

At least part of the oxide semiconductor layer 30a preferably has a CAAC structure by the heat treatment step (FIG. 22D). The CAAC structure is expected to be easily generated when the mixed layer 231 formed in the oxide semiconductor layer 30a in the formation of the oxide semiconductor layer 30b becomes a nucleus or a seed. The oxide semiconductor layer 30a preferably has a large CAAC region, and the CAAC region preferably extends to the vicinity of the layer 229.

Since the CAAC region extends from the upper portion to the lower portion of the oxide semiconductor layer 30a, the CAAC region can extend to the vicinity of the layer 229, regardless of the material and crystallinity of the layer 229. For example, even when the layer 229 has an amorphous structure, the oxide semiconductor layer 30a having high crystallinity can be formed. Thus, the method for forming the oxide semiconductor layer of one embodiment of the present invention is suitable for the case where a layer on which the oxide semiconductor layer is formed has an amorphous structure, in particular.

FIGS. 22A to 22D are cross-sectional views illustrating the formation method of a metal oxide of one embodiment of the present invention. FIGS. 22A to 22D can also be regarded as conceptual diagrams illustrating a deposition model of the metal oxide of one embodiment of the present invention. As illustrated in FIGS. 22A to 22D, the crystallinity of each of the oxide semiconductor layers 30a and 30c is increased with the oxide semiconductor layer 30b as a nucleus or a seed. Specifically, the crystallinity of the oxide semiconductor layer 30a may be increased at the time of forming the oxide semiconductor layer 30b or by heat treatment after the formation of the oxide semiconductor layer 30c. The crystallinity of the oxide semiconductor layer 30c may be increased at the time of forming the oxide semiconductor layer 30c or by heat treatment after the formation of the oxide semiconductor layer 30c. Note that the heat treatment has an assisting function of increasing the crystallinity.

As described above, in the method for forming a metal oxide of one embodiment of the present invention, the crystallinity of the oxide semiconductors (here, the oxide semiconductor layers 30a and 30c) above and below the oxide semiconductor layer 30b can be increased by using the oxide semiconductor layer 30b (i.e., CAAC) having high crystallinity as a nucleus or a seed. This can increase the crystallinity of the whole oxide semiconductor. In other words, the oxide semiconductor layer 30b serves as a nucleus or a seed to cause solid-phase growths of the oxide semiconductors above and below the oxide semiconductor layer 30b, so that the oxide semiconductor with high crystallinity can be formed. An oxide semiconductor formed by such a formation method, here, a CAAC film, may be referred to as an axial growth CAAC (AG CAAC).

The region having a CAAC structure preferably spreads in the whole layer of the oxide semiconductor layer 30 including the oxide semiconductor layers 30a and 30c. FIG. 23A illustrates a state where the oxide semiconductor layers 30a, 30b, and 30c are each crystallized. Crystals in the region having a CAAC structure in the oxide semiconductor layer 30a are connected to crystals in the region having a CAAC structure in the oxide semiconductor layer 30b. Crystals in the region having a CAAC structure in the oxide semiconductor layer 30c are connected to the crystals in the region having a CAAC structure in the oxide semiconductor layer 30b. As a result, a boundary between the oxide semiconductor layer 30a and the oxide semiconductor layer 30b is not observed in some cases. In addition, a boundary between the oxide semiconductor layer 30b and the oxide semiconductor layer 30c is not observed in some cases. The oxide semiconductor layer 30 may be expressed as one layer where the interfaces are not clearly observed. The oxide semiconductor layer 30 may be expressed as a single layer in some cases.

In cross-sectional observation with a high-resolution TEM, for example, in each of the oxide semiconductor layers 30a, 30b, and 30c, bright spots arranged parallel to the surface on which the oxide semiconductor layer 30a is formed are observed in the region having the CAAC structure. The c-axis of the CAAC structure included in each of the oxide semiconductor layers 30a, 30b, and 30c is preferably substantially parallel to the normal direction of the surface on which the oxide semiconductor layer 30a is formed.

Part of the oxide semiconductor layer 30a or part of the oxide semiconductor layer 30c is not crystallized in some cases. An example illustrated in FIG. 23B illustrates a state of the oxide semiconductor layer 30a where the vicinity of the interface between the oxide semiconductor layer 30a and the layer 229 is not crystallized. FIG. 23C illustrates a state where the vicinity of the surface of the oxide semiconductor layer 30c is not crystallized. FIG. 23D illustrates a state where the vicinity of the interface between the oxide semiconductor layer 30a and the layer 229 and the vicinity of the surface of the oxide semiconductor layer 30c are not crystallized.

Increasing the crystallinity of the oxide semiconductor layer can inhibit an increase in the electric resistance of the semiconductor layer of a transistor including the oxide semiconductor layer or increase the initial characteristics (in particular, the on-state current) of the transistor, and thus a transistor suitable for high-speed operation can be expected. In addition, the reliability and the on-state current of the transistor can be improved.

By the method for forming the oxide semiconductor layer of one embodiment of the present invention, the crystallinities of the metal oxides positioned above and below can be improved with the metal oxide having the CAAC structure as the starting point, and the whole oxide semiconductor layer can have high crystallinity.

The oxide semiconductor layer of one embodiment of the present invention has high crystallinity throughout the whole layer. Thus, in the oxide semiconductor layer 30, the boundaries between the stacked films of the oxide semiconductor layers 30a, 30b, and 30c are not observed in some cases. In particular, after heat treatment is performed, the boundaries between the stacked films are difficult to observe in some cases. Whether the boundaries between the stacked films are present can be checked with a cross-sectional TEM or a cross-sectional STEM, for example.

As described above, when a metal oxide with a high In content is used for a transistor, the field-effect mobility of the transistor can be increased. On the other hand, an oxide semiconductor with a high In content tends to be polycrystallized. The use of a metal oxide having a polycrystalline structure for a transistor adversely affects the initial characteristics or reliability of the transistor. Thus, when an oxide semiconductor with a high In content is used for one or both of the oxide semiconductor layers 30a and 30c, crystals reflecting crystal orientations included in the oxide semiconductor layer 30b are formed, so that one or both of the oxide semiconductor layers 30a and 30c can be inhibited from being polycrystallized.

It is preferable that crystals included in the oxide semiconductor layer 30b and crystals included in the oxide semiconductor layer 30a or 30c have a small lattice mismatch. Thus, the oxide semiconductor layer 30a or 30c can form crystals reflecting the orientation of crystals included in the oxide semiconductor layer 30b. In this case, for example, in high-resolution TEM cross-sectional observation of the oxide semiconductor layer 30, bright spots arranged in a layered manner in a direction parallel to the surface on which the oxide semiconductor layer 30 is formed are observed in the oxide semiconductor layer 30a or 30c.

As long as crystals included in the oxide semiconductor layer 30b and crystals included in the oxide semiconductor layer 30a or 30c have a small lattice mismatch, there is no particular limitation on the crystal structure of the oxide semiconductor layer 30a or 30c. The crystal structure of the oxide semiconductor layer 30a or 30c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

The oxide semiconductor layer 30a preferably has a composition different from that of the oxide semiconductor layer 30b. The oxide semiconductor layer 30c preferably has a composition different from that of the oxide semiconductor layer 30b. The oxide semiconductor layer 30a can have the same composition as the oxide semiconductor layer 30c. Alternatively, the oxide semiconductor layers 30a and 30c can have different compositions.

As described above, the oxide semiconductor layer 30b preferably has a composition suitable for forming the CAAC structure. The oxide semiconductor layer 30b can be formed by a sputtering method, for example. In addition, the oxide semiconductor layer 30b preferably contains zinc, for example. The oxide semiconductor layer 30b containing zinc can be a metal oxide having high crystallinity. The oxide semiconductor layer 30b preferably contains an element M in addition to zinc. When the oxide semiconductor layer 30b contains the element M, formation of oxygen vacancies in the metal oxide can be inhibited, for example. Thus, the reliability of the transistor including an oxide semiconductor layer can be improved. As the oxide semiconductor layer 30b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. As the element M, one or more of gallium, aluminum, and tin is preferably used.

The oxide semiconductor layer 30b may have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The oxide semiconductor layers 30a and 30c can be metal oxides with a high proportion of In. The oxide semiconductor layers 30a and 30c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor using an oxide semiconductor layer.

Alternatively, the oxide semiconductor layers 30a and 30c may each have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed for the oxide semiconductor layers 30a and 30c. Specific examples of the composition include a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, and a composition of In:Sn:Zn=2:0.1:1 [atomic ratio] or in the neighborhood thereof.

The oxide semiconductor layers 30a and 30c can each be a metal oxide having a higher proportion of In than that of the oxide semiconductor layer 30b.

For example, as the oxide semiconductor layers 30a and 30c, a metal oxide having a Ga proportion higher than that of the oxide semiconductor layer 30b can also be used. For the oxide semiconductor layers 30a and 30c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. When the proportion of Ga is increased, the band gap of each of the oxide semiconductor layers 30a and 30c can be larger than that of the oxide semiconductor layer 30b in some cases, for example. Thus, the oxide semiconductor layer 30b is sandwiched between the oxide semiconductor layers 30a and 30c each having a wide band gap, and the oxide semiconductor layer 30b mainly functions as a current path (channel). When the oxide semiconductor layer 30b is sandwiched between the oxide semiconductor layers 30a and 30c, trap states at the interfaces with the oxide semiconductor layer 30b and the vicinity thereof can be reduced. Accordingly, a buried-channel transistor where a channel is away from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

Alternatively, one of the oxide semiconductor layers 30a and 30c can be a metal oxide with a higher In proportion than the oxide semiconductor layer 30b, and the other can be a metal oxide with a higher Ga proportion than the oxide semiconductor layer 30b.

The oxide semiconductor layers 30a, 30b, and 30c may each include a stack of layers having the above compositions. For example, the oxide semiconductor layer 30c may have a structure in which a metal oxide with a high Ga proportion is stacked over a metal oxide with a high In proportion.

In the oxide semiconductor layer of one embodiment of the present invention, even in the case where a composition in which the CAAC structure is less likely to be formed in the formation of a single layer is used for the oxide semiconductor layers 30a and 30c, crystal growth occurs with the oxide semiconductor layer 30b as a nucleus, so that the whole oxide semiconductor layer including the oxide semiconductor layers 30a and 30c can have a CAAC structure. Alternatively, a CAAC structure can be formed in a region that includes the oxide semiconductor layer 30b and at least part of each of the oxide semiconductor layers 30a and 30c.

In particular, even in a composition where the proportion of In in the oxide semiconductor layers 30a and 30c is high, crystallinity suitable for a semiconductor layer of a transistor can be obtained. For the oxide semiconductor layer of one embodiment of the present invention, it is possible to attain higher on-state characteristics of the transistor by increasing the proportion of In and a higher reliability by employing a CAAC structure with high crystallinity at the same time.

A metal oxide having the same composition as the oxide semiconductor layer 30b may be used for the oxide semiconductor layers 30a and 30c. By using the same composition, the oxide semiconductors easily have a CAAC structure after heat treatment in some cases.

The oxide semiconductor layer having a CAAC structure formed by the two kinds of formation methods sometimes has one or more of a higher dielectric constant, higher film density, and higher film hardness than the oxide semiconductor layer having a CAAC structure formed by one kind of formation method.

With the use of the oxide semiconductor layer having a CAAC structure formed by the above two kinds of formation methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the oxide semiconductor layer 30 can be performed by EDX, XPS, inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

An oxide semiconductor layer of one embodiment of the present invention includes a metal oxide.

A metal oxide has a lattice defect in some cases. Examples of the lattice defect include point defects such as an atomic vacancy and an exotic atom, linear defects such as transition, plane defects such as a grain boundary, and volume defects such as a cavity. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide may cause generation, capture, or the like of a carrier. Thus, when a metal oxide with a large number of lattice defects is used for a semiconductor layer of a transistor, the electrical characteristics of the transistor may be unstable. Therefore, a metal oxide used for a semiconductor layer of a transistor preferably has a small number of lattice defects. The kind of a lattice defect that is likely to be present in a metal oxide and the number of lattice defects vary depending on the structure of the metal oxide, a method for forming the metal oxide, or the like.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables the transistor to have favorable electrical characteristics. In addition, the transistor can have high reliability.

For the channel formation region of a transistor, a metal oxide that can increase the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

### [Impurities in Oxide Semiconductor]

The influence of impurities in the oxide semiconductor is described here.

It is preferable that the channel formation region of the transistor including an oxide semiconductor in the semiconductor layer contain less oxygen vacancies or have a lower concentration of impurities such as hydrogen, nitrogen, or a metal element than the source region and the drain region. Oxygen vacancies (V_{O}) and impurities in a channel formation region of an oxide semiconductor may easily vary electrical characteristics and worsen the reliability. In some cases, hydrogen in the vicinity of oxygen vacancies forms V_{O}H and generates an electron serving as a carrier. Thus, if the channel formation region of the oxide semiconductor includes oxygen vacancies, the transistor tends to have normally-on characteristics. Therefore, V_{O}H in the channel formation region is also preferably reduced. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. Examples of the impurity include hydrogen, carbon, and nitrogen. Note that an impurity in an oxide semiconductor refers to, for example, elements other than the main components of the oxide semiconductor. For example, an element with a concentration of lower than 0.1 atomic % is an impurity.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This may make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region using the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, or yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

The carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. The minimum carrier density of an oxide semiconductor in the region functioning as a channel formation region is not particularly limited and can be 1×10⁻⁹ cm⁻³, for example.

### [C-Axis Alignment Proportion]

The oxide semiconductor layer of one embodiment of the present invention has a CAAC structure. The crystallinity degree of the oxide semiconductor layer of one embodiment of the present invention can be evaluated with the use of crystal orientation, for example.

The crystal orientation can be obtained from an FFT pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including a layered crystal part. The direction of the crystal axis of the region can be obtained from the angle of the line segment connecting the two spots.

In the map showing crystal orientation, the proportion of regions having c-axis alignment is calculated to obtain a c-axis alignment proportion. Here, the region having c-axis alignment represents a region where the orientation is aligned with the c-axis and a region where a difference between the orientation and the c-axis is preferably less than or equal to 20°, further preferably less than or equal to 15°, still further preferably less than or equal to 10°, yet still further preferably less than or equal to 5°. Here, the angle of the c-axis is an angle with respect to a surface on which the oxide semiconductor layer is formed.

In the oxide semiconductor layer of one embodiment of the present invention, the c-axis alignment proportion can be calculated by, for example, cross-sectional or plan-view TEM observation of the oxide semiconductor layer, using the above-described map showing crystal orientation. The region where the FFT is performed (also referred to as an FFT window) can be a circle with a diameter of 1.0 nm, for example. Note that the region where the FFT is performed is not limited to a circle.

In the case where analysis is performed using a cross-sectional TEM image, the cross-sectional TEM image observation range is, for example, a region having a width of 100 nm in the horizontal direction on the assumption that a direction perpendicular to the surface on which the oxide semiconductor layer is formed is regarded as the vertical direction. Note that the observation range is not limited to this.

In the oxide semiconductor layer of one embodiment of the present invention, the c-axis alignment proportion is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The c-axis alignment proportions of a region formed as the oxide semiconductor layer 30a, a region formed as the oxide semiconductor layer 30b, and a region formed as the oxide semiconductor layer 30c are Rc1, Rc2, and Rc3, respectively. Rc2 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Rc3/Rc1 is preferably greater than one. Furthermore, Rc2/Rc1 is preferably greater than one. Here, the c-axis alignment proportion is preferably calculated as the proportion of regions where the orientation is deviated from the c-axis by less than or equal to 20°, for example.

Note that after the formation of the oxide semiconductor layer 30, the boundaries between the oxide semiconductor layers 30a, 30b, and 30c are not clearly observed in some cases.

The oxide semiconductor layer 30 of one embodiment of the present invention can be divided into three regions: a first region, a second region, and a third region in this order from the top of the layer 229. Each of the regions is a layered region.

The first region, the second region, and the third region each have a CAAC structure. The c-axis alignment proportion of the third region is preferably higher than that of the first region. The c-axis alignment proportion of the second region is preferably higher than that of the first region. The c-axis alignment proportion of the third region is higher than or equal to 50%, preferably higher than or equal to 60%, further preferably higher than or equal to 70%, still further preferably higher than or equal to 80%, yet still further preferably higher than or equal to 90%, yet still further preferably higher than or equal to 95%. The c-axis alignment proportion of the second region is higher than or equal to 50%, preferably higher than or equal to 60%, further preferably higher than or equal to 70%, still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The first region is positioned in a range of 0 nm to 3 nm from the top surface of the layer 229, and the third region is positioned in a range of 0 nm to 3 nm from the top surface of the oxide semiconductor layer 30.

Alternatively, the thicknesses of the layers in the regions are substantially equal, for example.

### <Manufacturing Method Example 1 of Semiconductor Device>

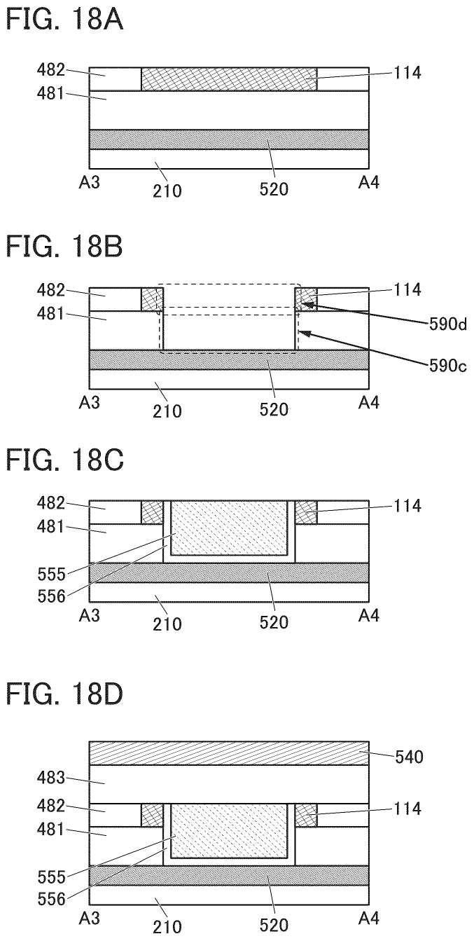

A method for manufacturing a semiconductor device is described with reference to FIGS. 18A to 20C. Note that as for a material and a formation method of each component, portions similar to those described in the above embodiment are not described in some cases.

Thin films included in the semiconductor device (e.g., insulating films, semiconductor films, and conductive films) can be formed by a sputtering method, a CVD method, a vacuum evaporation method, a PLD method, an ALD method, or the like.

Examples of the sputtering method include an RF sputtering method in which a high-frequency power source is used for a sputtering power source, a DC sputtering method in which a

DC power source is used, and a pulsed DC sputtering method in which a voltage is applied to an electrode while being changed in a pulsed manner. Furthermore, an RF superimposed DC sputtering method can be given. For film formation using an insulating target, an RF sputtering method is preferably used. A DC sputtering method is used mainly in the case of film formation using a conductive target. In a DC sputtering method, not only formation of a conductive film but also formation of an insulating film is possible when reactive sputtering is performed. The pulsed DC sputtering method can be specifically used for forming a film of a compound such as an oxide, a nitride, or a carbide by a reactive sputtering method. In an RF superimposed DC sputtering method, the ion energy and the potential on the target side can be controlled during film formation. Thus, damage due to film formation can be reduced as compared with that in the case of an RF sputtering method. Moreover, a high-quality film can be obtained.

As a sputtering method, for example, an ionization sputtering method, a long throw sputtering method, or the like can be used. The ionization sputtering method is a method in which a sputtering particle generated from a target is ionized by RF or the like and deposited with anisotropy by a self bias or the like. In the long throw sputtering method, the distance between a sputtering target and a substrate is long to enable deposition with anisotropy.

Note that CVD methods can be classified into a PECVD method, a thermal CVD method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A wiring, an electrode, an element (e.g., a transistor or a capacitor), or the like included in a semiconductor device might be charged up by receiving charge from plasma, for example. In that case, the accumulated charge might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during film formation.

Examples of the ALD method include a thermal ALD method, in which a precursor and a reactant react with each other only by a thermal energy, and a plasma-enhanced ALD (PEALD) method, in which a reactant excited by plasma is used.

The ALD method enables atomic layers to be deposited one by one, and has advantages such as formation of an extremely thin film, formation of a film on a component with a high aspect ratio, formation of a film on a surface with a large step, formation of a film with few defects such as pinholes, formation of a film with excellent coverage, and low-temperature film formation. A PEALD method utilizing plasma is preferable because film formation at lower temperatures is possible in some cases. Note that a precursor used in the ALD method sometimes contains an impurity such as carbon. Thus, a film formed by the ALD method may contain an impurity such as carbon in a larger quantity than a film formed by another film formation method. Note that the impurity can be quantified by XPS or SIMS. The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike in a film formation method in which particles ejected from a target or the like are deposited, a film is formed by reaction at a surface of an object to be processed in a CVD method and an ALD method. Thus, the CVD method and the ALD method can give good step coverage, almost regardless of the shape of an object to be processed. In particular, the ALD method allows excellent step coverage and excellent thickness uniformity and can be suitably used to cover a surface of an opening portion with a high aspect ratio, for example. Note that the ALD method has a relatively low film formation rate; hence, in some cases, the ALD method is preferably combined with another film formation method with a high film formation rate, such as a sputtering method or a CVD method. For example, when the metal oxide has a stacked-layer structure of a first metal oxide and a second metal oxide, a method in which a sputtering method is used to form the first metal oxide, and an ALD method is used to form the second metal oxide over the first metal oxide can be given. For example, in the case where the first metal oxide has a crystal part, crystal growth occurs in the second metal oxide with the use of the crystal part as a nucleus.

When a CVD method or an ALD method is used, the composition of a film to be formed can be controlled with the flow rate ratio of the source gases. For example, in a CVD method and an ALD method, a film with a certain composition can be formed by adjusting the flow rate ratio of the source gases. Moreover, for example, when the flow rate ratio of the source gases is changed during film formation in a CVD method and an ALD method, a film whose composition is continuously changed can be formed. In the case where a film is formed while the flow rate ratio of the source gases is changed, as compared with the case where a film is formed using a plurality of deposition chambers, the time taken for the film formation can be shortened because the time taken for transfer and pressure adjustment is omitted. Hence, the productivity of the semiconductor device can be improved in some cases.

A film with a certain composition can be formed by adjusting the amount of introduced source gases, the number of times of introduction (also referred to as the number of pulses), and the time required for one pulse (also referred to as the pulse time) in an ALD method. An ALD method in which a plurality of different kinds of precursors are introduced at a time enables formation of a film with a desired composition. In the case where a plurality of different kinds of precursors are introduced, the number of cycles for each precursor is controlled, whereby a film with a desired composition can be formed.

Alternatively, thin films included in the semiconductor device (e.g., insulating films, semiconductor films, and conductive films) can be formed by a wet process such as a spin coating method, a dip coating method, a spray coating method, an inkjet method, dispensing, screen printing, offset printing, doctor blade coating, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. EUV, X-rays, or an electron beam is preferably used to enable extremely minute processing. Note that a photomask is not needed when exposure is performed by scanning with a beam such as an electron beam.

For etching of thin films, a dry etching method, a wet etching method, a sandblast method, or the like can be used.

First, the conductive layer 520 is formed over the insulating layer 210. Next, the insulating layer 481 is formed over the conductive layer 520 and the insulating layer 210. Then, the conductive layer 114 and the insulating layer 482 are formed over the insulating layer 481 (FIG. 18A).

The conductive layer 114 is provided so as to be embedded in an opening portion of the insulating layer 482. The top surfaces of the conductive layer 114 and the insulating layer 482 are preferably subjected to planarization treatment (also referred to as CMP treatment) by a chemical mechanical polishing (CMP) method or the like.

Next, the opening portions (the opening portion 590c and the opening portion 590d) reaching the conductive layer 520 are formed in the conductive layer 114 and the insulating layer 481 (FIG. 18B). The opening portion 590d and the opening portion 590c can be formed using the same mask.

Then, the insulating layer 556 and the charge-accumulation layer 555 are formed in the opening portion 590c and the opening portion 590d (FIG. 18C).

The insulating layer 556 and the charge-accumulation layer 555 can be formed as follows, for example. First, an insulating film to be the insulating layer 556 is formed in the opening 590c and the opening 590d and over the insulating layer 482 and the conductive layer 114. Then, a film to be the charge-accumulation layer 555 is formed over the insulating film to be the insulating layer 556. The film to be the charge-accumulation layer 555 is formed to fill the opening 590c and the opening 590d. Next, parts positioned over the insulating layer 482 and the conductive layer 114 are removed from the film to be the charge-accumulation layer 555 and the insulating film to be the insulating layer 556, whereby the charge-accumulation layer 555 and the insulating layer 556 are formed.

Next, the insulating layer 483 is formed over the charge-accumulation layer 555, the insulating layer 556, the conductive layer 114, and the insulating layer 482. Subsequently, the conductive layer 540 is formed over the insulating layer 483 (FIG. 18D).

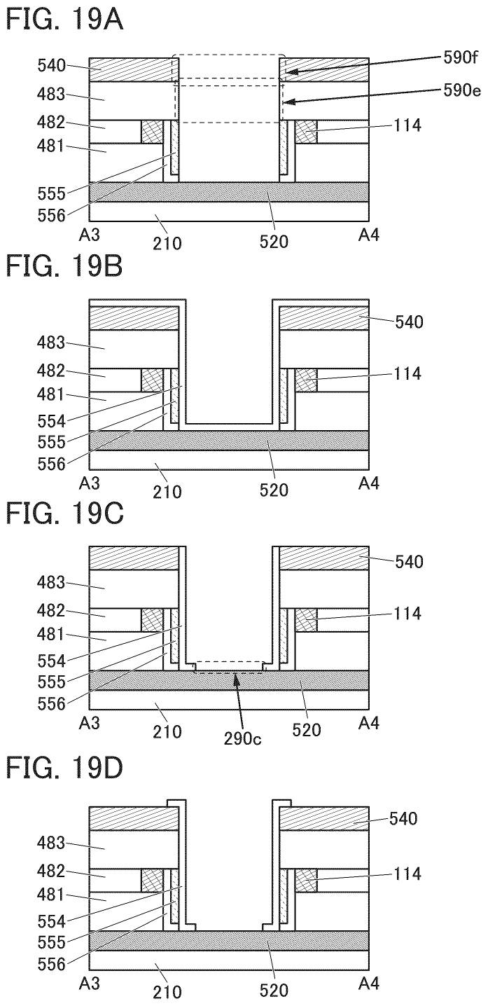

Next, opening portions reaching the conductive layer 520 are provided in the conductive layer 540, the insulating layer 483, the charge-accumulation layer 555, and the insulating layer 556 (FIG. 19A). The opening portion provided in the conductive layer 540 is referred to as the opening portion 590f. The opening portion provided in the insulating layer 483 is referred to as the opening portion 590e. When the opening portions are formed using the same mask, the sidewalls of the upper and lower opening portions can be smoothly connected to each other. An opening portion in one layer may be provided using the opening portion in the upper layer as a hard mask.

Next, the insulating layer 554 is formed to be in contact with the sidewalls of the opening portions provided in the conductive layer 540, the insulating layer 483, the charge-accumulation layer 555, and the insulating layer 556, the top surface of the conductive layer 520, and the top surface of the conductive layer 540 (FIG. 19B).

Next, a region of the insulating layer 554 that is positioned over the conductive layer 540 is removed. The opening portion 290c is formed in a region positioned over the conductive layer 520 (FIG. 19C).

The region of the insulating layer 554 that is positioned over the conductive layer 540 can be removed by planarization treatment, for example. Alternatively, etching using a mask can be performed. In the case of using a mask, part of a region over the conductive layer 540 may remain in the insulating layer 554 as illustrated in FIG. 19D. Thus, for example, the oxide semiconductor layer 530 covers an end portion of the conductive layer 540 on the opening portion 590f side with the insulating layer 554 therebetween. This may improve the coverage with the oxide semiconductor layer 530.

Subsequently, the oxide semiconductor layer 530 is formed to cover the top surface of the conductive layer 520, the top surface of the insulating layer 554, and the top surface of the conductive layer 540, and then the insulating layer 551, the charge-accumulation layer 552, the insulating layer 553, the conductive layer 560, the insulating layer 283, and the insulating layer 285 are formed in this order, so that the semiconductor device illustrated in FIGS. 4A to 4C can be manufactured.

Note that the insulating layer 554 may be formed as a sidewall insulating layer on the sidewalls of the opening portions provided in the conductive layer 540, the insulating layer 483, the charge-accumulation layer 555, and the insulating layer 556. Accordingly, the semiconductor device illustrated in FIG. 6A can be fabricated.

Heat treatment can be performed after any one or a plurality of steps from the formation of the insulating layer 481 to the formation of the conductive layer 560. The heat treatment may be performed at a temperature higher than or equal to 100° C. and lower than or equal to 800° C., preferably higher than or equal to 250° C. and lower than or equal to 650° C., further preferably higher than or equal to 350° C. and lower than or equal to 550° C., for example. For example, the treatment time at a temperature higher than or equal to 350° C. and lower than or equal to 550° C. is longer than or equal to 1 minute and shorter than or equal to 1 hour, or longer than or equal to 10 minutes and shorter than or equal to 30 minutes.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. Heat treatment is preferably performed before the formation of the oxide semiconductor layer 530 to reduce impurities such as water contained in the insulating layer or the like.

The gas used in the heat treatment preferably has high purity. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the insulating layer or the like as much as possible. By performing the heat treatment after the formation of the oxide semiconductor layer 530, the crystallinity of the oxide semiconductor layer 530 can be increased.

### <Manufacturing Method Example 2 of Semiconductor Device>

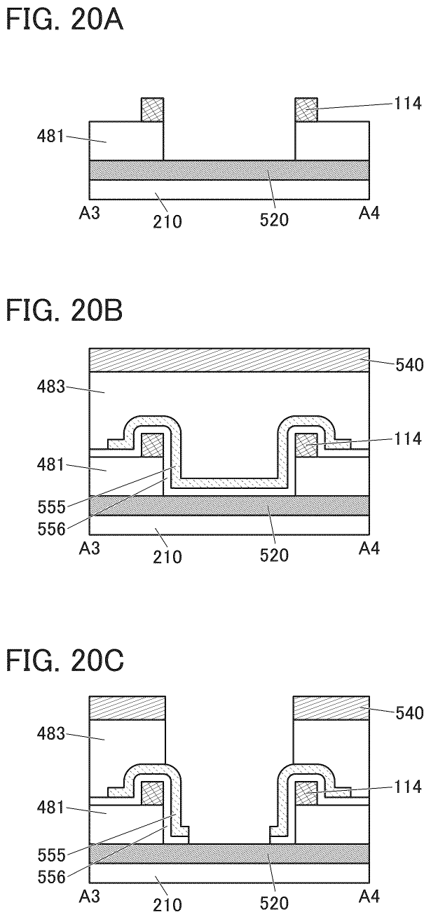

A method for manufacturing the semiconductor device illustrated in FIG. 6B is described with reference to FIGS. 20A to 20C. The semiconductor device illustrated in FIG. 6B does not include the insulating layer 482.

First, the conductive layer 520 is formed over the insulating layer 210. Next, the insulating layer 481 is formed over the conductive layer 520 and the insulating layer 210. Then, the conductive layer 114 is formed over the insulating layer 481.

Next, opening portions reaching the conductive layer 520 are formed in the conductive layer 114 and the insulating layer 481 (FIG. 20A).

Then, the insulating layer 556 and the charge-accumulation layer 555 are sequentially formed to cover the sidewalls of the conductive layer 114 and the insulating layer 481, the top surface of the conductive layer 520, the top surface of the conductive layer 114, and the top surface of the insulating layer 481. Next, the insulating layer 483 and the conductive layer 540 are formed in this order over the charge-accumulation layer 555 and the insulating layer 556 (FIG. 20B).

Next, an opening portion is provided in the conductive layer 540 and the insulating layer 483. The opening portion provided in the conductive layer 540 and the insulating layer 483 can be formed using the same mask.

Subsequently, an opening portion is provided in each of the insulating layer 556 and the charge-accumulation layer 555, so that the top surface of the conductive layer 520 is exposed (FIG. 20C). In the example illustrated in FIG. 20C, the widths of the opening portions in the insulating layer 556 and the charge-accumulation layer 555 are smaller than those of the opening portions in the conductive layer 540 and the insulating layer 483. Although not illustrated, in a plan view, the opening portions in the insulating layer 556 and the charge-accumulation layer 555 are surrounded by the opening portions in the conductive layer 540 and the insulating layer 483, for example.

Next, the insulating layer 554 is formed to cover the sidewall of the opening portion in the conductive layer 540, the sidewall of the opening portion in the insulating layer 483, the top surface of the conductive layer 520, the top surface of the charge-accumulation layer 555, and the side surface of the insulating layer 556. Subsequently, the oxide semiconductor layer 530, the insulating layer 551, the charge-accumulation layer 552, the insulating layer 553, the conductive layer 560, the insulating layer 283, and the insulating layer 285 are formed in this order, whereby the semiconductor device illustrated in FIG. 6B can be manufactured.

### <Structure Example 2 of Semiconductor Device>

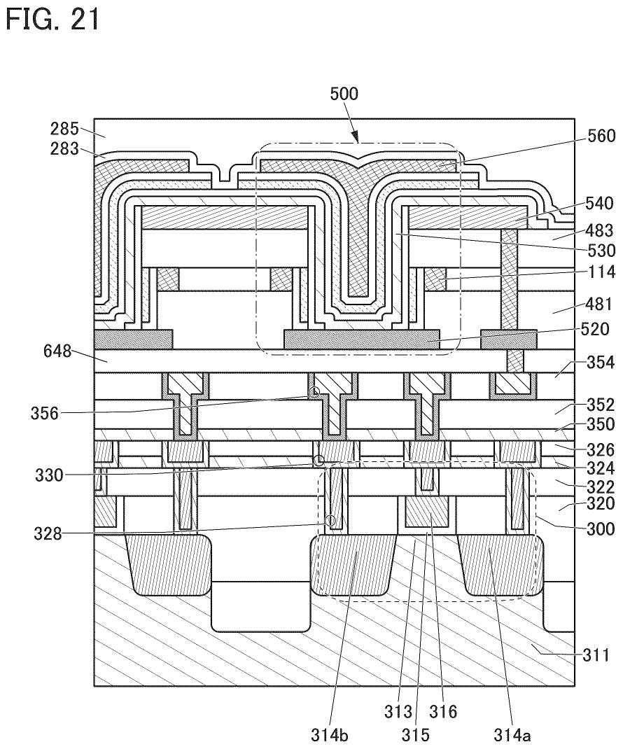

As illustrated in FIG. 21, in the semiconductor device of one embodiment of the present invention, memory cells can be stacked over a layer including a circuit for driving the memory cells.

In FIG. 21, the transistor 500 is provided above a transistor 300.

The transistor 300 can be used as, for example, a transistor included in a sense amplifier described later.

For the transistor 500 illustrated in FIG. 21, the description in FIG. 4B and the like can be referred to.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 can be a p-channel transistor or an n-channel transistor.

In the transistor 300 illustrated in FIG. 21, the semiconductor region 313 (part of the substrate 311) where a channel is formed has a projecting shape. The conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 21 is just an example and is not limited to having the structure illustrated therein; an appropriate transistor can be used in accordance with a circuit structure or a driving method.

A wiring layer including an interlayer film, a wiring, a plug, and the like may be provided between components. A plurality of wiring layers can be provided in accordance with the design. Here, a plurality of conductive layers functioning as plugs or wirings are collectively denoted by the same reference numeral in some cases. In this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. In the structure example in FIG. 21, an insulating layer 350, an insulating layer 352, and an insulating layer 354 are stacked sequentially. Furthermore, a conductive layer 356 is formed in the insulating layers 350, 352, and 354. The conductive layer 356 functions as a plug or a wiring.

For the insulating layer 352, the insulating layer 354, and the like functioning as interlayer films, the description of the above insulating layer that can be used for the semiconductor device can be referred to.

For the conductive layer functioning as a plug or a wiring, for example, the conductive layer 328, the conductive layer 330, the conductive layer 356, and the like, the description of the above conductive layer that can be used in the semiconductor device can be referred to.

The transistor 300 is connected to a circuit including the transistor 500 through the conductive layer 356, a conductive layer embedded in an insulating layer 648, and the like.

This embodiment can be combined with any of the other embodiments as appropriate.

### Embodiment 2

In this embodiment, the semiconductor device of one embodiment of the present invention will be described. The semiconductor device of one embodiment of the present invention can function as a memory device.

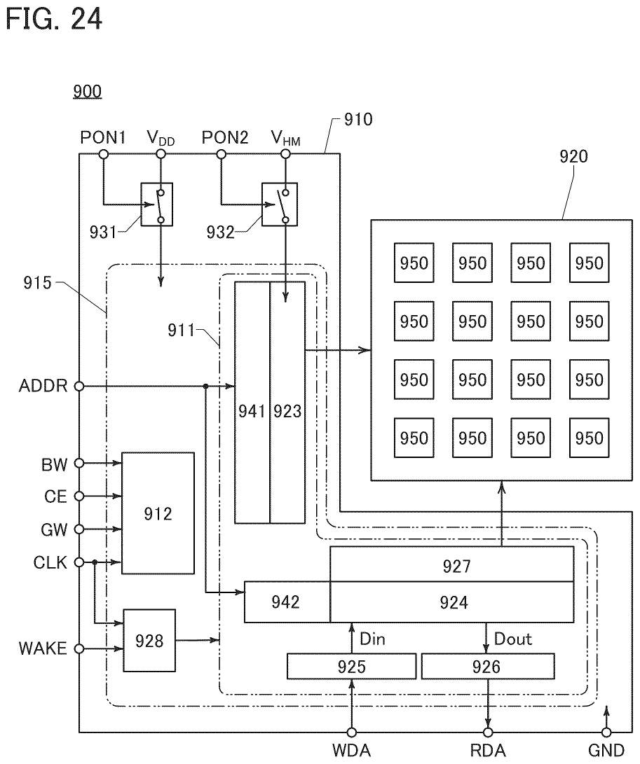

FIG. 24 is a block diagram illustrating a structure example of a semiconductor device 900. The semiconductor device 900 illustrated in FIG. 24 includes a driver circuit 910 and a memory cell array 920.

The memory cell array 601, the memory cell array 611, and the like described in the above embodiment can be used as the memory cell array 920.

The memory cell array 920 includes one or more memory cells 950. The memory cell 602, the memory cell 612, and the like described in the above embodiment can be used as the memory cell 950.

The driver circuit 910 includes a power switch (PSW) 931, a PSW 932, and a peripheral circuit 915. The peripheral circuit 915 includes a peripheral circuit 911, a control circuit 912 (Control Circuit), and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed. The control circuit 912 may have a function of detecting and correcting an error (also referred to as ECC: Error Check and Correct) in reading out data from the memory cell array 920.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941 (Row Decoder), a column decoder 942 (Column Decoder), a row driver 923 (Row Driver), a column driver 924 (Column Driver), an input circuit 925 (Input Cir.), an output circuit 926 (Output Cir.), and a sense amplifier 927 (Sense Amplifier).

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply voltage is VDD and a low power supply voltage is GND (ground potential). In addition, VHM is a voltage higher than VDD and used as a potential applied at the time of writing, erasing, and the like. The on/off state of the PSW 931 is controlled by the signal PON1, and the on/off state of the PSW 932 is controlled by the signal PON2. The number of power domains to which VDD is supplied is one in the peripheral circuit 915 in FIG. 24 but can be more than one. In that case, a power switch is provided for each power domain.

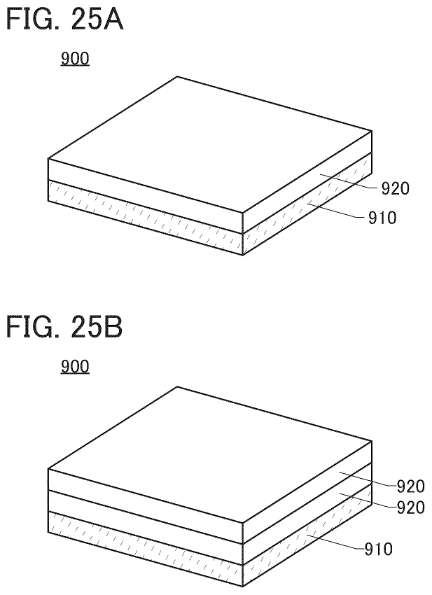

The driver circuit and the memory cell array 920 included in the semiconductor device 900 may be provided on the same plane. Alternatively, as illustrated in FIG. 25A, the driver circuit and the memory cell array 920 may be provided to overlap with each other. Overlapping the driver circuit and the memory cell array 920 can shorten a signal propagation distance.

For easy understanding of the structure of the semiconductor device 900, a layer where the driver circuit 910 is provided and a layer where the memory cell array 920 is provided are separately illustrated in FIG. 25A.

As illustrated in FIG. 25B, a plurality of memory cell arrays 920 may be stacked over the driver circuit.

### [Arithmetic Processing Device]

Description is made on an example of an arithmetic processing device that can include the semiconductor device such as the memory device described above.

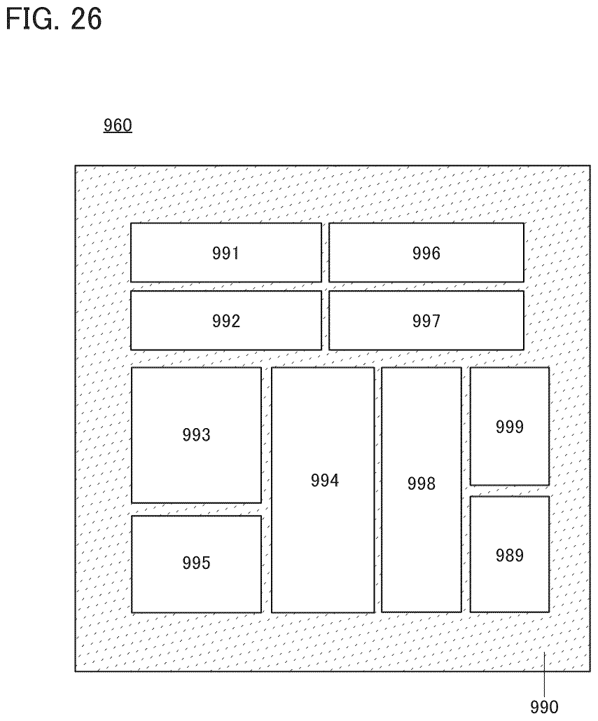

FIG. 26 is a block diagram of an arithmetic device 960. The arithmetic device 960 illustrated in FIG. 26 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 26 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory cell array 920 can be stacked over the arithmetic device 960. The memory cell array 920 can be used as a cache. Here, the cache interface 989 may have a function of supplying data retained in the memory cell array 920 to the cache 999. Moreover, in this case, the driver circuit 910 is preferably included in part of the cache interface 989.

Note that it is also possible that the cache 999 is not provided and only the memory cell array 920 is used as a cache.

The arithmetic device 960 illustrated in FIG. 26 is only an example with a simplified structure, and the actual arithmetic device 960 has a variety of structures depending on the application. For example, what is called a multicore structure is preferably employed in which a plurality of cores each including the arithmetic device 960 in FIG. 26 operate in parallel. The larger number of cores can further enhance the arithmetic performance. The number of cores is preferably larger; for example, the number is preferably 2, further preferably 4, further preferably 8, further preferably 12, further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 26, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

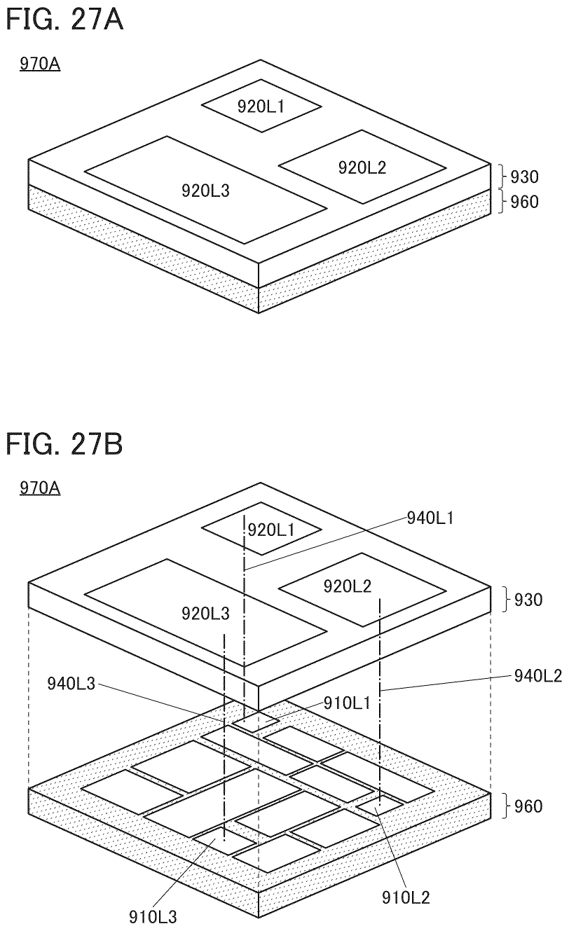

The memory cell array 920 and the arithmetic device 960 can be provided to overlap with each other. FIGS. 27A and 27B are perspective views of a semiconductor device 970A. The semiconductor device 970A includes a layer 930 provided with memory cell arrays over the arithmetic device 960. A memory cell array 920L1, a memory cell array 920L2, and a memory cell array 920L3 are provided in the layer 930. The arithmetic device 960 and each of the memory cell arrays overlap with each other. For easy understanding of the structure of the semiconductor device 970A, the arithmetic device 960 and the layer 930 are separately illustrated in FIG. 27B.

Overlapping the arithmetic device 960 and the layer 930 including the memory cell arrays can shorten the connection distance therebetween. Accordingly, the communication speed therebetween can be increased. Moreover, a short connection distance leads to lower power consumption.

As a method for stacking the layer 930 including the memory cell arrays and the arithmetic device 960, either of the following methods may be employed: a method in which the layer 930 including the memory cell arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory cell arrays 920L1, 920L2, and 920L3 provided in the layer 930 are each used as a cache. In this case, for example, the memory cell array 920L1, the memory cell array 920L2, and the memory cell array 920L3 can be used as an L1 cache (also referred to as a level 1 cache), an L2 cache (also referred to as a level 2 cache), and an L3 cache (also referred to as a level 3 cache), respectively. Among the three memory cell arrays, the memory cell array 920L3 has the highest capacity and the lowest access frequency. The memory cell array 920L1 has the lowest capacity and the highest access frequency.

Note that in the case where the cache 999 provided in the arithmetic device 960 is used as the L1 cache, the memory cell arrays provided in the layer 930 can each be used as the lower-level cache or the main memory. The main memory has higher capacity and lower access frequency than the cache.

As illustrated in FIG. 27B, a driver circuit 910L1, a driver circuit 910L2, and a driver circuit 910L3 are provided. The driver circuit 910L1 is connected to the memory cell array 920L1 through a connection electrode 940L1. Similarly, the driver circuit 910L2 is connected to the memory cell array 920L2 through a connection electrode 940L2, and the driver circuit 910L3 is connected to the memory cell array 920L3 through a connection electrode 940L3.

Note that although the case where three memory cell arrays function as caches is described here, the number of memory cell arrays may be one, two, or four or more.

In the case where the memory cell array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory cell array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

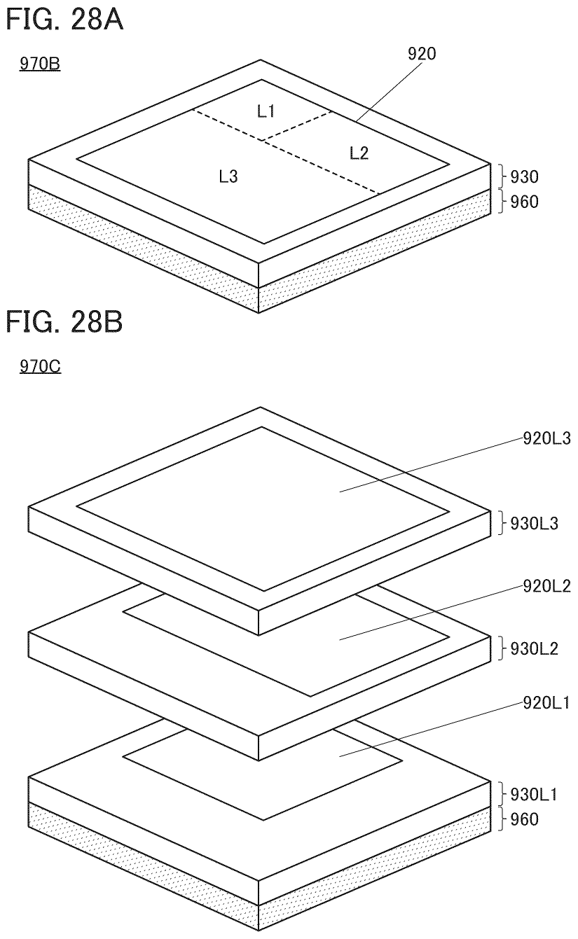

The layer 930 including one memory cell array 920 may be provided to overlap with the arithmetic device 960. FIG. 28A is a perspective view of a semiconductor device 970B.

In the semiconductor device 970B, one memory cell array 920 can be divided into a plurality of areas having different functions. FIG. 28A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory cell arrays may be stacked. FIG. 28B is a perspective view of a semiconductor device 970C.

In the semiconductor device 970C, a layer 930L1 including the memory cell array 920L1, a layer 930L2 including the memory cell array 920L2 over the layer 930L1, and a layer 930L3 including the memory cell array 920L3 over the layer 930L2 are stacked. The memory cell array 920L1 physically closest to the arithmetic device 960 can be used as a high-level cache, and the memory cell array 920L3 physically farthest from the arithmetic device 960 can be used as a low-level cache or a main memory. Such a structure can increase the capacity of each memory cell array, leading to higher processing capability.

This embodiment can be combined with any of the other embodiments as appropriate.

### Embodiment 3

In this embodiment, application examples of the memory device of one embodiment of the present invention will be described.

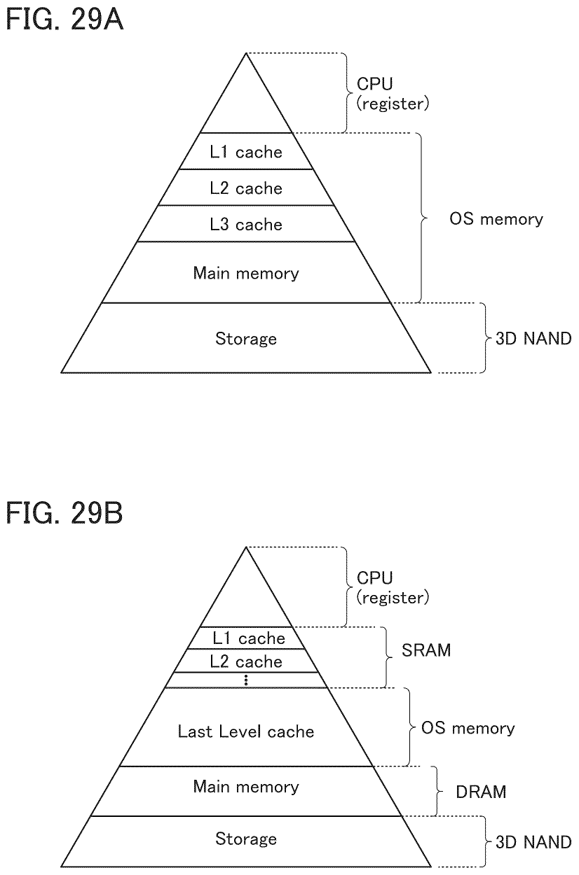

In general, a variety of memory devices are used in semiconductor devices such as computers in accordance with the intended use. FIG. 29A illustrates the hierarchy of various memory devices used in a semiconductor device. The memory devices at the upper levels require a higher operating speed, whereas the memory devices at the lower levels require a larger memory capacity and a higher memory density. FIG. 29A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be held for a long time and programs used in an arithmetic processing device, for example. Therefore, the storage needs to have a large memory capacity and a high memory density rather than operating speed. For example, a high-capacity nonvolatile memory device such as a 3D NAND memory device can be used.

The memory device including an oxide semiconductor (the OS memory) of one embodiment of the present invention operates at high speed and can retain data for a long time. Specifically, the DOSRAM, the NOSRAM, the OS-SRAM, or the like described in the above embodiment can be used as the OS memory, for example. As illustrated in FIG. 29A, the memory device of one embodiment of the present invention can be favorably used at both the level including the cache and the level including the main memory. The memory device of one embodiment of the present invention can also be used at the level including the storage. For example, the memory device using the transistor 500 described in the above embodiment can be used at the level including the storage.

FIG. 29B illustrates an example in which an SRAM is used as at least one of the caches and the OS memory of one embodiment of the present invention is used as the other cache.

The lowest-level cache can be referred to as a last level cache (LLC). The LLC does not require a higher operation speed than a higher-level cache, but desirably has large memory capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 29B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 29B.

This embodiment can be combined with any of the other embodiments as appropriate.

### Embodiment 4

In this embodiment, application examples of the semiconductor device of one embodiment of the present invention are described.

The semiconductor device of one embodiment of the present invention can be used for an electronic component, a large computer, a device for space, a data center (also referred to as DC), and a variety of electronic devices, for example. With the use of the semiconductor device of one embodiment of the present invention, an electronic component, a large computer, a device for space, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

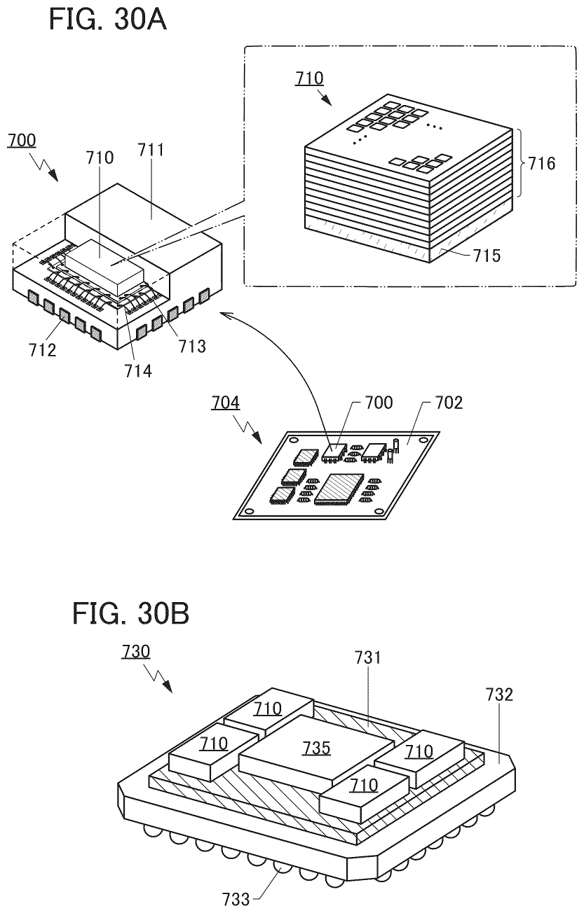

FIG. 30A is a perspective view of a substrate (a circuit board 704) provided with an electronic component 700. The electronic component 700 illustrated in FIG. 30A includes a semiconductor device 710 in a mold 711. FIG. 30A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. Monolithically stacking the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 30B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 30B illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

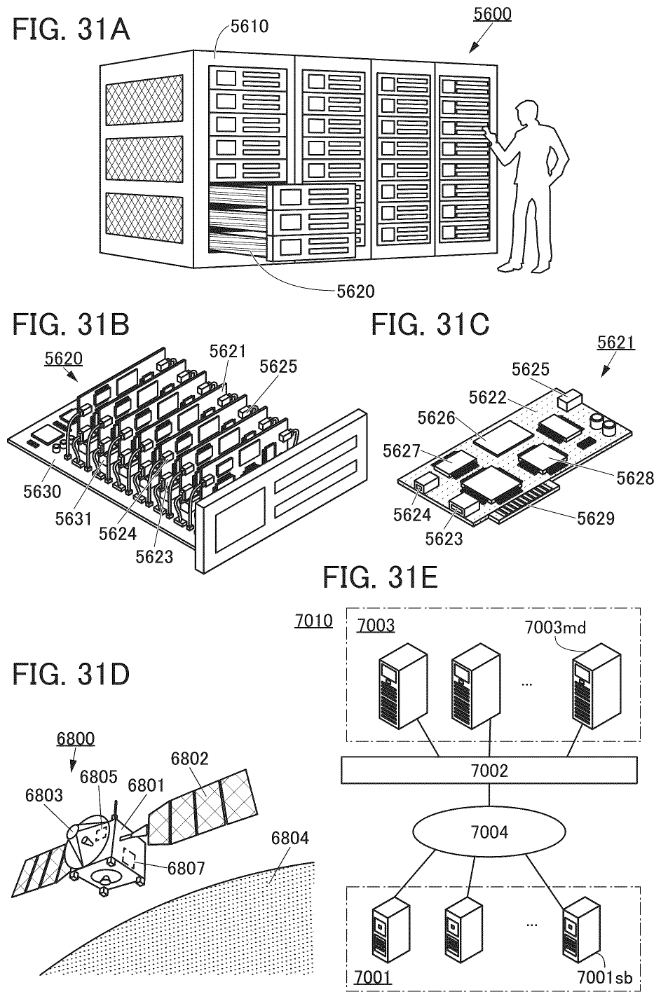

FIG. 31A is a perspective view of a large computer 5600. In the large computer 5600 illustrated in FIG. 31A, a plurality of rack mount computers 5620 are stored in a rack 5610. Note that the large computer 5600 may be referred to as a supercomputer.

The computer 5620 can have a structure illustrated in a perspective view in FIG. 31B, for example. In FIG. 31B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 31C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 31C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that although outer space refers to, for example, space at an altitude greater than or equal to 100 km, outer space described in this specification may include one or more of thermosphere, mesosphere, and stratosphere.

FIG. 31D illustrates an artificial satellite 6800 as an example of a device for space. The artificial satellite 6800 includes a body 6801, a solar panel 6802, an antenna 6803, a secondary battery 6805, and a control device 6807. In FIG. 31D, a planet 6804 in outer space is illustrated as an example.

Although not illustrated in FIG. 31D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 can be provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for storing a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 31E illustrates a storage system that can be used in a data center. A storage system 7010 illustrated in FIG. 31E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic component, a large computer, a device for space, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate.

This application is based on Japanese Patent Application Serial No. 2023-188121 filed with Japan Patent Office on Nov. 2, 2023, the entire contents of which are hereby incorporated by reference.

What is claimed is:

1. A semiconductor device comprising:
a first conductive layer;
a first insulating layer over the first conductive layer;
a second conductive layer over the first insulating layer;
a second insulating layer over the second conductive layer;
a third conductive layer over the second insulating layer;
an oxide semiconductor layer;
a fourth conductive layer;
a third insulating layer;
a fourth insulating layer;
a fifth insulating layer;
a sixth insulating layer;
a first charge-accumulation layer; and
a second charge-accumulation layer,
wherein the first insulating layer, the second conductive layer, the second insulating layer, and the third conductive layer each comprise an opening portion reaching the first conductive layer,
wherein the third insulating layer comprises a region in contact with a sidewall of the opening portion of the first insulating layer, a region in contact with a sidewall of the opening portion of the second conductive layer, and a region in contact with a top surface of the first conductive layer,
wherein the first charge-accumulation layer comprises a region covering the sidewall of the opening portion of the second conductive layer with the third insulating layer therebetween,
wherein the fourth insulating layer comprises a region covering the sidewall of the opening portion of the second conductive layer with the third insulating layer and the first charge-accumulation layer therebetween,
wherein the fourth insulating layer comprises a region between the oxide semiconductor layer and the first charge-accumulation layer,
wherein the oxide semiconductor layer comprises a region in contact with the top surface of the first conductive layer, a region covering the sidewall of the opening portion of the second conductive layer with the third insulating layer, the first charge-accumulation layer, and the fourth insulating layer therebetween, and a region in contact with the third conductive layer,
wherein the fourth conductive layer comprises a region positioned in the opening portion of the second conductive layer,
wherein the second charge-accumulation layer comprises a region between the oxide semiconductor layer and the fourth conductive layer,
wherein the fifth insulating layer comprises a region between the oxide semiconductor layer and the second charge-accumulation layer, and
wherein the sixth insulating layer comprises a region between the second charge-accumulation layer and the fourth conductive layer.

2. The semiconductor device according to claim 1,
wherein the fourth insulating layer and the fifth insulating layer each comprise one or more selected from silicon oxide, silicon oxynitride, silicon nitride oxide, silicon nitride, and aluminum oxide.

3. The semiconductor device according to claim 1,
wherein at least one of the first charge-accumulation layer and the second charge-accumulation layer comprises one or more metal elements selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, and lanthanum, an alloy comprising any of these metal elements as its component, or an alloy comprising a combination of these metal elements.

4. The semiconductor device according to claim 1,
wherein at least one of the first charge-accumulation layer and the second charge-accumulation layer comprises a metal nitride or a metal oxide.

5. The semiconductor device according to claim 1,
wherein at least one of the first charge-accumulation layer and the second charge-accumulation layer comprises one or more selected from silicon and germanium.

6. The semiconductor device according to claim 1,
wherein at least one of the first charge-accumulation layer and the second charge-accumulation layer comprises one or more selected from silicon nitride and silicon nitride oxide.

7. The semiconductor device according to claim 1,
wherein the first conductive layer functions as one of a source electrode and a drain electrode of a transistor,
wherein the third conductive layer functions as the other of the source electrode and the drain electrode of the transistor,
wherein the fourth conductive layer functions as a first control gate of the transistor, and
wherein the second conductive layer functions as a second control gate of the transistor.
